(19) United States
(12) Patent Application Publication
(10) Pub. No.: US 2023/0101361 A1
(43) Pub. Date: Mar. 30, 2023

(54) METHOD FOR MANUFACTURING DIFFUSION COVER, DIFFUSION COVER, AND SEMICONDUCTOR LIGHT-EMITTING DEVICE COMPRISING SAME

(71) Applicant: ROHM CO., LTD., Kyoto-shi, Kyoto (JP)

(72) Inventor: Goro NAKATANI, Kyoto-shi, Kyoto (JP)

(21) Appl. No.: 17/802,050

(22) PCT Filed: Apr. 5, 2021
(86) PCT No.: PCT/JP2021/014512

§ 371 Date: Aug. 24, 2022

(30) Foreign Application Priority Data
Apr. 17, 2020 (JP) 2020-074267
Sep. 7, 2020 (JP) 2020-149558
Sep. 30, 2020 (JP) 2020-165068

(51) Int. Cl. G02B 5/02; H01S 5/02257

(52) U.S. Cl. CPC G02B 5/0215; H01S 5/02257; G02B 5/0278; G02B 5/0268; H01S 5/423

(57) ABSTRACT

The present disclosure provides a method for manufacturing a diffusion cover that diffuses and transmits light from a semiconductor light-emitting element. The method includes the steps of preparing a base member having an obverse surface and a reverse surface that face away from each other in a thickness direction; forming a lens material on the obverse surface, the lens material containing a photosensitive transparent resin; and removing a portion of the lens material by performing grayscale exposure and development, and forming a lens having a plurality of lens members. Such a configuration can provide a diffusion cover suitable for reducing the manufacturing cost.

### TECHNICAL FIELD

A first group of the present disclosure relates to a method for manufacturing a diffusion cover, the diffusion cover, and a semiconductor light-emitting device including the same.

A second group of the present disclosure relates to a wiring board, an electronic device including the wiring board, and a method for manufacturing the wiring board.

A third group of the present disclosure relates to a substrate and a semiconductor device.

### BACKGROUND ART

In the background art of the first group of the present disclosure, a semiconductor light-emitting device including a semiconductor light-emitting element as a light source has been widely proposed. Patent Document 1 discloses an example of such a semiconductor light-emitting device. The semiconductor light-emitting device disclosed in this document includes a semiconductor laser element, which is an example of a semiconductor light-emitting element, a support on which the semiconductor light-emitting element is mounted and that surrounds the semiconductor light-emitting element, and a cover that is translucent. The cover may be a diffusion plate (diffusion cover) that transmits and diffuses light from the semiconductor light-emitting element.

The diffusion cover includes a base layer that transmits light from the semiconductor light-emitting element, and a diffusion layer that diffuses light from the semiconductor light-emitting element. The diffusion layer may be configured as a microlens array having a plurality of lens members. Such a diffusion layer (microlens array) is generally formed by embossing a plate-like lens material made of, for example, a transparent resin, using an imprinting technique.

However, forming a diffusion layer using an imprinting technique requires use of an imprinting apparatus, which leads to a rise in the manufacturing cost of a diffusion cover.

Regarding the background art of the second group of the present disclosure, Patent Document 2 discloses an example of a conventional wiring board. The wiring board disclosed in this document includes an insulating substrate, an upper conductive layer, a lower conductive layer, and a conductive layer. The insulating substrate is made of aluminum nitride. The insulating substrate is formed with a through-hole that penetrates through in the thickness direction. The upper conductive layer is provided on the insulating substrate and surrounds the through-hole. The lower conductive layer is provided under the insulating substrate, and surrounds the through-hole. The conductive layer is embedded in the through-hole and electrically connects the upper conductive layer and the lower conductive layer. In the following description, the wiring board described in Patent Document 1 may be referred to as an ALN substrate.

In the wiring board described in Patent Document 2, the upper conductive layer and the lower conductive layer sandwich the insulating substrate. Accordingly, in order to electrically connect the upper conductive layer and the lower conductive layer, the through-hole for burying the conductive layer needs to be formed in the insulating substrate. In Patent Document 1, laser processing is used as a method for forming the through-hole. In this method, however, an increase in the cross-sectional area of the through-hole or an increase in the number of through-holes causes the manufacturing efficiency of the ALN substrate to drop. This leads to a rise in the manufacturing cost of the ALN substrate.

Regarding the background art of the third group of the present disclosure, Patent Document 3 discloses an example of a conventional semiconductor device. The semiconductor device disclosed in this document includes a plurality of leads, a semiconductor element, and a sealing resin. The semiconductor element is mounted on one of the leads. The semiconductor element is connected to the other leads via wires. The plurality of leads are insulated from one another by the sealing resin.

It is necessary for the semiconductor device to dissipate heat generated during the operation of the semiconductor element to the outside of the semiconductor device. So-called surface mounting is preferable for the heat dissipation. In addition, there is a demand for reducing the size of the semiconductor device.

### PRIOR ART DOCUMENT

### Patent Document

Patent Document 1: JP-A-2020-77678
Patent Document 2: JP-A-2012-74451
Patent Document 3: JP-A-2019-110278

### SUMMARY OF THE INVENTION

### Problem to be Solved by the Invention

An object of the first group of the present disclosure is to provide a method for manufacturing a diffusion cover suitable for reducing the manufacturing cost, the diffusion cover, and a semiconductor light-emitting device including the same.

An object of the second group of the present disclosure is to provide a wiring board capable of reducing the manufacturing cost.

An object of the third group of the present disclosure is to provide a substrate and a semiconductor device capable of facilitating heat dissipation and miniaturization.

### Means to Solve the Problem

According to a first aspect of the first group of the present disclosure, there is provided a method for manufacturing a diffusion cover that diffuses and transmits light from a semiconductor light-emitting element, the method comprising the steps of: preparing a base member having an obverse surface and a reverse surface that face away from each other in a thickness direction; forming a lens material on the obverse surface, the lens material containing a photosensitive transparent resin; and removing a portion of the lens material by performing grayscale exposure and development, and forming a lens having a plurality of lens members.

According to a second aspect of the first group of the present disclosure, there is provided a diffusion cover that diffuses and transmits light from a semiconductor light-emitting element. The diffusion cover comprises: a base member having an obverse surface and a reverse surface that face away from each other in a thickness direction; and a lens arranged on the obverse surface, having a plurality of lens members protruding to the same side as a side that the obverse surface faces in the thickness direction, and containing a transparent resin.

According to a third aspect of the first group of the present disclosure, there is provided a semiconductor light-emitting device comprising: a semiconductor light-emitting element; a support that supports the semiconductor light-emitting element; and the diffusion cover according to the second aspect of the first group of the present disclosure, the diffusion cover overlapping with the semiconductor light-emitting element as viewed in the thickness direction.

According to a first aspect of the second group of the present disclosure, there is provided a wiring board comprising: a base member having an obverse surface and a reverse surface that are spaced apart from each other in a thickness direction, the base member containing a semiconductor material; and an insulating portion that penetrates through the base member from the obverse surface to the reverse surface in the thickness direction, wherein the base member includes a first portion and a second portion that are separated from each other by the insulating portion.

According to a second aspect of the second group of the present disclosure, there is provided an electronic device comprising: the wiring board provided by the first aspect; and an electronic component electrically connected to the first portion and the second portion.

According to a third aspect of the second group of the present disclosure, there is provided a method for manufacturing a wiring board. The method comprises: a wafer preparation step of preparing a semiconductor wafer having an obverse surface and a reverse surface spaced apart from each other in a thickness direction, the semiconductor wafer containing a semiconductor material; and an insulating portion formation step of forming an insulating portion in the semiconductor wafer, the insulating portion penetrating through from the obverse surface to the reverse surface in the thickness direction, wherein the insulating portion formation step forms a first portion and a second portion in the semiconductor wafer, the first portion and the second portion being separated from each other by the insulating portion.

According to a first aspect of the third group of the present disclosure, there is provided a substrate comprising: a base member containing a semiconductor material and having an obverse surface and a reverse surface that face away from each other in a thickness direction; and a conductive portion formed on the base member, wherein the base member has a through-hole penetrating through in the thickness direction to reach the obverse surface and the reverse surface, the through-hole having an inner wall surface along the thickness direction, and the conductive portion has an obverse surface portion supported by the obverse surface, a reverse surface portion supported by the reverse surface, and a through portion housed in the through-hole and connected to the obverse surface portion and the reverse surface portion.

According to a second aspect of the third group of the present disclosure, there is provided a semiconductor device comprising: the substrate provided by the first aspect of the third group of the present disclosure; and a semiconductor element mounted on the obverse surface portion of the conductive portion.

### Advantages of the Invention

The first group of the present disclosure can reduce the manufacturing cost of a diffusion cover.

The second group of the present disclosure can reduce the manufacturing cost.

The third group of the present disclosure can provide a substrate and a semiconductor device capable of facilitating heat dissipation and miniaturization.

Other features and advantages of the present invention will be more apparent from the detailed description given below with reference to the accompanying drawings.

### BRIEF DESCRIPTION OF THE DRAWINGS

FIG. 1 is a plan view showing main parts of a semiconductor light-emitting device according to a first embodiment of a first group of the present disclosure.

FIG. 2 is a bottom view showing the semiconductor light-emitting device according to the first embodiment of the first group of the present disclosure.

FIG. 3 is a cross-sectional view taken along line in FIG. 1.

FIG. 4 is a cross-sectional view taken along line IV-IV in FIG. 1.

FIG. 5 is a cross-sectional view taken along line V-V in FIG. 1.

FIG. 6 is a partially enlarged view of FIG. 3.

FIG. 7 is an enlarged cross-sectional perspective view showing a semiconductor light-emitting element of the semiconductor light-emitting device according to the first embodiment of the first group of the present disclosure.

FIG. 8 is a partially enlarged cross-sectional view showing the semiconductor light-emitting element of the semiconductor light-emitting device according to the first embodiment of the first group of the present disclosure.

FIG. 9 is a cross-sectional view showing a step of an illustrative method for manufacturing a diffusion cover according to the first embodiment of the first group of the present disclosure.

FIG. 10 is a cross-sectional view showing a step following the step in FIG. 9.

FIG. 11 is a cross-sectional view showing a step following the step in FIG. 10.

FIG. 12 is a cross-sectional view showing a step following the step in FIG. 11.

FIG. 13 is a cross-sectional view similar to FIG. 3, showing a variation of the semiconductor light-emitting device according to the first embodiment of the first group of the present disclosure.

FIG. 14 is a partially enlarged view of FIG. 13.

FIG. 15 is a cross-sectional view similar to FIG. 3, showing a semiconductor light-emitting device according to a second embodiment of the first group of the present disclosure.

FIG. 16 is a partially enlarged view of FIG. 15.

FIG. 17 is a cross-sectional view showing a step of an illustrative method for manufacturing a diffusion cover according to the second embodiment of the first group of the present disclosure.

FIG. 18 is a cross-sectional view showing a step following the step in FIG. 17.

FIG. 19 is a cross-sectional view showing a step following the step in FIG. 18.

FIG. 20 is a cross-sectional view showing a step following the step in FIG. 19.

FIG. 21 is a perspective view showing a wiring board according to a first embodiment of a second group of the present disclosure.

FIG. 22 is a plan view showing the wiring board according to the first embodiment of the second group of the present disclosure.

FIG. 23 is a bottom view showing the wiring board according to the first embodiment of the second group of the present disclosure.

FIG. 24 is a cross-sectional view taken along line XXIV-XXIV in FIG. 22.

FIG. 25 is an enlarged cross-sectional view showing a portion of FIG. 24.

FIG. 26 is a perspective view showing a step of a method for manufacturing the wiring board according to the first embodiment of the second group of the present disclosure.

FIG. 27 is a cross-sectional view showing a step of the method for manufacturing the wiring board according to the first embodiment of the second group of the present disclosure.

FIG. 28 is a cross-sectional view showing a step of the method for manufacturing the wiring board according to the first embodiment of the second group of the present disclosure.

FIG. 29 is a plan view showing a step of the method for manufacturing the wiring board according to the first embodiment of the second group of the present disclosure.

FIG. 30 is a cross-sectional view showing a step of the method for manufacturing the wiring board according to the first embodiment of the second group of the present disclosure.

FIG. 31 is a cross-sectional view showing a step of the method for manufacturing the wiring board according to the first embodiment of the second group of the present disclosure.

FIG. 32 is a plan view showing a step of the method for manufacturing the wiring board according to the first embodiment of the second group of the present disclosure.

FIG. 33 is a cross-sectional view showing a step of the method for manufacturing the wiring board according to the first embodiment of the second group of the present disclosure.

FIG. 34 is a plan view showing a step of the method for manufacturing the wiring board according to the first embodiment of the second group of the present disclosure.

FIG. 35 is a cross-sectional view showing a step of the method for manufacturing the wiring board according to the first embodiment of the second group of the present disclosure.

FIG. 36 is a cross-sectional view showing a step of the method for manufacturing the wiring board according to the first embodiment of the second group of the present disclosure.

FIG. 37 is a plan view showing a step of the method for manufacturing the wiring board according to the first embodiment of the second group of the present disclosure.

FIG. 38 is a perspective view showing an electronic device including the wiring board according to the first embodiment of the second group of the present disclosure.

FIG. 39 is a cross-sectional view taken along line XXXIX-XXXIX in FIG. 38.

FIG. 40 is a plan view showing a wiring board according to a variation of the first embodiment of the second group of the present disclosure.

FIG. 41 is a plan view showing a wiring board according to a variation of the first embodiment of the second group of the present disclosure.

FIG. 42 is a plan view showing a wiring board according to a variation of the first embodiment of the second group of the present disclosure.

FIG. 43 is a cross-sectional view showing a step of a manufacturing method for a variation of the wiring board according to the first embodiment of the second group of the present disclosure.

FIG. 44 is a cross-sectional view showing a step of the manufacturing method for the variation of the wiring board according to the first embodiment of the second group of the present disclosure.

FIG. 45 is a plan view showing a wiring board according to a second embodiment of the second group of the present disclosure.

FIG. 46 is a cross-sectional view taken along line XLVI-XLVI in FIG. 45.

FIG. 47 is a plan view showing a wiring board according to a variation of the second embodiment of the second group of the present disclosure.

FIG. 48 is a plan view showing a wiring board according to a variation of the second embodiment of the second group of the present disclosure.

FIG. 49 is a plan view showing a wiring board according to a third embodiment of the second group of the present disclosure.

FIG. 50 is a plan view showing a step of a method for manufacturing the wiring board according to the third embodiment of the second group of the present disclosure.

FIG. 51 is a plan view showing a wiring board according to a fourth embodiment of the second group of the present disclosure.

FIG. 52 is a cross-sectional view taken along line LII-LII in FIG. 51.

FIG. 53 is a plan view showing a step of a method for manufacturing the wiring board according to the fourth embodiment of the second group of the present disclosure.

FIG. 54 is a plan view showing a step of the method for manufacturing the wiring board according to the fourth embodiment of the second group of the present disclosure.

FIG. 55 is a plan view showing a step of the method for manufacturing the wiring board according to the fourth embodiment of the second group of the present disclosure.

FIG. 56 is a cross-sectional view taken along line LVI-LVI in FIG. 35.

FIG. 57 is a perspective view showing a substrate according to a first embodiment of a third group of the present disclosure.

FIG. 58 is a plan view showing the substrate according to the first embodiment of the third group of the present disclosure.

FIG. 59 is a cross-sectional view taken along line LIX-LIX in FIG. 58.

FIG. 60 is a partially enlarged cross-sectional view showing the substrate according to the first embodiment of the third group of the present disclosure.

FIG. 61 is a plan view showing a method for manufacturing the substrate according to the first embodiment of the third group of the present disclosure.

FIG. 62 is a cross-sectional view taken along line LXII-LXII in FIG. 61.

FIG. 63 is a cross-sectional view showing the method for manufacturing the substrate according to the first embodiment of the third group of the present disclosure.

FIG. 64 is a cross-sectional view showing the method for manufacturing the substrate according to the first embodiment of the third group of the present disclosure.

FIG. 65 is a cross-sectional view showing the method for manufacturing the substrate according to the first embodiment of the third group of the present disclosure.

FIG. 66 is a cross-sectional view showing the method for manufacturing the substrate according to the first embodiment of the third group of the present disclosure.

FIG. 67 is a plan view showing the method for manufacturing the substrate according to the first embodiment of the third group of the present disclosure.

FIG. 68 is a cross-sectional view taken along line LXVIII-LXVIII in FIG. 67.

FIG. 69 is a cross-sectional view showing the method for manufacturing the substrate according to the first embodiment of the third group of the present disclosure.

FIG. 70 is a cross-sectional view showing the method for manufacturing the substrate according to the first embodiment of the third group of the present disclosure.

FIG. 71 is a partially enlarged cross-sectional view showing the method for manufacturing the substrate according to the first embodiment of the third group of the present disclosure.

FIG. 72 is a cross-sectional view showing the method for manufacturing the substrate according to the first embodiment of the third group of the present disclosure.

FIG. 73 is a cross-sectional view showing the method for manufacturing the substrate according to the first embodiment of the third group of the present disclosure.

FIG. 74 is a cross-sectional view showing the method for manufacturing the substrate according to the first embodiment of the third group of the present disclosure.

FIG. 75 is a cross-sectional view showing the method for manufacturing the substrate according to the first embodiment of the third group of the present disclosure.

FIG. 76 is a cross-sectional view showing the method for manufacturing the substrate according to the first embodiment of the third group of the present disclosure.

FIG. 77 is a cross-sectional view showing the method for manufacturing the substrate according to the first embodiment of the third group of the present disclosure.

FIG. 78 is a cross-sectional view showing the method for manufacturing the substrate according to the first embodiment of the third group of the present disclosure.

FIG. 79 is a cross-sectional view showing the method for manufacturing the substrate according to the first embodiment of the third group of the present disclosure.

FIG. 80 is a plan view showing a semiconductor device according to the first embodiment of the third group of the present disclosure.

FIG. 81 is a cross-sectional view taken along line LXXXI-LXXXI in FIG. 80.

FIG. 82 is a cross-sectional view showing a first variation of the semiconductor device according to the first embodiment of the third group of the present disclosure.

FIG. 83 is a plan view showing a substrate according to a second embodiment of the third group of the present disclosure.

FIG. 84 is a plan view showing a semiconductor device according to a third embodiment of the third group of the present disclosure.

FIG. 85 is a cross-sectional view taken along line LXXXV-LXXXV in FIG. 84.

FIG. 86 is a cross-sectional view showing a method for manufacturing a substrate according to the third embodiment of the third group of the present disclosure.

FIG. 87 is a cross-sectional view showing the method for manufacturing the substrate according to the third embodiment of the third group of the present disclosure.

FIG. 88 is a cross-sectional view showing the method for manufacturing the substrate according to the third embodiment of the third group of the present disclosure.

FIG. 89 is a cross-sectional view showing the method for manufacturing the substrate according to the third embodiment of the third group of the present disclosure.

FIG. 90 is a cross-sectional view showing the method for manufacturing the substrate according to the third embodiment of the third group of the present disclosure.

FIG. 91 is a cross-sectional view showing the method for manufacturing the substrate according to the third embodiment of the third group of the present disclosure.

### MODE FOR CARRYING OUT THE INVENTION

The following describes preferred embodiments of the present disclosure in detail with reference to the drawings.

[First Group]

The following describes a first group of the present disclosure. The terms and reference signs in the first group of the present disclosure are defined independently from the terms and reference signs in the other groups.

The following describes a preferred embodiment of the first group of the present disclosure in detail with reference to the drawings. The drawings are illustrated schematically. Furthermore, parts of the drawings may be simplified or exaggerated.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Furthermore, the phrase “an object A overlaps with an object B as viewed in a certain direction” includes, unless otherwise specified, “an object A overlaps with the entirety of an object B” and “an object A overlaps with a portion of an object B”.

The terms such as “first”, “second” and “third” in the present disclosure are used merely as labels and not intended to impose orders on the elements accompanied with these terms.

### First Embodiment

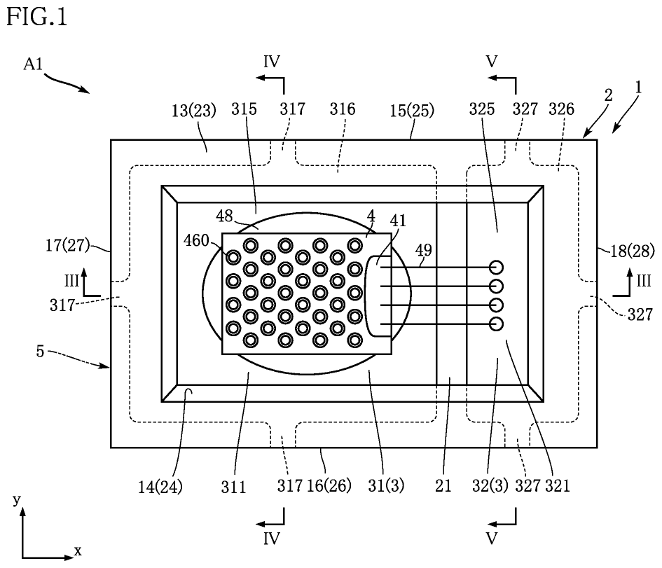

FIGS. 1 to 8 show a semiconductor light-emitting device according to a first embodiment the first group of the present disclosure. A semiconductor light-emitting device A1 of the present embodiment includes a support 1, a semiconductor light-emitting element 4, and a diffusion cover 5.

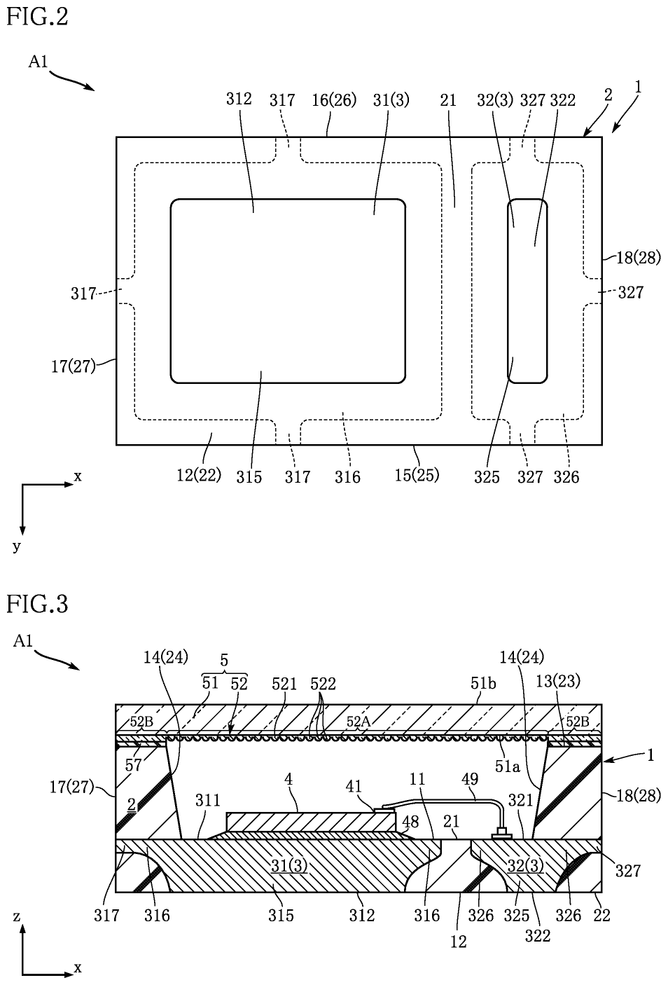

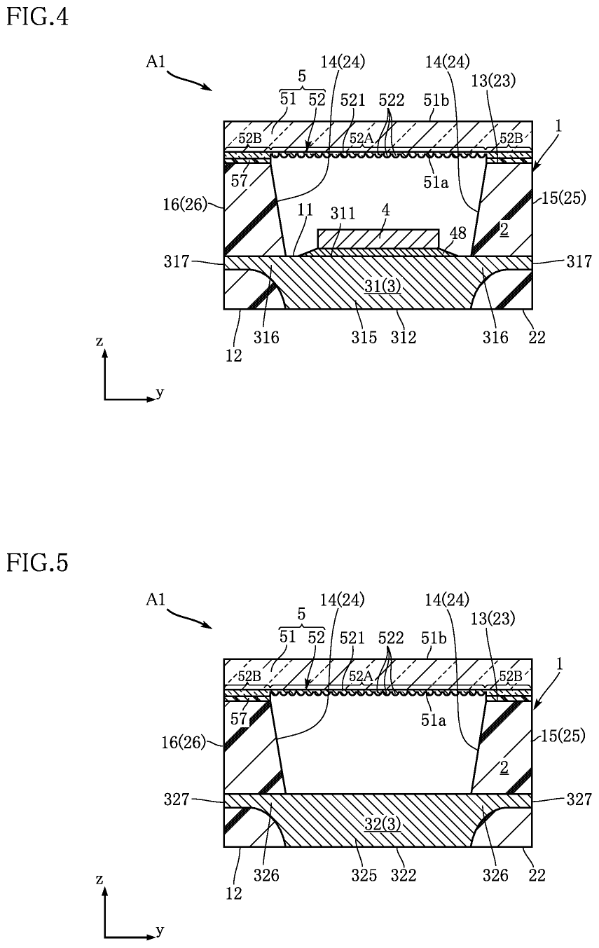

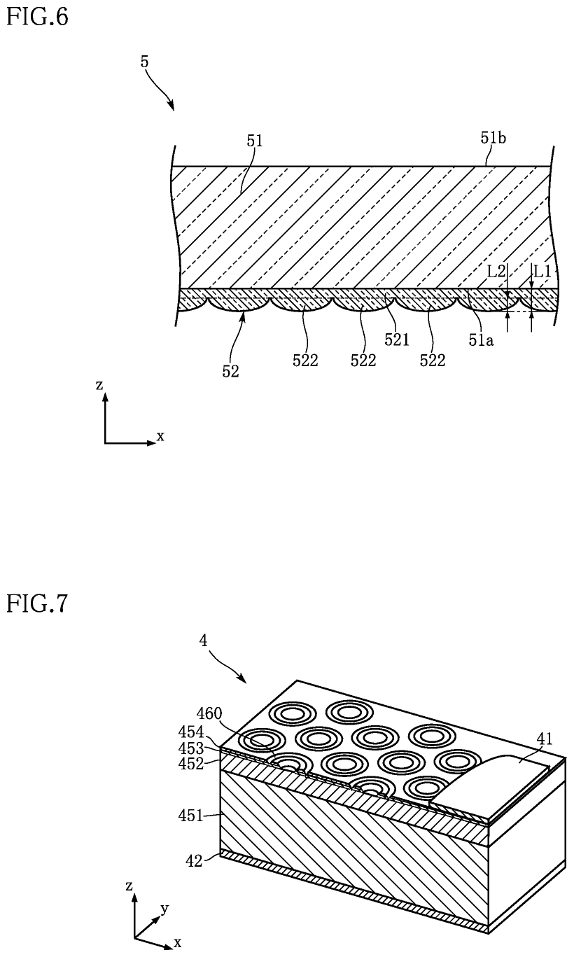

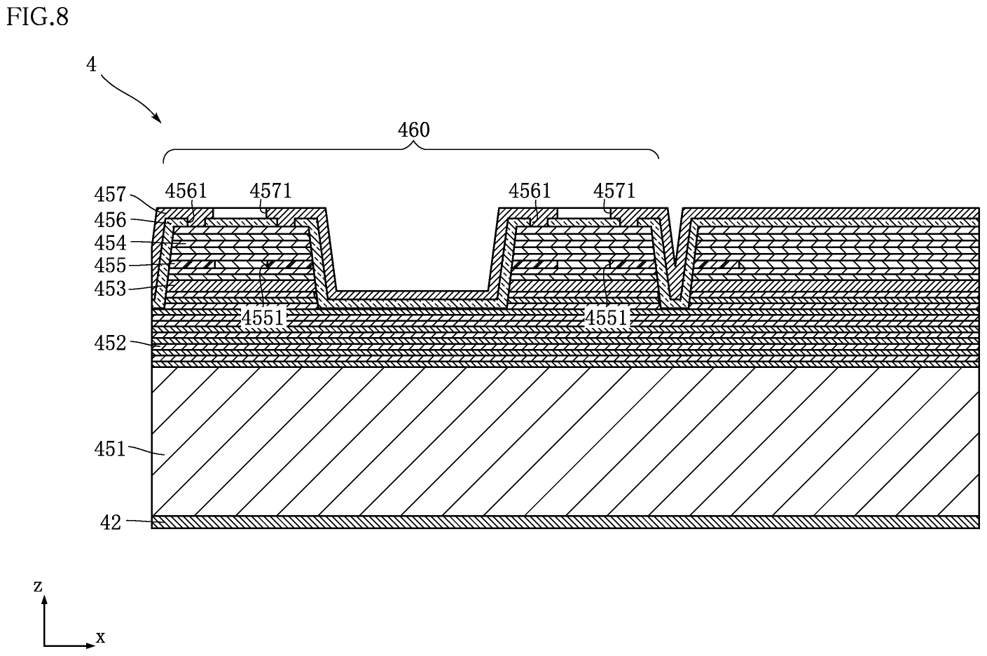

FIG. 1 is a partial plan view showing the semiconductor light-emitting device A1. FIG. 2 is a bottom view showing the semiconductor light-emitting device A1. FIG. 3 is a cross-sectional view taken along line III-III of FIG. 1. FIG. 4 is a cross-sectional view taken along line IV-IV of FIG. 1. FIG. 5 is a cross-sectional view taken along line V-V of FIG. 1. FIG. 6 is a partially enlarged cross-sectional view showing the semiconductor light-emitting device A1 in FIG. 3. FIG. 7 is an enlarged cross-sectional perspective view showing the semiconductor light-emitting element 4 of the semiconductor light-emitting device A1. FIG. 8 is a partially enlarged cross-sectional view showing the semiconductor light-emitting element 4 of the semiconductor light-emitting device A1. In these figures, the z direction corresponds to the thickness direction in the first group of the present disclosure. The y direction is perpendicular to the z direction, and the x direction is perpendicular to both the y direction and the z direction. Viewing a member along the z direction is referred to as plan view.

The support 1 of the present embodiment has a first surface 11, a second surface 12, a third surface 13, a fourth surface 14, a fifth surface 15, a sixth surface 16, a seventh surface 17, and an eighth surface 18.

The first surface 11 faces one side in the z direction (upper side in FIG. 3). The second surface 12 faces the other side in the z direction (lower side in FIG. 3), which is the side opposite from the side that the first surface 11 faces. The third surface 13 faces the one side in the z direction (upper side in FIG. 3), which is the same side as the side that the first surface 11 faces, and is spaced farther apart from the second surface 12 than the first surface 11 is from the second surface 12. The fourth surface 14 is located between the first surface 11 and the third surface 13, and is connected to the first surface 11 and the third surface 13 in the present embodiment. The fourth surface 14 has an annular shape surrounding the first surface 11 as viewed in the z direction. The fourth surface 14 is inclined such that the distance between opposing portions of the fourth surface 14 increases from the first surface 11 to the third surface 13 in the z direction.

The fifth surface 15 is located between the first surface 11 and the third surface 13 in the z direction, and faces one side in the y direction (right side in FIG. 4). In the illustrated example, the fifth surface 15 is connected to the first surface 11 and the third surface 13. The sixth surface 16 is located between the first surface 11 and the third surface 13 in the z direction, and faces the other side in the y direction (left side in FIG. 4). In the illustrated example, the sixth surface 16 is connected to the first surface 11 and the third surface 13. The seventh surface 17 is located between the first surface 11 and the third surface 13 in the z direction, and faces one side in the x direction (left side in FIG. 3). In the illustrated example, the seventh surface 17 is connected to the first surface 11 and the third surface 13. The eighth surface 18 is located between the first surface 11 and the third surface 13 in the z direction, and faces the other side in the x direction (right side in FIG. 3). In the illustrated example, the eighth surface 18 is connected to the first surface 11 and the third surface 13.

The configuration of the support 1 is not particularly limited. In the present embodiment, the support 1 includes an insulating member 2 and a conductive portion 3.

The insulating member 2 is made of a suitable insulating material, such as epoxy resin or silicone resin. The insulating member 2 of the present embodiment has a first surface 21, a second surface 22, a third surface 23, a fourth surface 24, a fifth surface 25, a sixth surface 26, a seventh surface 27, and an eighth surface 28.

The first surface 21 faces the one side in the z direction, and constitutes a portion of the first surface 11. The second surface 22 faces the other side in the z direction, and constitutes a portion of the second surface 12. The third surface 23 faces the one side in the z direction, and constitutes the third surface 13. The fourth surface 24 is provided between the first surface 21 and the third surface 23 in the z direction, and constitutes the fourth surface 14. The fifth surface 25 faces the one side in the y direction, and constitutes the fifth surface 15. The sixth surface 26 faces the other side in the y direction, and constitutes the sixth surface 16. The seventh surface 27 faces the one side in the x direction, and constitutes the seventh surface 17. The eighth surface 28 faces the other side in the x direction, and constitutes the eighth surface 18.

The conductive portion 3 forms a conductive path between the semiconductor light-emitting element 4 and the outside of the semiconductor light-emitting device A1. In the present embodiment, the conductive portion 3 includes a first lead 31 and a second lead 32. The first lead 31 and the second lead 32 are made of a metal such as Cu, Fe, or Ni.

The first lead 31 has a first surface 311, a second surface 312, a main portion 315, an edge portion 316, and a plurality of extending portions 317. The first surface 311 faces the one side in the z direction, and constitutes a portion of the first surface 11. As viewed in the z direction, a portion of the first surface 311 is exposed in the area surrounded by the fourth surface 14. The second surface 312 faces the other side in the z direction, which is the side opposite from the side that the first surface 311 faces, and constitutes a portion of the second surface 12. In the illustrated example, the second surface 312 is smaller than the first surface 311 and encompassed by the first surface 311 as viewed in the z direction.

The main portion 315 is a portion that has the first surface 311 and the second surface 312, and where the first surface 311 and the second surface 312 overlap with each other as viewed in the z direction. The edge portion 316 surrounds the main portion 315 as viewed in the z direction, and has a portion of the first surface 311. A portion of the edge portion 316 located on the other side in the z direction is covered with the insulating member 2. The plurality of extending portions 317 extend outward from the edge portion 316 as viewed in the z direction. Each of the extending portions 317 has a portion of the first surface 311. A portion of each extending portion 317 located on the other side in the z direction is covered with the insulating member 2. In the illustrated example, the first lead 31 has three extending portions 317. One of the extending portions 317 reaches the fifth surface 25 of the insulating member 2, and the end surface of the extending portion 317 is flush with and exposed from the fifth surface 25. Another one of the extending portions 317 reaches the sixth surface 26 of the insulating member 2, and the end surface of the extending portion 317 is flush with and exposed from the sixth surface 26. Yet another one of the extending portions 317 reaches the seventh surface 27 of the insulating member 2, and the end surface of the extending portion 317 is flush with and exposed from the seventh surface 27.

The second lead 32 is spaced apart from the first lead 31 to the other side in the x direction. The second lead 32 has a first surface 321, a second surface 322, a main portion 325, an edge portion 326, and a plurality of extending portions 327. The first surface 321 faces the one side in the z direction, and constitutes a portion of the first surface 11. As viewed in the z direction, a portion of the first surface 321 is exposed in the area surrounded by the fourth surface 14. The second surface 322 faces the other side in the z direction, which is the side opposite from the side that the first surface 321 faces, and constitutes a portion of the second surface 12. In the illustrated example, the second surface 322 is smaller than the first surface 321 and encompassed by the first surface 321 as viewed in the z direction.

The main portion 325 has the first surface 321 and the second surface 322, which overlap with each other as viewed in the z direction. The edge portion 326 surrounds the main portion 325 as viewed in the z direction, and has a portion of the first surface 321. A portion of the edge portion 326 located on the other side in the z direction is covered with the insulating member 2. The plurality of extending portions 327 extend outward from the edge portion 326 as viewed in the z direction. Each of the extending portions 327 has a portion of the first surface 321. A portion of each extending portion 327 located on the other side in the z direction is covered with the insulating member 2. In the illustrated example, the second lead 32 has three extending portions 327. One of the extending portions 327 reaches the fifth surface 25 of the insulating member 2, and the end surface of the extending portion 327 is flush with and exposed from the fifth surface 25. Another one of the extending portions 327 reaches the sixth surface 26 of the insulating member 2, and the end surface of the extending portion 327 is flush with and exposed from the sixth surface 26. Yet another one of the extending portions 327 reaches the eighth surface 28 of the insulating member 2, and the end surface of the extending portion 327 is flush with and exposed from the eighth surface 28.

The semiconductor light-emitting element 4 is a light source in the semiconductor light-emitting device A1, and emits light in a predetermined wavelength band. The semiconductor light-emitting element 4 is not particularly limited to having a specific configuration, but may be a semiconductor laser element or an LED element. In the present embodiment, the semiconductor light-emitting element 4 is a semiconductor laser element, specifically a vertical cavity surface emitting laser (VCSEL) element. The semiconductor light-emitting element 4 is die-bonded to the first surface 311 (first surface 11) of the first lead 31 of the conductive portion 3 by a conductive bonding material 48. The conductive bonding material 48 may be Ag paste or solder. The light from the semiconductor light-emitting element 4 is generally emitted to the one side in the z direction.

As shown in FIG. 1, the semiconductor light-emitting element 4 is provided with a first electrode 41 and a plurality of light-emitting regions 460 in plan view. The light-emitting regions 460 are separately disposed in an area of the semiconductor light-emitting element 4 excluding the first electrode 41 in plan view.

As shown in FIGS. 7 and 8, the semiconductor light-emitting element 4 of the present embodiment includes the first electrode 41, a second electrode 42, a substrate 451, a first semiconductor layer 452, an active layer 453, a second semiconductor layer 454, a current constriction layer 455, an insulating layer 456, and a conductive layer 457, and is formed with the light-emitting regions 460. The configuration shown in these figures is merely an example of a VCSEL element used as the semiconductor light-emitting element 4, and the semiconductor light-emitting element 4 is not limited to having this configuration. FIG. 8 is an enlarged view showing a portion including one of the light-emitting regions 460.

The substrate 451 is made of a semiconductor. The semiconductor that constitutes the substrate 451 is an n-type GaAs, for example. The semiconductor that constitutes the substrate 451 may be other than GaAs.

The active layer 453 is made of a compound semiconductor that emits light having a wavelength in a 980 nm band (hereinafter, “Aa”) by, for example, spontaneous emission and stimulated emission. The active layer 453 is located between the first semiconductor layer 452 and the second semiconductor layer 454. In the present embodiment, the active layer 453 is formed by a multiple quantum well structure in which an undoped GaAs well layer and an undoped AlGaAs barrier layer are alternately laminated. For example, an undoped Al_{0.35}Ga_{0.65}As barrier layer and an undoped GaAs well layer are alternately and repeatedly laminated for two to six cycles.

The first semiconductor layer 452 is typically a distributed bragg reflector (DBR) layer, and is formed on the substrate 451. The first semiconductor layer 452 is made of a semiconductor of a first conductive type. In the present example, the first conductive type is n-type. The first semiconductor layer 452 is configured as a DBR for efficiently reflecting light emitted from the active layer 453. The first semiconductor layer 452 is configured by stacking a plurality of pairs of layers, each of which is an AlGaAs layer having a thickness of λa/4 with a different reflectance. More specifically, the first semiconductor layer 452 may be configured by alternately and repeatedly stacking two AlGaAs layers for a plurality of cycles (e.g., 20 cycles), where one of the AlGaAs layers is an n-type Al_{0.16}Ga_{0.84}As layer (low Al composition layer) having a thickness of 600 Å and relatively low Al composition, for example, and the other is an n-type Al_{0.92}Ga_{0.16}As layer (high Al composition layer) having a thickness of 700 Å and relatively high Al composition, for example. The n-type Al_{0.16}Ga_{0.84}As layer and the n-type Al_{0.92}Ga_{0.16}As layer are doped with an n-type impurity (e.g., Si) in a concentration of, for example, 2×10¹⁷ cm⁻³ to 3×10¹⁸ cm⁻³ and in a concentration of 2×10¹⁷ cm⁻³ to 3×10¹⁸ cm⁻³, respectively.

The current constriction layer 455 is located within the second semiconductor layer 454. The current constriction layer 455 is made of a layer that contains a large amount of Al and is easily oxidized, for example. The current constriction layer 455 is formed by oxidizing the easily oxidizable layer. The current constriction layer 455 is not necessarily formed by oxidization, and may be formed by another method (e.g., ion implantation). The current constriction layer 455 is formed with an opening 4551. Current flows through the opening 4551.

The insulating layer 456 is formed on the second semiconductor layer 454. The insulating layer 456 may be made of SiO₂. The insulating layer 456 is formed with an opening 4561.

The conductive layer 457 is formed on the insulating layer 456. The conductive layer 457 is made of a conductive material (e.g., metal). The conductive layer 457 is electrically connected to the second semiconductor layer 454 via the opening 4561 of the insulating layer 456. The conductive layer 457 has an opening 4571.

The light-emitting region 460 is a region where light from the active layer 453 is emitted directly or after reflection. In the present example, the light-emitting region 460 has a circular ring shape in plan view, but the shape thereof is not particularly limited. The light-emitting region 460 is provided by stacking the second semiconductor layer 454, the current constriction layer 455, the insulating layer 456, and the conductive layer 457 and forming the opening 4551 of the current constriction layer 455, the opening 4561 of the insulating layer 456, the opening 4571 of the conductive layer 457, and so on. In the light-emitting region 460, light from the active layer 453 is emitted via the opening 4571 of the conductive layer 457.

The first electrode 41 is made of metal, and is electrically connected to the second semiconductor layer 454. The second electrode 42 is formed on a reverse surface of the substrate 451, and is made of metal, for example. The second electrode 42 is die-bonded to the first surface 311 with the conductive bonding material 48 such as a paste containing metal such as Ag, solder, or the like (see FIG. 3). As a result, the second electrode 42 is electrically connected to the first lead 31 of the conductive portion 3.

As shown in FIGS. 1 and 3, wires 49 are connected to the first electrode 41 of the semiconductor light-emitting element 4 and the first surface 321 of the second lead 32. The material of the wires 49 is not particularly limited. For example, the wires 49 are made of Au. In the present embodiment, four wires 49 are provided in parallel with each other. Note that the number of wires 49 and the arrangement thereof are not particularly limited.

The diffusion cover 5 covers the semiconductor light-emitting element 4 as viewed in the z direction, and diffuses and transmits light from the semiconductor light-emitting element 4. In the present embodiment, the diffusion cover 5 includes a base member 51 and a lens 52. The diffusion cover 5 is bonded to the third surface 13 (third surface 23) of the support 1 with a bonding material 57, for example. The bonding material 57 is an insulating adhesive made of a resin material, for example.

The base member 51 is made of a material, such as glass, that transmits light from the semiconductor light-emitting element 4. In the present embodiment, the base member 51 is made of a transparent glass substrate. The shape and other characteristics of the base member 51 are not particularly limited. In the present embodiment, the base member 51 has a rectangular shape.

The base member 51 has an obverse surface 51a and a reverse surface 51b. The obverse surface 51a and the reverse surface 51b face away from each other in the z direction. As shown in FIG. 3, the reverse surface 51b faces the one side in the z direction (upper side in FIG. 3). The obverse surface 51a faces the other side in the z direction (lower side in FIG. 3), so that the obverse surface 51a and the semiconductor light-emitting element 4 face each other. The obverse surface 51a and the reverse surface 51b are flat surfaces. In the illustrated example, each of the obverse surface 51a and the reverse surface 51b has a size that coincides with the size of the entirety of the base member 51 as viewed in the z direction. The base member 51 has a thickness (dimension in the z direction) of about 300 μm to 725 μm, for example, but the thickness of the base member 51 is not particularly limited.

The lens 52 is provided on the obverse surface 51a of the base member 51, and diffuses and transmits light from the semiconductor light-emitting element 4. The lens 52 is made of a transparent resin such as an acrylic resin.

As shown in FIGS. 3 to 6, the lens 52 has a base layer 521 and a plurality of lens members 522. The base layer 521 is in close contact with the obverse surface 51a of the base member 51, and is formed on the obverse surface 51a. In the present embodiment, the base layer 521 covers the entirety of the obverse surface 51a.

The lens members 522 have a function of diffusing light from the semiconductor light-emitting element 4. The lens members 522 are integrally connected to each other on the base layer 521, and are each a curved lens that protrudes to the other side in the z direction (the side that the obverse surface 51a faces). The lens members 522 are arranged in both the x direction and the y direction as viewed in the z direction to form a microlens array. The lens members 522 are formed by grayscale exposure and development as described below.

The dimensions of portions of the lens 52 shown in FIG. 6 are not particularly limited. As an example, a description is provided of a first dimension L1 and a second dimension L2. The first dimension L1 is the length of the lens 52 in the z direction. Specifically, the first dimension L1 is a distance between the apex of the lens 52 in the z direction (the point that protrudes most to the lower side in FIG. 6) and the bottom surface of the lens 52 (the surface opposite to the apex in the z direction). The second dimension L2 is the length of each lens member 522 in the z direction. Specifically, the second dimension L2 is the distance between the apex of the lens 52 in the z direction and the interface (shown by a dashed line in FIG. 6) between the base layer 521 and the lens members 522. The first dimension L1 is 1 μm to 10 μm, for example, and is preferably 2 μm to 7 μm. The second dimension L2 is 1 μm to 10 μm, for example, and is preferably 2 μm to 6 μm. Furthermore, the first dimension L1 is one to three times larger than the second dimension L2, for example.

In the present embodiment, the lens 52 shown in FIGS. 3 to 5 has a lens region 52A and a non-lens region 52B. The lens region 52A is a region of the lens 52 where the lens members 522 are formed. In the illustrated example, the lens region 52A is surrounded by the third surface 13 (third surface 23) of the support 1 as viewed in the z direction.

The non-lens region 52B is a region of the lens 52 where the lens members 522 are not formed. The non-lens region 52B surrounds the lens region 52A as viewed in the z direction. The non-lens region 52B is formed in a region corresponding to the third surface 13 (third surface 23) of the support 1. In the present embodiment, the diffusion cover 5 is arranged such that the non-lens region 52B faces the third surface 13 (third surface 23). The bonding material 57 is interposed between the third surface 13 (third surface 23) and the non-lens region 52B. The bonding material 57 is provided in a region that overlaps with the third surface 13 (third surface 23) and the non-lens region 52B as viewed in the z direction.

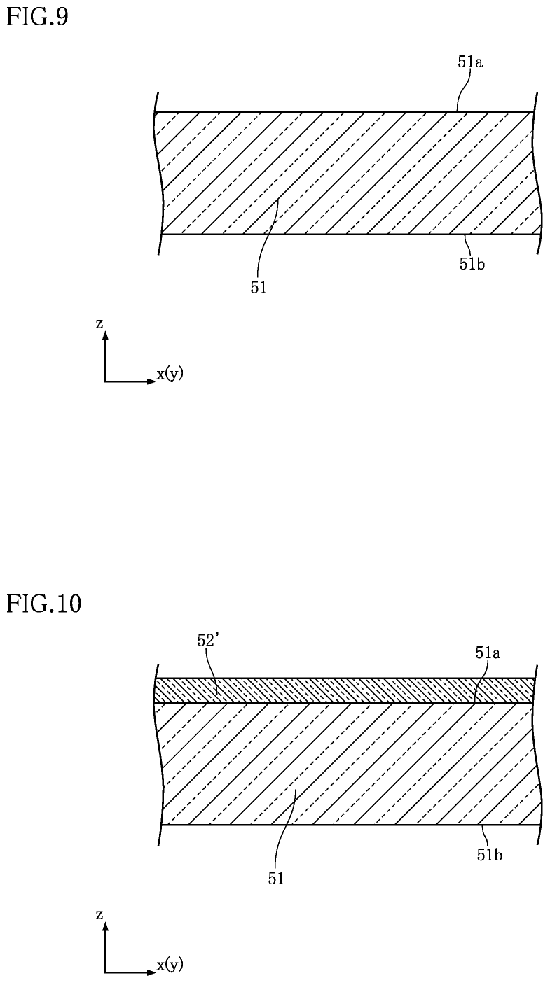

Next, an example of a method for manufacturing the diffusion cover 5 is described below with reference to FIGS. 9 to 12. Although these figures show a method for forming a single diffusion cover 5 to facilitate understanding, the present disclosure is not limited to this. A plurality of diffusion covers 5 may be manufactured by using a material that allows for manufacturing the diffusion covers 5 collectively and performing a suitable process such as a dividing process.

First, a base member 51 is prepared as shown in FIG. 9. The base member 51 is made of a transparent glass substrate, for example. The base member 51 has an obverse surface 51a and a reverse surface 51b. The obverse surface 51a and the reverse surface 51b face away from each other in the thickness direction of the base member 51.

Next, as shown in FIG. 10, a lens material 52′ is provided on the obverse surface 51a of the base member 51. The lens material 52′ is the material of a lens 52, and is made of a photosensitive transparent resin obtained by imparting positive photosensitivity to a transparent resin such as an acrylic resin. The lens material 52′ may be provided by, without limitation, applying a photosensitive transparent resin to the obverse surface 51a of the base member 51 to a predetermined thickness by spin coating and drying the photosensitive transparent resin. The thickness of the lens material 52′ is about the same as the first dimension L1 of the lens 52 in the z direction (thickness direction).

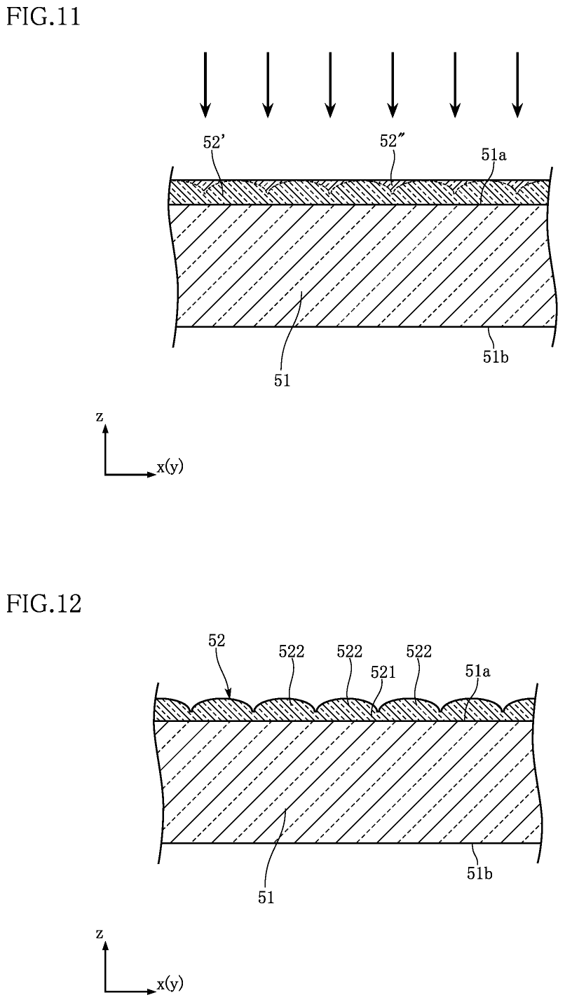

Next, as shown in FIG. 11, the lens material 52′ is subjected to exposure processing. In the present embodiment, the photosensitive transparent resin that constitutes the lens material 52′ has positive photosensitivity, and the exposure processing is performed by irradiation with light having a predetermined wavelength from the lens material 52′ side. Grayscale exposure is employed as the exposure processing. The grayscale exposure can be performed by various methods including a method of changing the intensity of light emitted to the lens material 52′ and a method of using a multi-gradation mask such as a gray tone mask. The exposure processing is performed on a region (lens region 52A) in which a plurality of lens members 522 are to be formed. An exposed portion (indicated by the reference sign 52″ in FIG. 11) of the lens material 52′, which is a portion subjected to the exposure processing (grayscale exposure), corresponds to the shape of each lens member 522.

Next, development processing is performed. The development processing removes a portion (exposed portion 52″) of the lens material 52′ and forms the lens members 522, as shown in FIG. 12. Next, heat processing is performed. As a result, a diffusion cover 5 in which the lens 52 is arranged on the obverse surface 51a of the base member 51 is formed.

Next, advantages of the present embodiment are described.

In the diffusion cover 5, the lens 52 made of a transparent resin has the lens members 522. The lens members 522 are formed by performing grayscale exposure and development on the lens material 52′ made of a photosensitive resin material and removing a portion of the lens material 52′. The configuration of the diffusion cover 5 as described above can reduce the manufacturing cost of the diffusion cover 5, as compared to the case where a plurality of lens members are formed with an imprinting apparatus, for example.

In the manufacturing of the diffusion cover 5, the photosensitive transparent resin that constitutes the lens material 52′ has positive photosensitivity. The grayscale exposure to the lens material 52′ formed on the base member 51 is performed by irradiation with light from the lens material 52′ side. Such a configuration makes it possible to form the lens members 522 appropriately from the lens material 52′ formed on the base member 51.

In the present embodiment, the lens members 522 are formed by grayscale exposure, which eliminates the need for embossing required in, for example, the imprinting technique. As a result, the first dimension L1 of the lens 52 in the z direction (thickness direction) can be as small as approximately 1 μm to 10 μm. This makes it possible to reduce the amount of the lens material 52′ used, and is thus suitable for reducing the manufacturing cost of the diffusion cover 5.

The lens 52 has the lens region 52A in which the lens members 522 are formed, and the non-lens region 52B in which the lens members 522 are not formed. The non-lens region 52B surrounds the lens region 52A as viewed in the z direction, and faces the third surface 13 (third surface 23) of the support 1. According to the configuration with the non-lens region 52B, light from the semiconductor light-emitting element 4 can be directed to the lens region 52A, and the diffusion cover 5 can be appropriately supported by the support 1.

<Variation of First Embodiment>

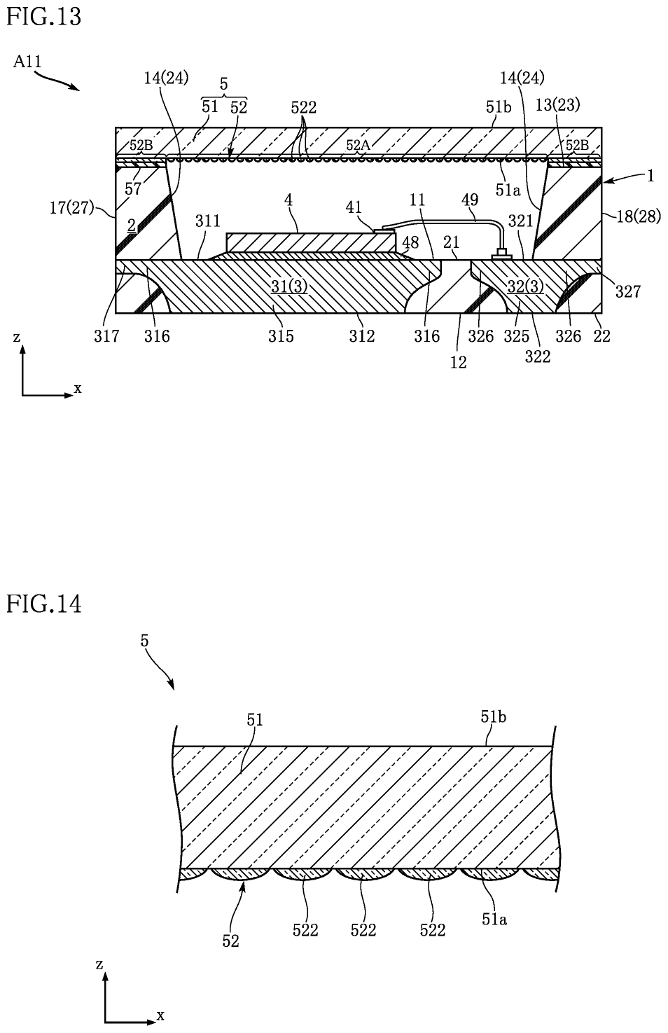

FIGS. 13 and 14 show a variation of the semiconductor light-emitting device A1 according to the first embodiment. From FIG. 13 onward, elements that are identical or similar to those of the semiconductor light-emitting device A1 in the above embodiment are designated by the same reference signs as in the above embodiment, and the descriptions thereof are omitted as appropriate.

A semiconductor light-emitting device A11 is different from the semiconductor light-emitting device A1 in the above embodiment in the configuration of the lens 52 of the diffusion cover 5. In the present variation, the lens members 522 of the lens 52 are formed directly on the obverse surface 51a of the base member 51. Unlike the above embodiment, the base layer 521 is not provided between the lens members 522 and the base member 51. A portion of the obverse surface 51a of the base member 51, which corresponds to the lens region 52A and where the lens members 522 are not formed, is not covered with the lens 52 and is exposed.

The lens 52 having such a configuration can be obtained by reducing the thickness of the lens material 52′ as compared to the thickness of the lens material 52′ in the above embodiment, during the forming step (see FIGS. 11 and 12) of the lens 52. It is also possible to obtain the lens 52 of the present variation by further deepening, along the z direction, the deepest spots of the exposed portion 52″ of the lens material 52′ by the grayscale exposure, without changing the positions in the x direction shown in FIG. 11, thereby expanding the deepened spots in the x direction and the y direction.

The semiconductor light-emitting device A11 of the present variation can also reduce the manufacturing cost of the diffusion cover 5, as compared to the case where a plurality of lens members are formed with an imprinting apparatus, for example. Furthermore, the semiconductor light-emitting device A11 also has the same advantages as those described above in connection with the semiconductor light-emitting device A1.

### Second Embodiment

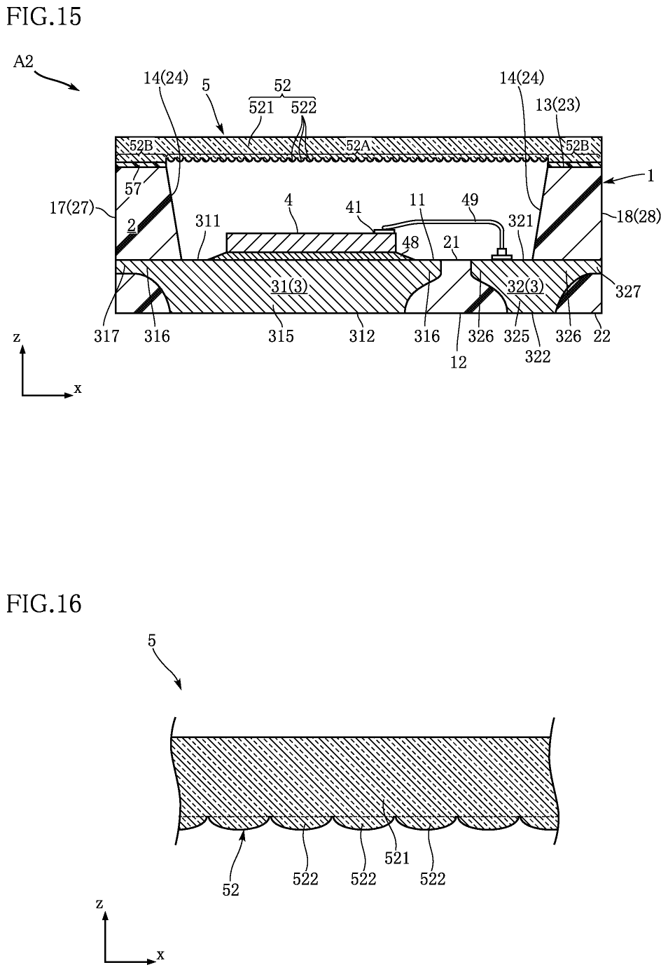

FIGS. 15 to 16 show a semiconductor light-emitting device according to a second embodiment of the first group of the present disclosure. A semiconductor light-emitting device A2 is different from the semiconductor light-emitting device A1 in the above embodiment in the configuration of the diffusion cover 5.

In the present embodiment, the diffusion cover 5 is not provided with the base member 51, and is configured with only the lens 52. The lens 52 includes the base layer 521 and the plurality of lens members 522. In the present embodiment, the dimension of the base layer 521 in the z direction is larger than that of the above embodiment.

Next, an example of a method for manufacturing the diffusion cover 5 of the present embodiment is described below with reference to FIGS. 17 to 20. Although these figures show a method for forming a single diffusion cover 5 to facilitate understanding, the present disclosure is not limited to this. A plurality of diffusion covers 5 may be manufactured by using a material with which the diffusion covers 5 can be manufactured collectively and performing a suitable process such as a dividing process.

First, a base member 91 is prepared as shown in FIG. 17. The base member 91 is made of a silicon substrate, for example. The base member 91 has an obverse surface 91a and a reverse surface 91b. The obverse surface 91a and the reverse surface 91b face away from each other in the thickness direction of the base member 91.

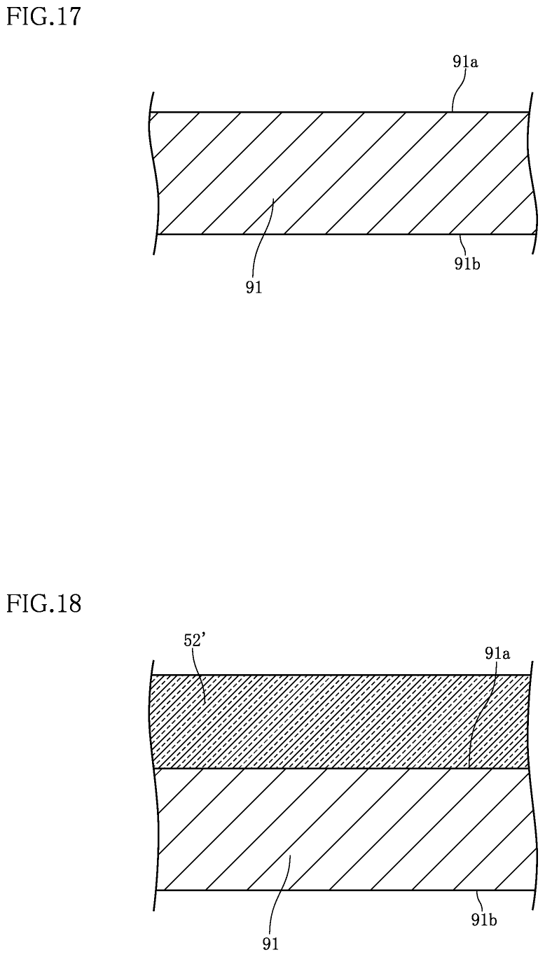

Next, as shown in FIG. 18, a lens material 52′ is formed on the obverse surface 91a of the base member 91. The lens material 52′ is the material of a lens 52, and is made of a photosensitive transparent resin obtained by imparting positive photosensitivity to a transparent resin such as an acrylic resin. The lens material 52′ may be formed by, without limitation, printing a thick film of a photosensitive transparent resin on the obverse surface 91a of the base member 91 and firing the film.

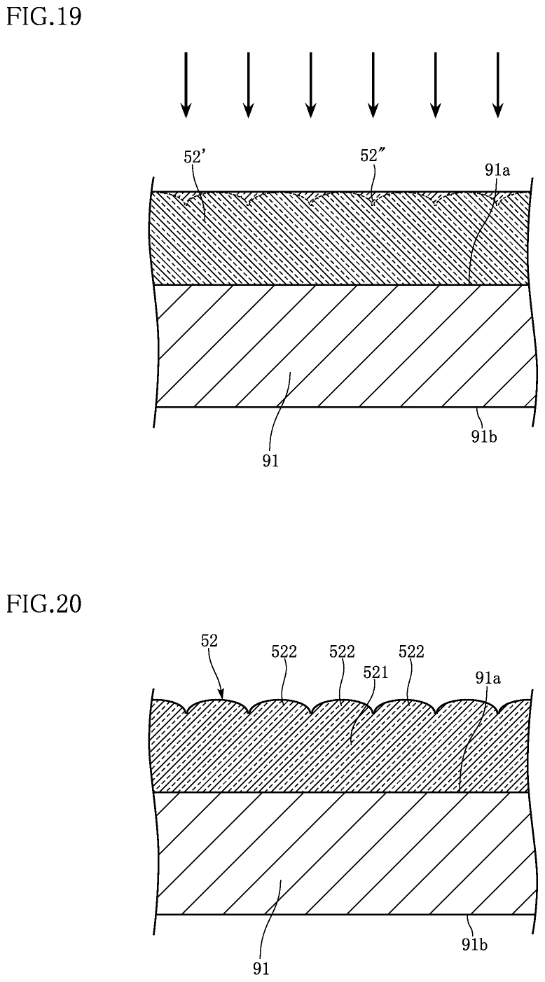

Next, as shown in FIG. 19, the lens material 52′ is subjected to exposure processing. In the present embodiment, the photosensitive transparent resin that constitutes the lens material 52′ has positive photosensitivity, and the exposure processing is performed by irradiation with light having a predetermined wavelength from the lens material 52′ side. Grayscale exposure is employed as the exposure processing. The grayscale exposure can be performed by various methods including a method of changing the intensity of light emitted to the lens material 52′ and a method of using a multi-gradation mask such as a gray tone mask. The exposure processing is performed on a region (lens region 52A) in which a plurality of lens members 522 are to be formed. An exposed portion 52″ of the lens material 52′, which is a portion subjected to the exposure processing (grayscale exposure), corresponds to the shape of each lens member 522.

Next, development processing is performed. The development processing removes a portion (exposed portion 52″) of the lens material 52′ and forms the lens members 522, as shown in FIG. 20. Next, heat processing is performed. As a result, the lens 52 is formed on the obverse surface 91a of the base member 91. Next, the lens 52 is peeled off from the base member 91. The lens 52 peeled off from the base member 91 as described above constitutes the diffusion cover 5.

The semiconductor light-emitting device A2 of the present embodiment can also reduce the manufacturing cost of the diffusion cover 5, as compared to the case where a plurality of lens members are formed with an imprinting apparatus, for example. Furthermore, the semiconductor light-emitting device A2 also has the same advantages as the semiconductor light-emitting device A1 within the range of the same configuration as the semiconductor light-emitting device A1.

The semiconductor light-emitting device according to the first group of the present disclosure is not limited to the above embodiments. Various design changes can be made to the specific configurations of the elements of the semiconductor light-emitting device according to the first group of the present disclosure.

The first group of the present disclosure includes the configurations relating to the following clauses A1 to A16.

Clause A1.

A method for manufacturing a diffusion cover that diffuses and transmits light from a semiconductor light-emitting element, the method comprising the steps of:

preparing a base member having an obverse surface and a reverse surface that face away from each other in a thickness direction;

forming a lens material on the obverse surface, the lens material containing a photosensitive transparent resin; and

removing a portion of the lens material by performing grayscale exposure and development, and forming a lens having a plurality of lens members.

Clause A2.

The method for manufacturing the diffusion cover according to clause A1,

wherein the photosensitive transparent resin has positive photosensitivity, and

the grayscale exposure is performed by irradiation with light from a side of the lens material.

Clause A3.

The method for manufacturing the diffusion cover according to clause A2, wherein the step of forming the lens includes forming a base layer covering the obverse surface, and forming the plurality of lens members such that each of the lens members connects to the base layer.

Clause A4.

The method for manufacturing the diffusion cover according to clause A2 or A3, wherein the base member includes a glass substrate.

Clause A5.

The method for manufacturing the diffusion cover according to clause A4, wherein the diffusion cover includes the base member and the lens.

Clause A6.

The method for manufacturing the diffusion cover according to clause A3,

wherein the base member includes a silicon substrate,

the method further comprises the step of peeling off the lens from the base member after the step of forming the lens, and

the diffusion cover includes the lens peeled off from the base member.

Clause A7.

A diffusion cover that diffuses and transmits light from a semiconductor light-emitting element, comprising:

a base member having an obverse surface and a reverse surface that face away from each other in a thickness direction; and

a lens arranged on the obverse surface, having a plurality of lens members protruding to the same side as a side that the obverse surface faces in the thickness direction, and containing a transparent resin.

Clause A8.

The diffusion cover according to clause A7,

wherein the lens has a base layer that is in close contact with the obverse surface, and

the plurality of lens members are integrally connected to each other on the base layer.

Clause A9.

The diffusion cover according to clause A8, wherein a first dimension, which is a length of the lens in the thickness direction, is 1 μm to 10 μm.

Clause A10.

The diffusion cover according to clause A9, wherein a second dimension, which is a length of each of the lens members in the thickness direction, is 1 μm to 10 μm.

Clause A11.

The diffusion cover according to clause A10, wherein the first dimension is one to three times larger than the second dimension.

Clause A12.

The diffusion cover according to any of clauses A7 to A11, wherein the base member includes a glass substrate.

Clause A13.

A semiconductor light-emitting device comprising:

a semiconductor light-emitting element;

a support that supports the semiconductor light-emitting element; and

the diffusion cover according to any of clauses A7 to A12, the diffusion cover overlapping with the semiconductor light-emitting element as viewed in the thickness direction.

Clause A14.

The semiconductor light-emitting device according to clause A13,

wherein the support has a first surface, a second surface, a third surface, and a fourth surface, the semiconductor light-emitting element being arranged on the first surface, the first surface facing in the thickness direction, the second surface facing in a direction opposite from the direction in which the first surface faces, the third surface facing in the same direction as the first surface, being spaced farther apart from the second surface than the first surface is from the second surface, and surrounding the first surface as viewed in the thickness direction, the fourth surface being provided between the first surface and the third surface, and

the diffusion cover is supported by the third surface.

Clause A15.

The semiconductor light-emitting device according to clause A14,

wherein the lens has a lens region in which the plurality of lens members are formed, and a non-lens region that surrounds the lens region as viewed in the thickness direction and in which the plurality of lens members are not formed, and

the diffusion cover is arranged such that the non-lens region faces the third surface.

Clause A16.

The semiconductor light-emitting device according to any of clauses A13 to A15, wherein the semiconductor light-emitting element is a VCSEL element.

[Second Group]

The following describes a second group of the present disclosure. The terms and reference signs in the second group of the present disclosure are defined independently from the terms and reference signs in the other groups.

The following describes a preferred embodiment of the second group of the present disclosure, which relates to a wiring board, an electronic device, and a method for manufacturing the wiring board, with reference to the drawings. In the following description, elements that are the same as or similar to the elements described above are provided with the same reference signs, and descriptions thereof are omitted.

### First Embodiment

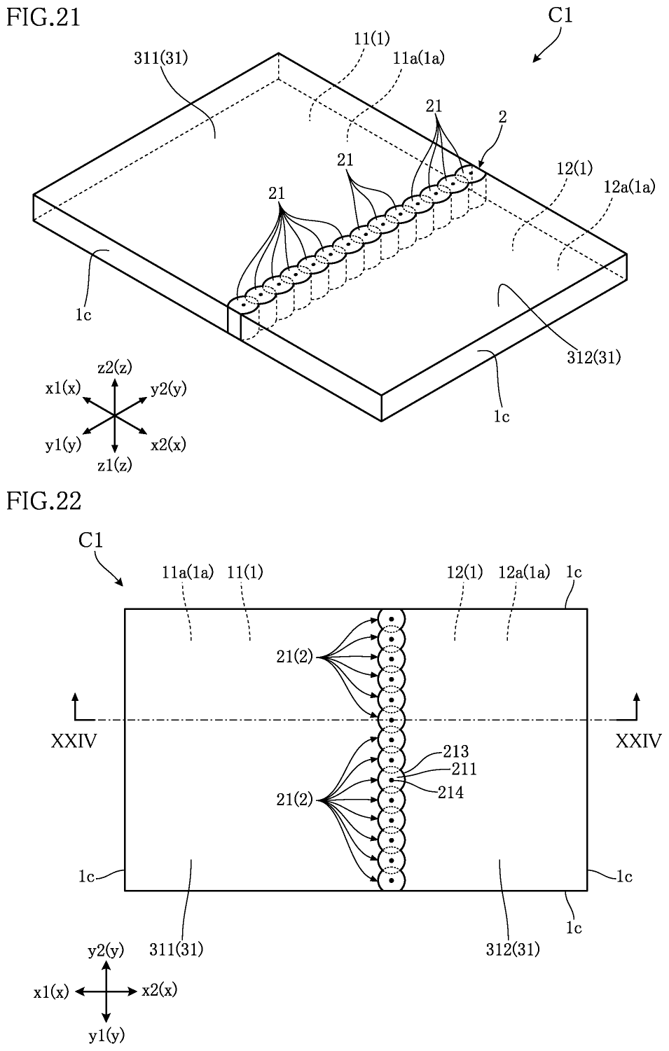

FIGS. 21 to 25 show a wiring board C1 according to a first embodiment of the second group of the present disclosure. The wiring board C1 includes a base member 1, an insulating portion 2, an obverse-surface electrode 31, and a reverse-surface electrode 32.

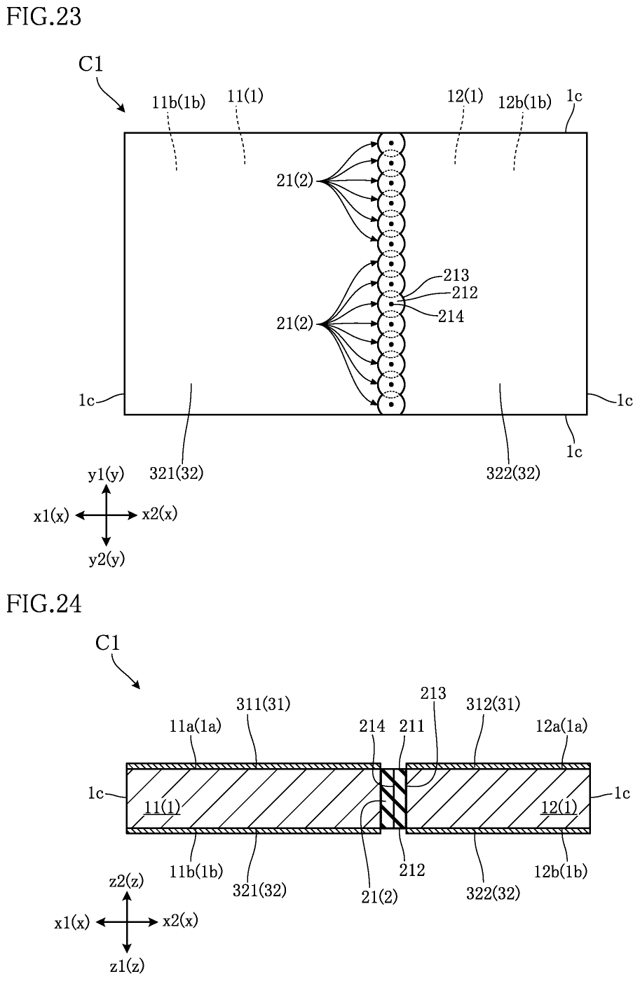

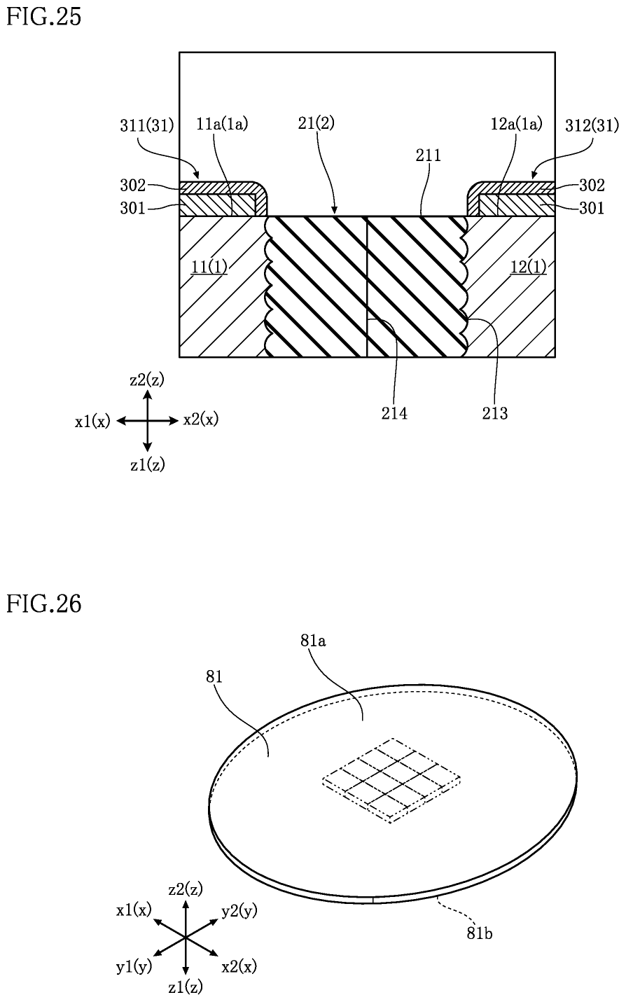

FIG. 21 is a perspective view showing the wiring board C1. FIG. 22 is a plan view showing the wiring board C1. FIG. 23 is a bottom view showing the wiring board C1. FIG. 24 is a cross-sectional view taken along line XXIV-XXIV of FIG. 22. FIG. 25 is an enlarged cross-sectional view showing a portion of FIG. 24.

For convenience, three directions that are perpendicular to each other are defined as x direction, y direction, and z direction, respectively. The z direction is the thickness direction of the wiring board C1. The x direction is the horizontal direction in the plan view (see FIG. 22) of the wiring board C1. The y direction is the vertical direction in the plan view (see FIG. 22) of the wiring board C1. One side in the x direction is referred to as x1 direction, and the other side in the x direction is referred to as x2 direction. Similarly, one side in the y direction is referred to as y1 direction, the other side in the y direction is referred to as y2 direction, one side in the z direction is referred to as z1 direction, and the other side in the z direction is referred to as z2 direction. In the following description, a “plan view” is a view seen in the z direction.

Electronic components and the like are mounted on the wiring board C1. The wiring board C1 is a member that, together with electronic components and the like, constitutes an electronic device, and that allows the electronic device to be mounted on a circuit board. The wiring board C1 is plate-like, and has a rectangular shape, for example, in plan view.

The base member 1 contains a semiconductor material. For example, the base member 1 mainly contains single-crystal silicon (Si), and is doped with an impurity to increase conductivity. The impurity is a p-type impurity such as boron (B), aluminum (Al), or gallium (Ga). Although the constituent material of the base member 1 is not particularly limited, it is preferable that the base member 1 mainly contain Si. This is because a bonding technique for Si is established, and Si is relatively cheap. Note that a semiconductor material doped with an n-type impurity may be used to make the base member 1. In the example shown in FIGS. 22 and 23, the base member 1 has a rectangular shape in plan view.

The base member 1 has an obverse surface 1a, a reverse surface 1b, and a plurality of side surfaces 1c. The obverse surface 1a and the reverse surface 1b are spaced apart from each other in the z direction. The obverse surface 1a and the reverse surface 1b are flat, for example, and are substantially perpendicular to the z direction. The obverse surface 1a faces in the z2 direction, and the reverse surface 1b faces in the z1 direction. The lattice plane of the obverse surface 1a is a (100) plane, for example. The side surfaces 1c are connected to the obverse surface 1a and the reverse surface 1b, and are sandwiched between the obverse surface 1a and the reverse surface 1b in the z direction. Since the base member 1 has a rectangular shape in plan view, the base member 1 has four 22 side surfaces 1c, as shown in FIGS. 22 and 23. Two of the four side surfaces 1c are spaced apart from each other in the x direction and face in opposite directions, and the other two of the side surfaces 1c are spaced apart from each other in the y direction and face in opposite directions.

The base member 1 includes a first portion 11 and a second portion 12. The first portion 11 and the second portion 12 are separated and insulated from each other by the insulating portion 2. In the present embodiment, the first portion 11 is shifted in the x1 direction relative to the insulating portion 2, and the second portion 12 is shifted in the x2 direction relative to the insulating portion 2. In the example shown in FIGS. 22 and 23, each of the first portion 11 and the second portion 12 has a rectangular shape in plan view.

The first portion 11 has a first obverse surface 11a and a first reverse surface 11b. The first obverse surface 11a and the first reverse surface 11b are spaced apart from each other in the z direction. The first obverse surface 11a faces in the z2 direction, and the first reverse surface 11b faces in the z1 direction. The second portion 12 has a second obverse surface 12a and a second reverse surface 12b. The second obverse surface 12a and the second reverse surface 12b are spaced apart from each other in the z direction. The second obverse surface 12a faces in the z2 direction, and the second reverse surface 12b faces in the z1 direction. The first obverse surface 11a and the second obverse surface 12a constitute the obverse surface 1a. The first reverse surface 11b and the second reverse surface 12b constitute the reverse surface 1b.

The insulating portion 2 separates the first portion 11 and the second portion 12. The insulating portion 2 is made of an insulating material, such as an oxide of the constituent material of the base member 1. In the example where the main component of the base member 1 is Si, the insulating portion 2 may be made of SiO₂(silicon oxide). In the present embodiment, the insulating portion 2 is linear in plan view. The insulating portion 2 is continuous in the y direction in plan view, and extends from the side surface 1c in the y1 direction to the side surface 1c in the y2 direction.

The insulating portion 2 includes a plurality of through portions 21. The through portions 21 penetrate through the base member 1 in the z direction from the obverse surface 1a to the reverse surface 1b. Each of the through portions 21 has a substantially circular cross section that is perpendicular to the z direction. The through portions 21 are aligned in the y direction in plan view, and two adjacent through portions 21 are connected to each other in plan view. As such, the through portions 21 are connected to each other to form the insulating portion 2.

Each of the through portions 21 has an obverse surface 211, a reverse surface 212, a side surface 213, and a boundary portion 214. The obverse surface 211 and the reverse surface 212 are spaced apart from each other in the z direction. The obverse surface 211 faces in the z2 direction, and the reverse surface 212 faces in the z1 direction. The obverse surface 211 is substantially flush with the obverse surface 1a (the first obverse surface 11a and the second obverse surface 12a). The reverse surface 212 is substantially flush with the reverse surface 1b (the first reverse surface 11b and the second reverse surface 12b). The side surface 213 is connected to the obverse surface 211 and the reverse surface 212, and is sandwiched between the obverse surface 211 and the reverse surface 212 in the z direction. The side surface 213 has a ribbed structure, and is wavy as viewed in a direction perpendicular to the z direction. The boundary portion 214 is located substantially at the center of the through portion 21 in plan view. The boundary portion 214 extends in the z direction, for example, and is continuous from the obverse surface 211 to the reverse surface 212. The boundary portion 214 is a trace formed in the manufacturing method described below.

The obverse-surface electrode 31 covers the obverse surface 1a of the base member 1. The obverse-surface electrode 31 includes a first obverse-surface covering portion 311 and a second obverse-surface covering portion 312. The first obverse-surface covering portion 311 covers the first obverse surface 11a (first portion 11). The second obverse-surface covering portion 312 covers the second obverse surface 12a (second portion 12).

The reverse-surface electrode 32 covers the reverse surface 1b of the base member 1. The reverse-surface electrode 32 includes a first reverse-surface covering portion 321 and a second reverse-surface covering portion 322. The first reverse-surface covering portion 321 covers the first reverse surface 11b (first portion 11). The second reverse-surface covering portion 322 covers the second reverse surface 12b (second portion 12). The reverse-surface electrode 32 is used as an external electrode when the wiring board C1 is mounted on a circuit board of an electronic device, for example.

Since the base member 1 (the first portion 11 and the second portion 12) is made of a semiconductor material, the first obverse-surface covering portion 311 and the first reverse-surface covering portion 321 are electrically connected to each other via the first portion 11. The second obverse-surface covering portion 312 and the second reverse-surface covering portion 322 are electrically connected to each other via the second portion 12. In the present embodiment, in particular, the base member 1 is subjected to a process for increasing conductivity (doping with an impurity). As a result, the electrical connection is improved between the first obverse-surface covering portion 311 and the first reverse-surface covering portion 321, and also between the second obverse-surface covering portion 312 and the second reverse-surface covering portion 322.

In the present embodiment, each of the obverse-surface electrode 31 and the reverse-surface electrode 32 includes a first metal layer 301 and a second metal layer 302 stacked in the z direction, for example, as shown in FIG. 25. The obverse-surface electrode 31 and the reverse-surface electrode 32 may have different structures.

The first metal layer 301 is in contact with the base member 1. That is, the first metal layer 301 is stacked on each of the obverse surface 1a (the first obverse surface 11a and the second obverse surface 12a) and the reverse surface 1b (the first reverse surface 11b and the second reverse surface 12b). The constituent material of the first metal layer 301 contains Al, for example. The constituent material of the first metal layer 301 is not limited to Al, and the first metal layer 301 may include a plurality of metal layers stacked on each other.

The second metal layer 302 is stacked on and in contact with the first metal layer 301. The second metal layer 302 is a surface layer of each of the obverse-surface electrode 31 and the reverse-surface electrode 32. The second metal layer 302 includes a gold (Au) layer, a nickel (Ni) layer, a silver (Ag) layer, and a Au layer stacked in this order on the first metal layer 301. The configuration of the second metal layer 302 is not limited to the example above. For example, the second metal layer 302 may include a Ni layer and a Au layer stacked in this order on the first metal layer 301, or may include a Ni layer, a palladium (Pd) layer, and a Au layer stacked in this order from the side in contact with the first metal layer 301. Each of the obverse-surface electrode 31 and the reverse-surface electrode 32 may be col posed of a single metal layer (e.g., a Au layer) instead of two metal layers (the first metal layer 301 and the second metal layer 302) stacked on each other.

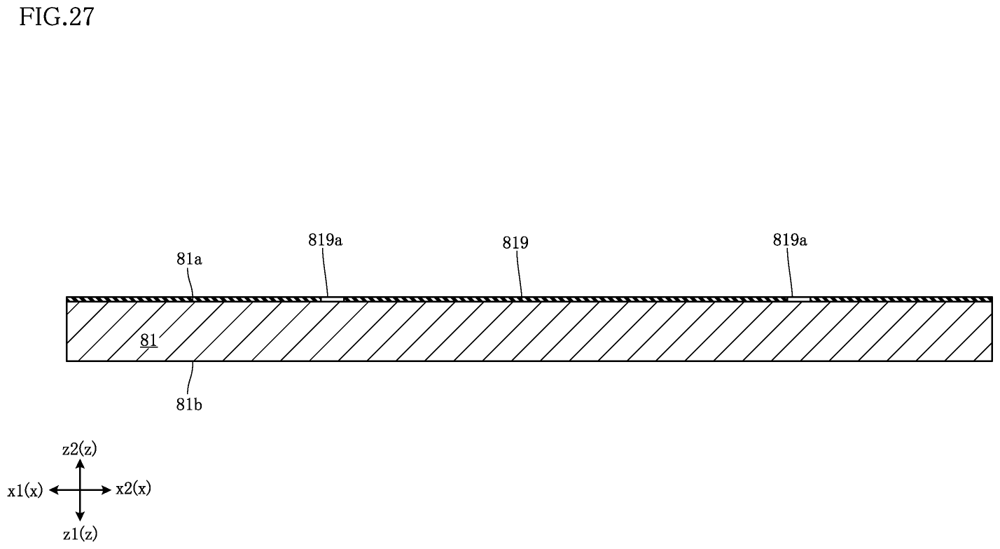

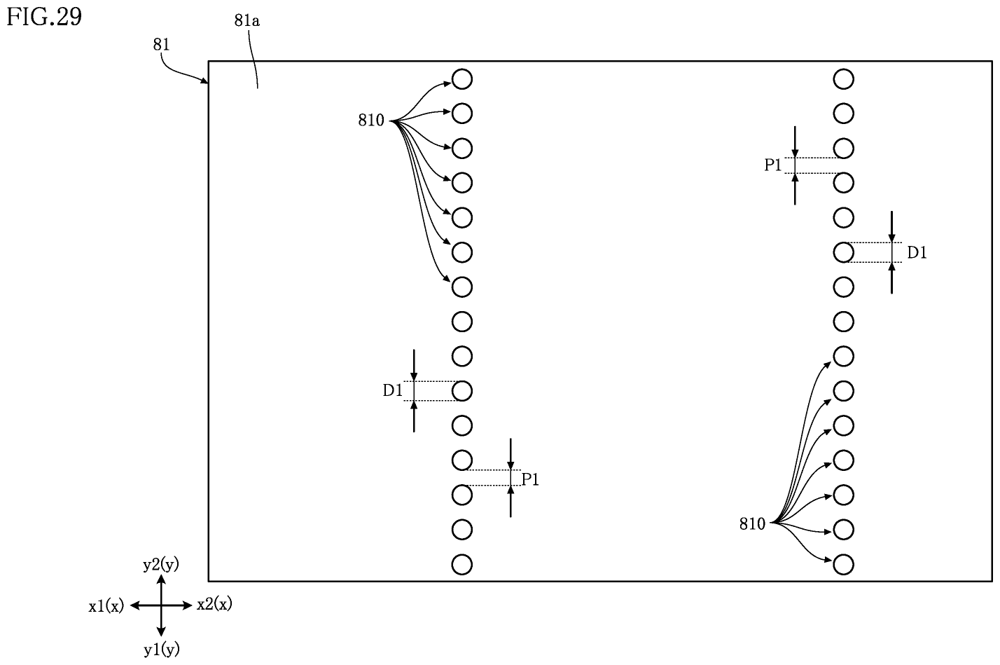

Next, a method for manufacturing the wiring board C1 is described below with reference to FIGS. 26 to 37. Each of FIGS. 26 to 37 shows a step of the method for manufacturing the wiring board C1. FIG. 26 is a perspective view showing a step of the manufacturing method. Each of FIGS. 27, 28, 30, 31, 33, 35, and 36 is a cross-sectional view showing a step of the manufacturing method. The cross-sectional views correspond to the cross section of the wiring board C1 shown in FIG. 24. Each of FIGS. 29, 32, 34, and 37 is a plan view showing a step of the manufacturing method. For convenience of understanding, the size of each component shown in FIGS. 26 to 37 is appropriately increased relative to the size of each component shown in FIGS. 21 to 25.

First, a semiconductor wafer 81 is prepared as shown in FIG. 26. In the step of preparing the semiconductor wafer 81 (wafer preparation step), a p-type impurity is added when a single-crystal Si ingot is created, and then the ingot is sliced thinly to form the semiconductor wafer 81. As shown in FIG. 26, the semiconductor wafer 81 has a wafer obverse surface 81a and a wafer reverse surface 81b. The wafer obverse surface 81a and the wafer reverse surface 81b are spaced apart from each other in the z direction. The wafer obverse surface 81a and the wafer reverse surface 81b are substantially flat and substantially perpendicular to the z direction. The wafer obverse surface 81a faces in the z2 direction, and the wafer reverse surface 81b faces in the z1 direction. The semiconductor wafer 81 shown in FIG. 26 has a circular shape in plan view, but may be formed with a notch, an orientation flat, or the like. FIG. 27 and the subsequent figures only show an area corresponding to four wiring boards C1.

Next, as shown in FIGS. 27 to 34, insulating portions 82 are formed in the semiconductor wafer 81. The step of forming the insulating portions 82 (insulating portion formation step) includes three steps, namely a through-hole formation step, a thermal oxidation step, and a grinding step.

In the through-hole formation step, a plurality of through-holes 810 are formed in the semiconductor wafer 81, as shown in FIGS. 27 to 30. The through-hole formation step may include the following three steps.

In a first step of the through-hole formation step, a resist film 819 is patterned by photolithography, for example, as shown in FIG. 27. Specifically, the resist film 819 is formed on substantially the entirety of the wafer obverse surface 81a of the semiconductor wafer 81, and then, the resist film 819 is subjected to exposure and etching appropriately so that the resist film 819 is patterned. The resist film 819 thus patterned has openings 819a as shown in FIG. 27, and portions of the semiconductor wafer 81 (wafer obverse surface 81a) where the plurality of through-holes 810 are to be formed are exposed from the openings 819a.

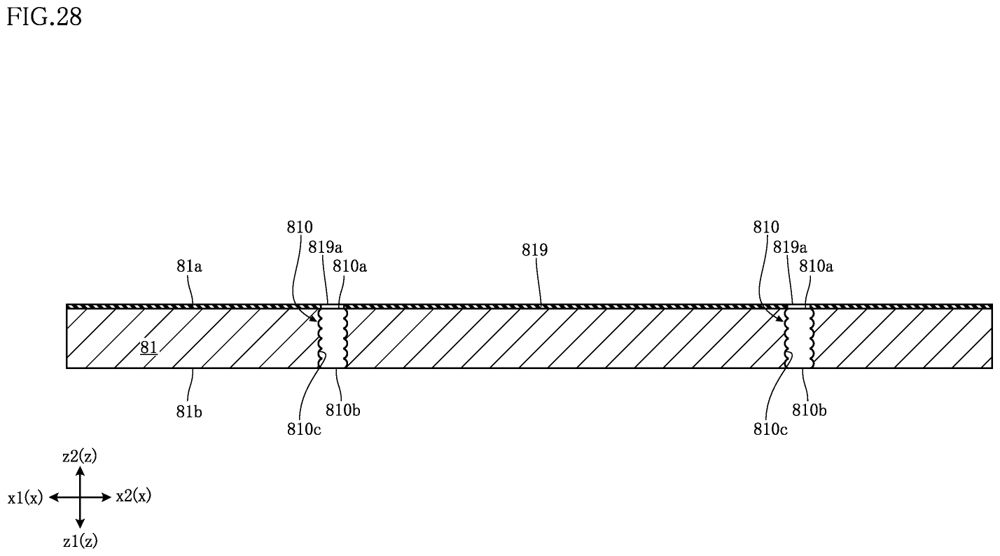

In a second step of the through-hole formation step, the portions of the semiconductor wafer 81 exposed from the resist film 819 are etched to form the through-holes 810, as shown in FIG. 28. The etching may be performed by deep RIE (Reactive Ion Etching), which is one of the reactive etching techniques. Note that the etching may be performed with a technique other than deep RIE.

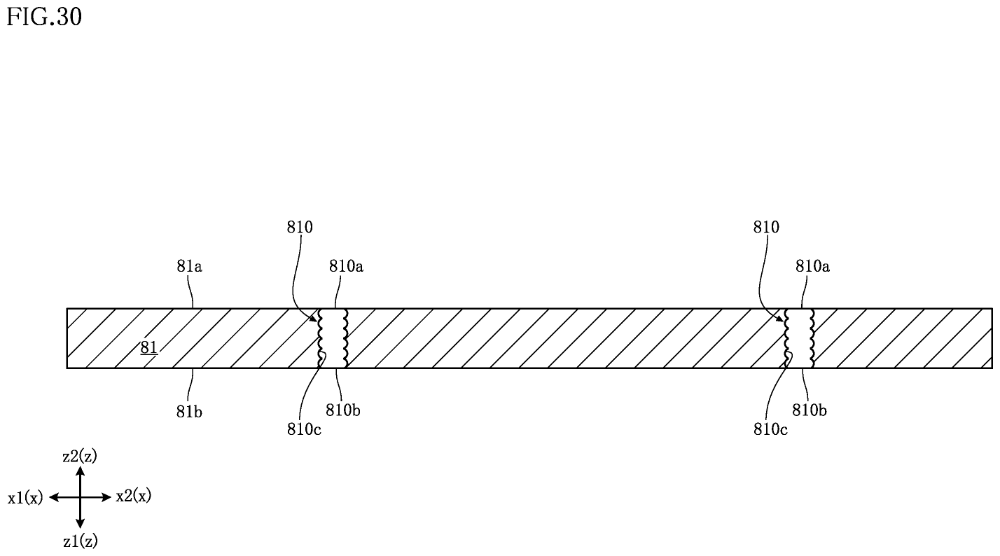

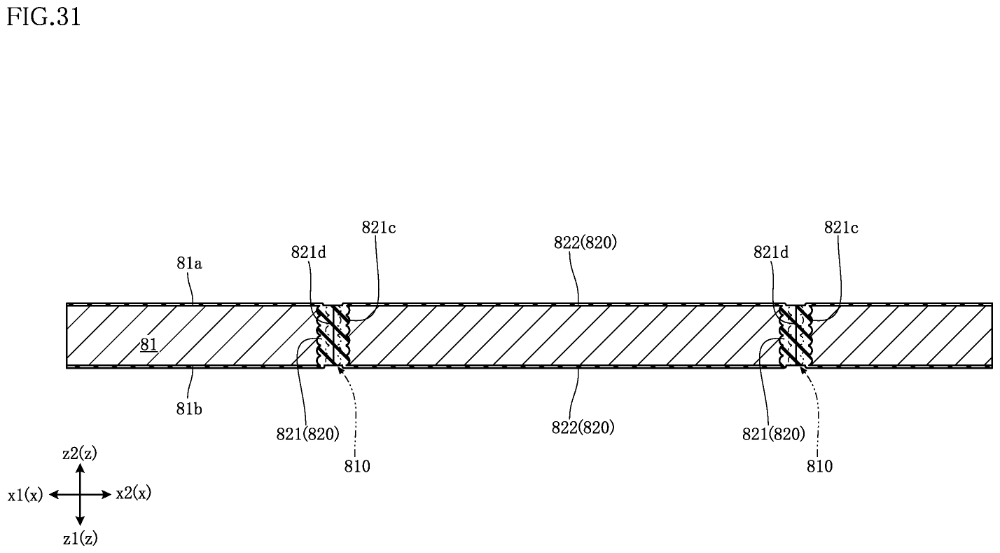

In a third step of the through-hole formation step, the resist film 819 is removed as shown in FIGS. 29 and 30. The method for removing the resist film 819 is not particularly limited.

Through the above three steps (through-hole formation step), the plurality of through-holes 810 are formed in the semiconductor wafer 81. As shown in FIG. 30, each of the through-holes 810 has a pair of openings 810a and 810b, and a peripheral wall 810c. The opening 810a is open in the wafer obverse surface 81a, and the opening 810b is open in the wafer reverse surface 81b. Each of the pair of openings 810a and 810b has a circular shape in plan view. The peripheral wall 810c is connected to the pair of openings 810a and 810b. Since the through-holes 810 are formed by deep RIE, the peripheral walls 810c have a ribbed structure called “scallop”. As shown in FIG. 29, the through-holes 810 are aligned in the y direction. Two through-holes 810 adjacent in the y direction are arranged at a predetermined interval P1. The interval P1 is not particularly limited, but may be about 0.5 μm to 4.0 μm (preferably about 0.9 μm), for example. Accordingly, the through-holes 810 are separated from each other. Each of the through-holes 810 has a diameter D1 of about 1 μm to 3 μm in plan view.

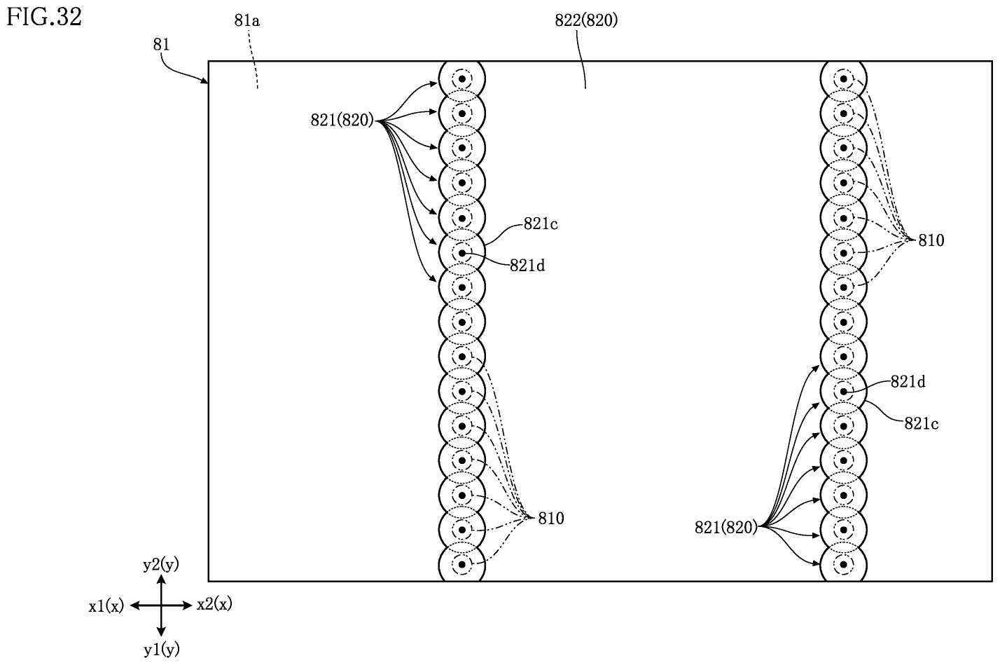

As shown in FIGS. 31 and 32, in the thermal oxidation step, the semiconductor wafer 81 is thermally oxidized to form an oxidation film 820. The oxidation film 820 is an oxide of the constituent material of the semiconductor wafer 81. The oxidation film 820 thus formed includes a plurality of through portions 821 and a surface portion 822. At this point, the through portions 821 and the surface portion 822 are connected to each other. As shown in FIGS. 31 and 32, each of the through portions 821 has a side surface 821c and a boundary portion 821d. The side surfaces 821c correspond to the side surfaces 213 of the wiring board C1, and the boundary portions 821d correspond to the boundary portions 214 of the wiring board C1. When the semiconductor wafer 81 is thermally oxidized, the oxidation film 820 is formed on the surface of the semiconductor wafer 81 exposed to the outside air. At this point, the oxidation film 820 is formed from the peripheral walls 810c of the through-holes 810 to the insides and outsides of the through-holes 810 in the radial direction in plan view. Due to the oxidation film 820 formed to the insides of the through-holes 810 in the radial direction, the through-holes 810 are filled with the through portions 821. During the growth of the oxidation film 820 to the inside of each through-hole 810 in the radial direction, a portion of the oxidation film 820 growing from the peripheral wall 810c in the x2 direction and a portion of the oxidation film 820 growing from the peripheral wall 810c in the x1 direction are in contact with each other near the center of the through-hole 810 in plan view, but these portions of the oxidation film 820 are not integrated to each other. As a result, the boundary portion 821d is formed in the through portion 821. Furthermore, since the oxidation film 820 is formed toward the outside of each through-hole 810 in the radial direction, two adjacent through portions 821 are connected to each other. In this regard, the larger the interval P1, the longer the time required for continuously forming the oxidation film 820 by thermal oxidation until two adjacent through portions 821 are connected to each other. Accordingly, it is preferable that the interval P1 be approximately 0.9 μm, as described above.

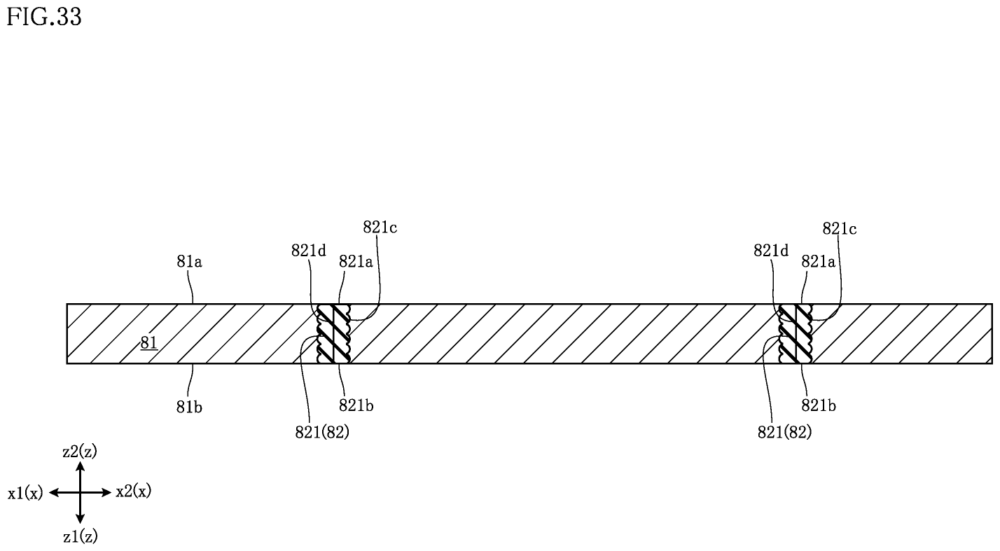

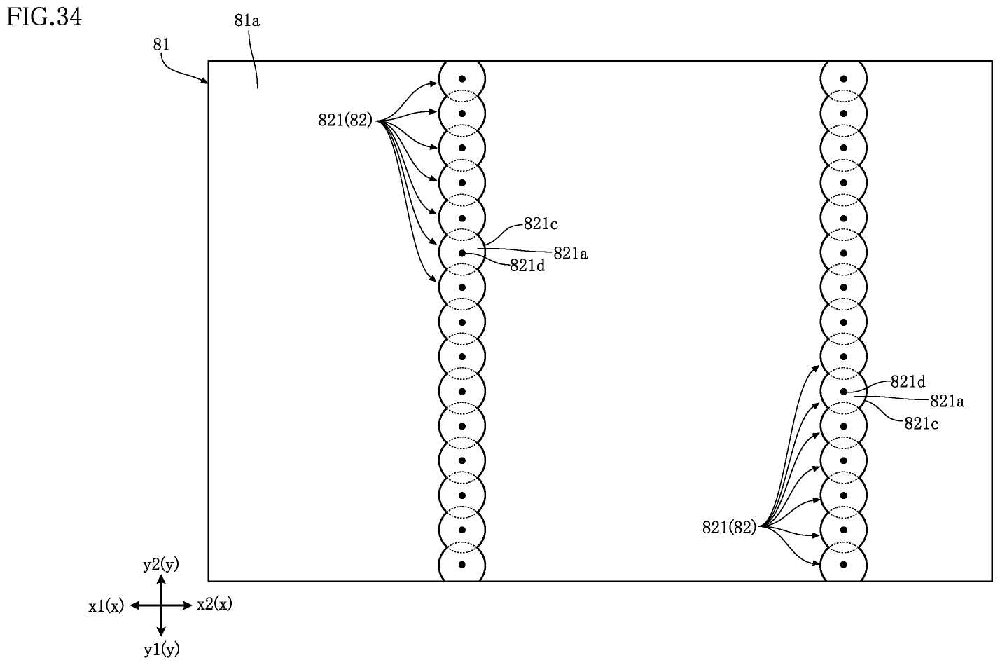

In the grinding step, the surface portions 822 formed on the wafer obverse surface 81a and the wafer reverse surface 81b of the semiconductor wafer 81 are ground, as shown in FIGS. 33 and 34. The wafer obverse surface 81a and the wafer reverse surface 81b are exposed as a result of the grinding step. At this point, the semiconductor wafer 81 may also be ground along with the grinding of the surface portion 822 in order to adjust (reduce) the thickness of the semiconductor wafer 81. As a result of the grinding step, an obverse surface 821a that is substantially flush with the wafer obverse surface 81a and a reverse surface 821b that is substantially flush with the wafer reverse surface 81b are formed for each of the through portions 821.

Through the through-hole formation step, the thermal oxidation step, and the grinding step, the insulating portions 82 are formed in the semiconductor wafer 81, as shown in FIGS. 33 and 34. The insulating portions 82 penetrate through the semiconductor wafer 81 from the wafer obverse surface 81a to the wafer reverse surface 81b in the z direction. Each of the insulating portions 82 is formed by the through portions 821 connected to each other.

Next, an obverse-surface electrode 831 and a reverse-surface electrode 832 are formed, as shown in FIGS. 35 to 37. The step of forming the obverse-surface electrode 831 (obverse-surface electrode formation step) and the step of forming the reverse-surface electrode 832 (reverse-surface electrode formation step) each include a first metal layer formation step and a second metal layer formation step.

In the first metal layer formation step, a first metal layer 830a that covers the wafer obverse surface 81a and the wafer reverse surface 81b is formed, as shown in FIG. 35. The first metal layer formation step begins by forming a metal film on the entirety of each of the wafer obverse surface 81a and the wafer reverse surface 81b by, for example, sputtering or vapor deposition. The constituent material of the metal film is Al, for example. Then, the metal film is patterned by photolithography. As a result, the first metal layer 830a is formed. The first metal layer 830a is not formed on the surfaces of the insulating portions 82 (the obverse surface 821a and the reverse surface 821b of each through portion 821).

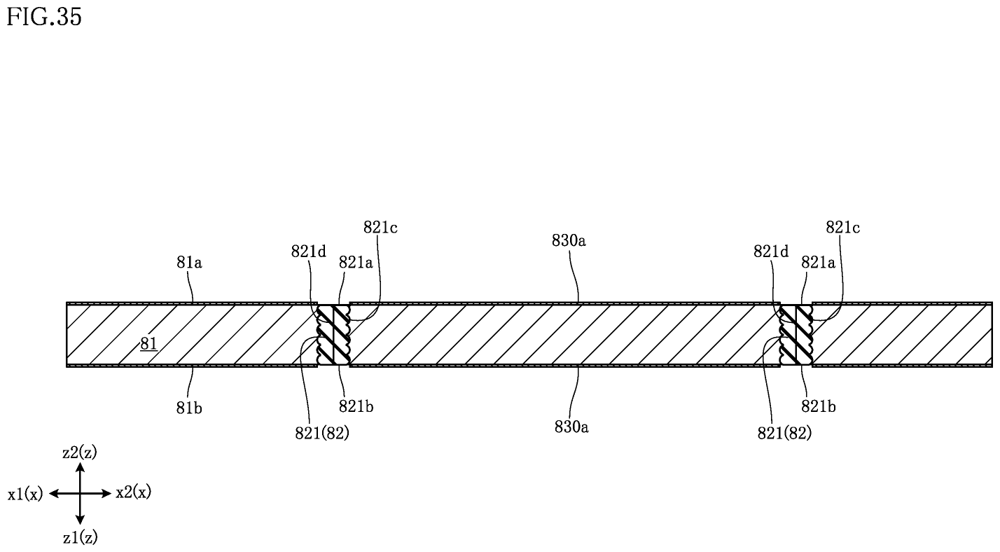

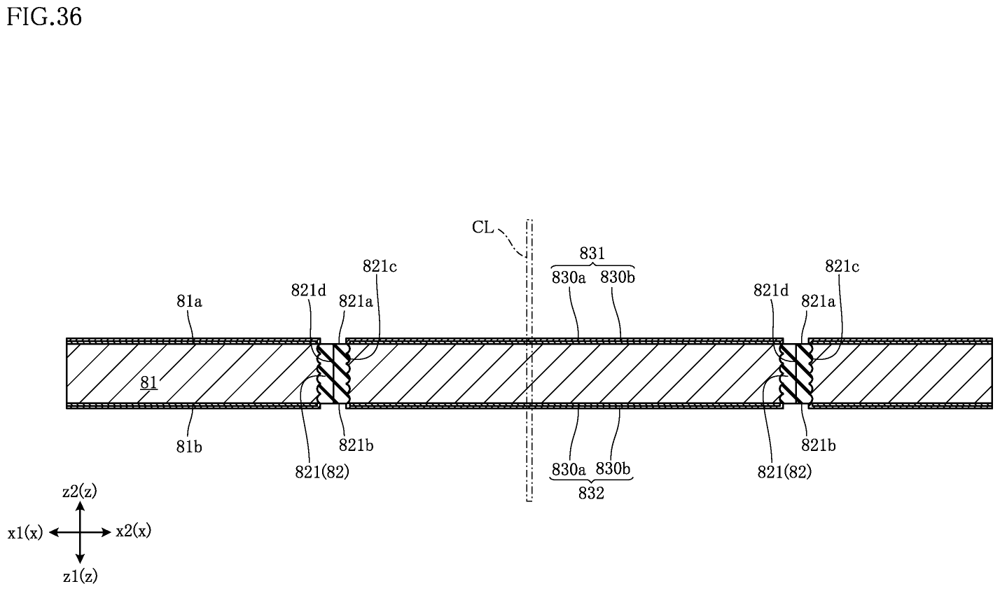

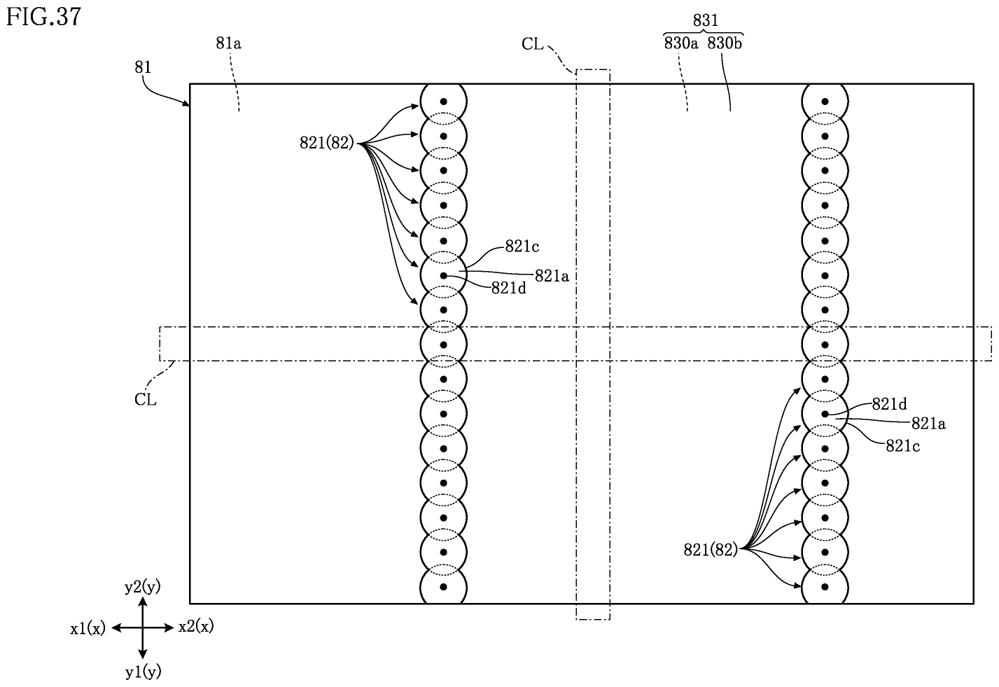

In the second metal layer formation step, a second metal layer 830b that covers the first metal layer 830a is formed, as shown in FIGS. 36 and 37. The second metal layer formation step is performed by electroless plating, for example. For example, a Au layer is deposited to be in contact with the first metal layer 830a by electroless plating, and then a Ni layer, a Ag layer, and a Au layer are deposited in this order. Accordingly, in the present embodiment, the second metal layer 830b includes a plurality of stacked metal layers, and may be formed by stacking a Au layer, a Ni layer, a Ag layer, and a Au layer in this order on the first metal layer 830a. The second metal layer formation step is modified appropriately according to the configuration of the second metal layer 302 of the wiring board C1.

Through the first metal layer formation step and the second metal layer formation step, the obverse-surface electrode 831 and the reverse-surface electrode 832 that each include the first metal layer 301 and the second metal layer 302 are formed. In other words, the obverse-surface electrode forming step and the reverse-surface electrode forming step are collectively performed by going through the first metal layer formation step and the second metal layer formation step. It is possible to first perform one of the obverse-surface electrode forming step and the reverse-surface electrode forming step and then perform the other.

Next, the semiconductor wafer 81 is cut along a cut line CL shown in FIGS. 36 and 37, for example, so that the semiconductor wafer 81 is diced into pieces that each have a final product shape. The semiconductor wafer 81 may be cut with a dicing blade, for example. In FIGS. 36 and 37, the cut line CL has a band shape in consideration of the thickness of the dicing blade.

Through the above steps, the wiring board C1 as shown in FIGS. 21 to 25 is manufactured. In other words, the wiring board C1 including the base member 1 (the first portion 11 and the second portion 12), the insulating portion 2 (the through portions 21), the obverse-surface electrode 31, and the reverse-surface electrode 32 is manufactured.

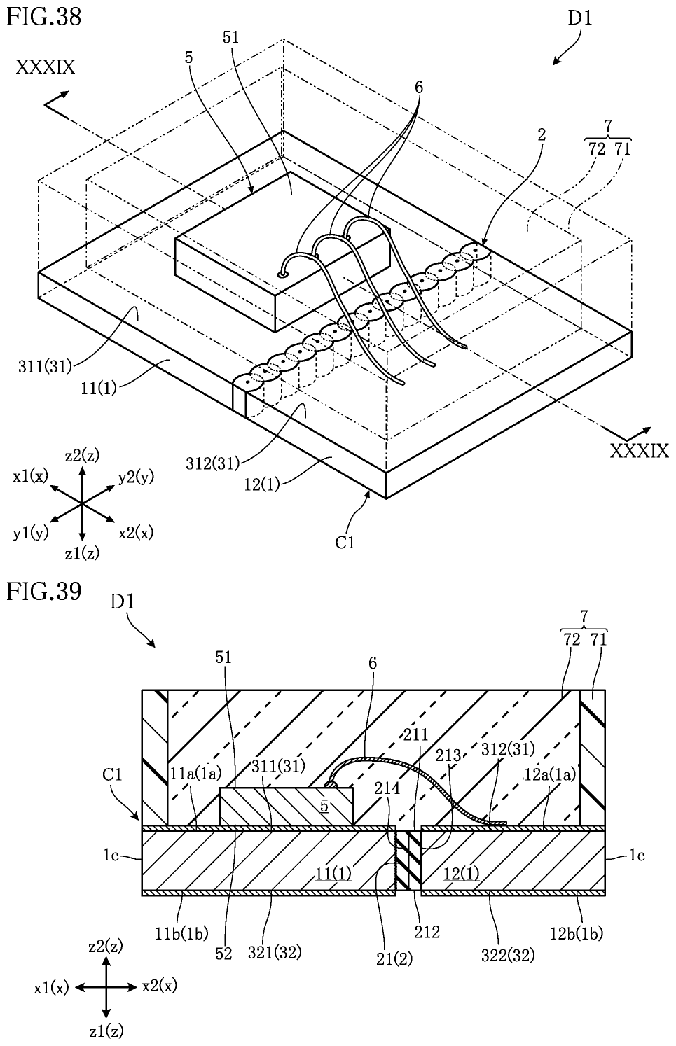

Next, an example of use of the wiring board C1 is described with reference to FIGS. 38 and 39. FIG. 38 is a perspective view showing an electronic device D1 including the wiring board C1. FIG. 39 is a cross-sectional view taken along line XXXIX-XXXIX in FIG. 38. The electronic device D1 includes the wiring board C1, an electronic component 5, a plurality of bonding wires 6, and a resin member 7. To facilitate understanding, FIG. 38 shows the resin member 7 with an imaginary line (two-dot chain line).

The electronic component 5 exhibits an electrical function of the electronic device D1. The electronic component 5 is a VCSEL element, for example. The electronic component 5 (VCSEL element) emits light in a predetermined wavelength band, and serves as the light source of the electronic device D1. The electronic component 5 is not limited to a VCSEL element, and may be another light-emitting element such as an LED element, a semiconductor element (active element) such as a transistor, a diode, or an IC, or a passive element such as a resistor, a capacitor, or an inductor. It is preferable that the electronic component 5 be one having a large heat generation property among light-emitting elements and power active elements.

The electronic component 5 has an obverse surface 51 and a reverse surface 52. The obverse surface 51 and the reverse surface 52 are spaced apart from each other in the z direction. A plurality of light-emitting regions are formed on the obverse surface 51. An electrode is provided on each of the obverse surface 51 and the reverse surface 52. When voltage is applied across the respective electrodes on the obverse surface 51 and the reverse surface 52, the electrodes are energized to emit light. The light is resonated inside and emitted as laser light from the light-emitting regions.

The electronic component 5 is mounted on the first portion 11 with the reverse surface 52 facing the first obverse surface 11a (first portion 11). The electrode on the reverse surface 52 of the electronic component 5 is bonded to the first obverse-surface covering portion 311 via a conductive bonding material. As a result, the electrode on the reverse surface 52 of the electronic component 5 and the first obverse-surface covering portion 311 (obverse-surface electrode 31) are electrically connected to each other via the bonding material. The first obverse-surface covering portion 311 is used as a die pad in the electronic device D1. Since the first obverse-surface covering portion 311 is electrically connected to the first reverse-surface covering portion 321 (reverse-surface electrode 32) via the first portion 11, the electrode on the reverse surface 52 of the electronic component 5 is electrically connected to the first reverse-surface covering portion 321 (reverse-surface electrode 32). The first reverse-surface covering portion 321 is used as a terminal (e.g., cathode terminal) of the electronic device D1.

The bonding wires 6 are connected to the electrode on the obverse surface 51 of the electronic component 5, and to the second obverse-surface covering portion 312 (obverse-surface electrode 31) of the wiring board C1. As a result, the electrode on the obverse surface 51 of the electronic component 5 and the second obverse-surface covering portion 312 (obverse-surface electrode 31) are electrically connected to each other via the bonding wires 6. The second obverse-surface covering portion 312 is used as a wire bonding pad in the electronic device D1. The material, thickness, number, and so on of the bonding wires 6 are not particularly limited. Since the second obverse-surface covering portion 312 is electrically connected to the second reverse-surface covering portion 322 (reverse-surface electrode 32) via the second portion 12, the electrode on the obverse surface 51 of the electronic component 5 is electrically connected to the second reverse-surface covering portion 322 (reverse-surface electrode 32). The second reverse-surface covering portion 322 is used as another terminal (e.g., anode terminal) of the electronic device D1.

The resin member 7 is a sealing member formed on the wiring board C1 and protecting the electronic component 5 and the bonding wires 6. The resin member 7 includes an outer wall portion 71 and a light-transmitting portion 72.

The outer wall portion 71 surrounds the electronic component 5 in plan view. The outer wall portion 71 is formed to have a frame shape surrounding the light-transmitting portion 72 in plan view. The outer wall portion 71 is made of an insulating resin. The insulating resin may be a thermosetting resin that mainly contains black epoxy resin.

The light-transmitting portion 72 is formed in the opening of the outer wall portion 71, and covers the electronic component 5 and the bonding wires 6. The light-transmitting portion 72 is translucent and electrically insulative. The light-transmitting portion 72 is made of silicone resin, for example. The laser light emitted from the light-emitting regions on the obverse surface 51 of the electronic component 5 passes through the light-transmitting portion 72 and is emitted to the outside. Unlike the electronic device D1, in a configuration where the electronic component 5 is not a light-emitting element, the light-transmitting portion 72 is not necessary, and the same constituent material as that of the outer wall portion 71 may cover the electronic component 5 and the bonding wires 6.

The electronic device D1 is mounted on a circuit board of an electronic device or the like (not shown). The first reverse-surface covering portion 321 and the second reverse-surface covering portion 322 are bonded to the circuit wiring formed on the circuit board via solder or the like. The heat generated by the electronic component 5 is released to the circuit board via the wiring board C1.

Advantages of the wiring board C1 and the method for manufacturing the same are described below.

The wiring board C1 includes the base member 1 made of a semiconductor material. In this way, the wiring board C1 can achieve electrical connection between the obverse surface 1a and the reverse surface 1b (e.g., electrical connection between the obverse-surface electrode 31 and the reverse-surface electrode 32) without providing a through-hole in the base member 1. In other words, the base member 1 of the wiring board C1 does not need a through-hole for electrically connecting the obverse surface 1a and the reverse surface 1b. Accordingly, the wiring board C1 can reduce the number of manufacturing man-hours as compared to the conventional wiring board (described in Patent Document 2). As described above, the wiring board C1 can reduce the manufacturing cost.

The wiring board C1 includes the insulating portion 2. The insulating portion 2 separates the base member 1 into the first portion 11 and the second portion 12. This makes it possible to pattern the wiring on the wiring board C1, as with a conventional wiring board. For example, in the electronic device D1 shown in FIGS. 38 and 39, the first portion 11 is configured as a die pad (island), and the second portion 12 is configured as a wire bonding pad.

Regarding the wiring board C1, the constituent material of the base member 1 mainly contains Si, which is a semiconductor material. In other words, the main constituent material of the wiring board C1 is Si. Since Si is cheaper than aluminum nitride (AlN), the wiring board C1 can reduce the material cost as compared to a conventional wiring board (ALN substrate). Furthermore, since Si has a relatively high thermal conductivity (which is approximately the same thermal conductivity as AlN), almost the whole of the wiring board C1 serves as a heat dissipation path for the heat generated by the electronic component 5. Accordingly, the wiring board C1 has approximately the same heat dissipation property as the ALN substrate. In short, the wiring board C1 can electrically connect the obverse surface 1a of the base member 1 and the reverse surface 1b thereof, and has approximately the same heat dissipation property as the ALN substrate. In particular, when the electronic component 5 mounted on the wiring board C1 of the electronic device D1 is a semiconductor element that mainly contains Si, the electronic component 5 and the base member 1 are made of approximately the same material. As a result, in the electronic device D1, there is almost no difference in coefficient of linear expansion between the electronic component 5 and the base member 1, which makes it possible to reduce the thermal stress caused by the heat from the electronic component 5.

In the wiring board C1, the base member 1, which contains Si as a main component, is doped with an impurity to increase conductivity. This improves the conductivity of the base member 1, thus further improving the conductivity from the obverse surface 1a to the reverse surface 1b.

In the wiring board C1, the lattice plane of the obverse surface 1a of the base member 1 is a (100) plane. For example, in the crystal structure of a hexagonal crystal system such as Si, the thermal conductivity in a direction parallel to a layer is relatively high, and the thermal conductivity in a direction perpendicular to the layer is relatively low. As such, the direction in which the thermal conductivity is relatively high is set to the thickness direction (z direction) of the base member 1 to thereby improve the thermal conductivity from the obverse surface 1a to the reverse surface 1b. As a result, the heat from the electronic component 5 mounted on the obverse surface 1a of the base member 1, for example, can be efficiently transferred to the reverse surface 1b of the base member 1. In other words, the heat dissipation of the wiring board C1 is further improved.

In the manufacturing method of the wiring board C1, the insulating portion formation step includes the through-hole formation step and the thermal oxidation step, and thermal oxidation is performed after the through-holes 810 are formed in the semiconductor wafer 81. The insides of the through-holes 810 are connected to the wafer obverse surface 81a and the wafer reverse surface 81b. In this way, during the thermal oxidation step, thermal oxidation progresses with respect to the insides of the through-holes 810 from the wafer obverse surface 81a and the wafer reverse surface 81b of the semiconductor wafer 81. Accordingly, the manufacturing method of the wiring board C1 can efficiently form the oxidation film 820 in the insides of the through-holes 810.

In the manufacturing method of the wiring board C1, the through-holes 810 are formed by reactive etching, for example (see the through-hole formation step). In this way, the through-holes 810 are collectively formed in the semiconductor wafer 81. In the case of the wiring board (ALM substrate) described in Patent Document 2, the through-holes (penetrating holes) are formed in the insulating substrate by laser processing, for example. In the laser processing, the through-holes are formed one by one, resulting in poor manufacturing efficiency. On the other hand, the manufacturing method of the wiring board C1 allows the through-holes 810 to be collectively formed, and therefore has a higher manufacturing efficiency than that of the ALN substrate. In other words, the wiring board C1 can be manufactured more efficiently with the manufacturing method of the wiring board C1 than with the manufacturing method of the ALN substrate.

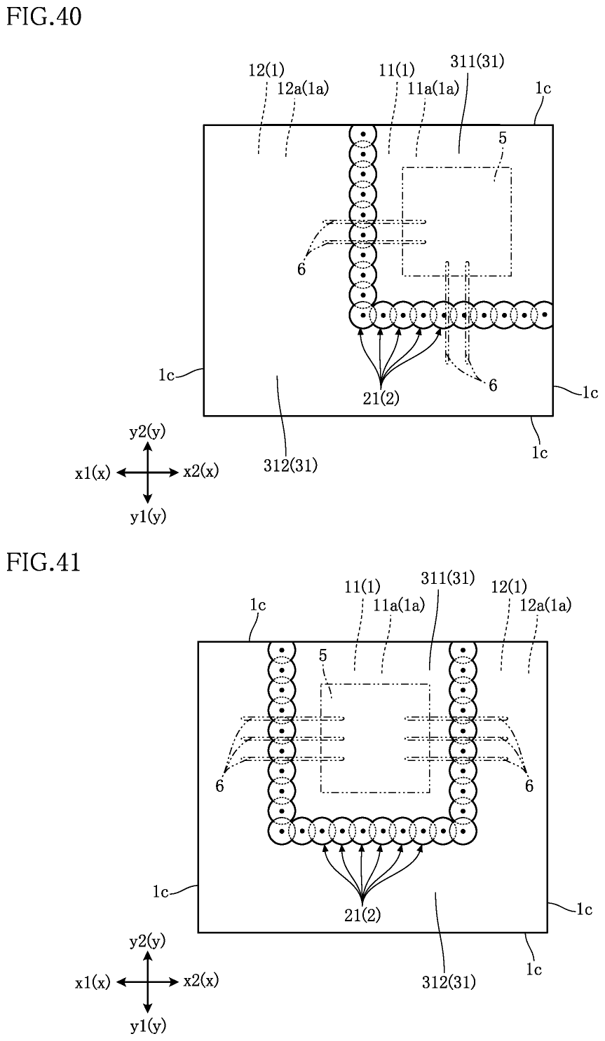

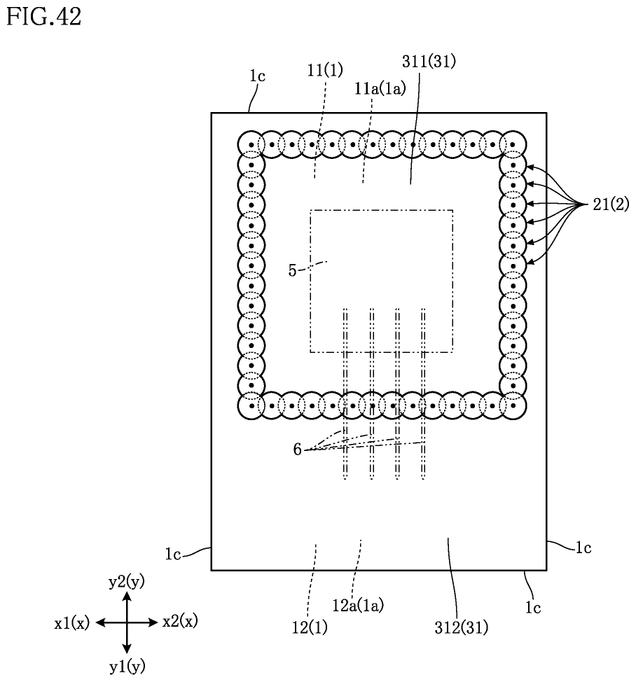

Although the first embodiment has given an example of linearly forming the insulating portion 2 in plan view, that is, an example of aligning the through portions 21 in a straight line, the arrangement of the through portions 21 is not limited to a straight line as long as the insulating portion 2 separates the base member 1 into the first portion 11 and the second portion 12. For example, in plan view, the through portions 21 may be arranged in an “L” shape as shown in FIG. 40, a “U” shape as shown in FIG. 41, or a square shape as shown in FIG. 42. In FIG. 42, the insulating portion 2 has a rectangular ring shape in plan view, and the second portion 12 is formed in a frame shape surrounding the first portion 11 with the insulating portion 2 interposed between the second portion 12 and the first portion 11. The insulating portion 2 in plan view is not limited to having a rectangular ring shape, and may have an annular shape, an elliptical ring shape, or a polygonal ring shape. In the variations shown in FIGS. 40 to 42, the insulating portion 2 formed by the through portions 21 can also separate the base member 1 into the first portion 11 and the second portion 12. In the variations shown in FIGS. 40 to 42, the electronic component 5 and the bonding wires 6 can be arranged as shown by imaginary lines (two-dot chain lines), for example.

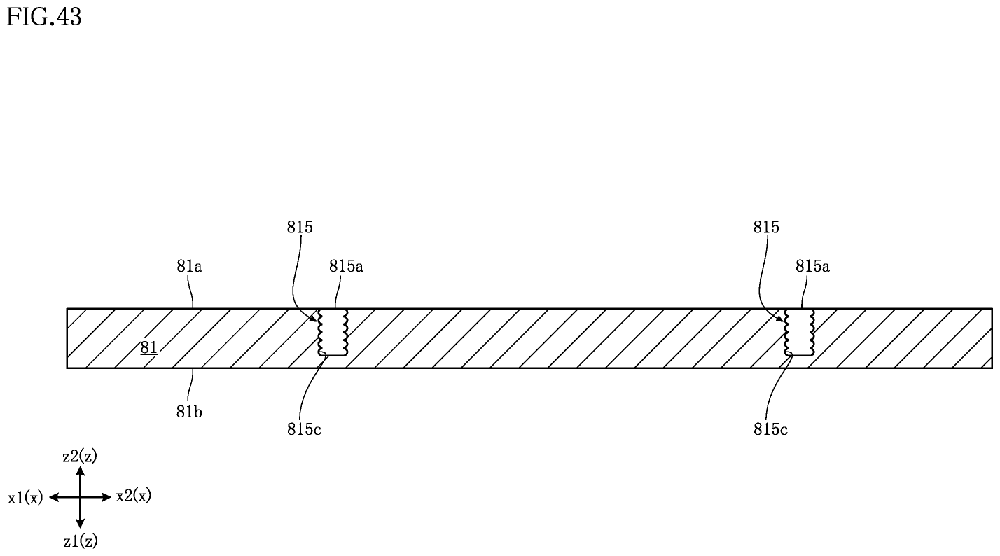

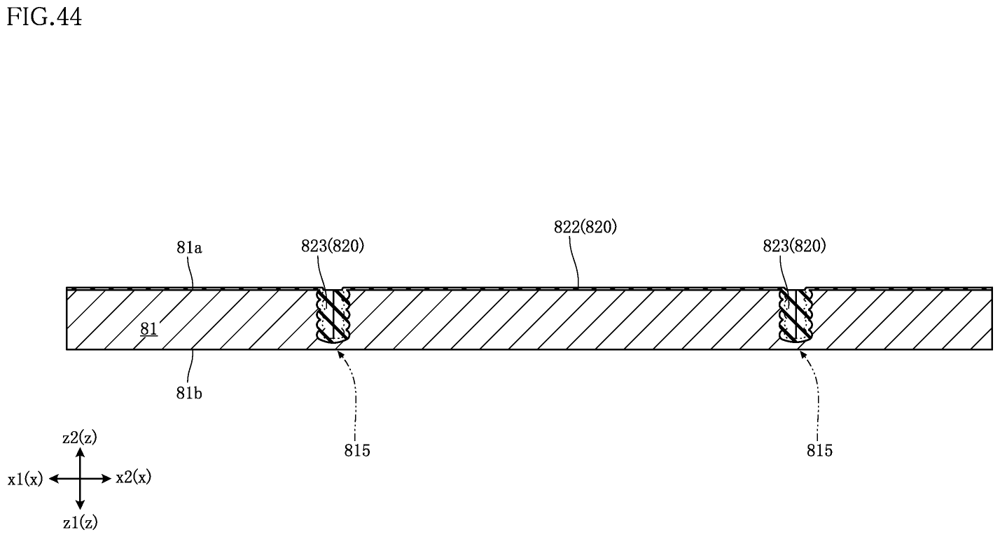

In the manufacturing method of the wiring board C1 in the first embodiment, the insulating portion formation step includes the through-hole formation step. However, the insulating portion formation step may include a groove formation step instead of the through-hole formation step. That is, the insulating portion formation step may include the groove formation step, the thermal oxidation step, and the grinding step. FIGS. 43 and 44 show a step of a manufacturing method according to such a variation. FIG. 43 is a cross-sectional view showing the groove formation step. FIG. 44 is a cross-sectional view showing the thermal oxidation step.

In the groove formation step, a plurality of grooves 815 are formed in the semiconductor wafer 81, as shown in FIG. 43. The groove formation step may be performed by using reactive etching, as with the through-hole formation step. The grooves 815 each have a circular shape in plan view, for example, and are formed in the same positions as those of the through-holes 810 in plan view. The grooves 815 are recessed from the wafer obverse surface 81a in the z direction, and do not pass through the semiconductor wafer 81 in the z direction. As shown in FIG. 43, each of the grooves 815 includes an opening 815a and a peripheral wall 815c. The opening 815a is open in the wafer obverse surface 81a. The peripheral wall 815c extends from the opening 815a in the z direction, and has a ribbed structure called “scallop”, similarly to the peripheral wall 810c.

Next, in the thermal oxidation step, filling portions 823 are formed to fill the grooves 815, as shown in FIG. 44. The filling portions 823 are portions of the oxidation film 820.

Then, in the grinding step, the semiconductor wafer 81 is ground until the filling portions 823 are exposed from the wafer reverse surface 81b, whereby the through portions 821 are formed from the filling portions 823. Each of the through portions 821 thus formed includes the obverse surface 821a, the reverse surface 821b, the side surface 821c, and the boundary portion 821d, as with each of the through portions 821 formed by the manufacturing method of the wiring board C1.

### Second Embodiment

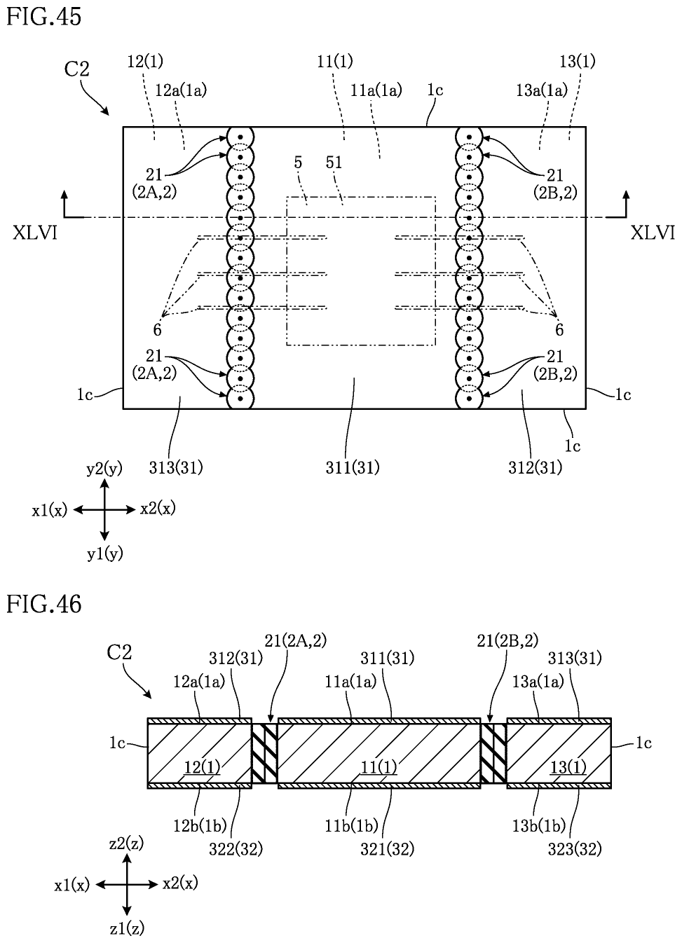

FIGS. 45 and 46 show a wiring board C2 according to a second embodiment of the second group of the present disclosure. FIG. 45 is a plan view showing the wiring board C2. FIG. 46 is a cross-sectional view taken along line XLVI-XLVI in FIG. 45.

As shown in FIGS. 45 and 46, the wiring board C2 includes two insulating portions 2, unlike the wiring board C1. The two insulating portions 2 separate the base member 1 into three portions. To distinguish the two insulating portions 2, one of the insulating portions 2 is referred to as an insulating portion 2A and the other as an insulating portion 2B. Each of the insulating portions 2A and 2B is continuous in the y direction in plan view, and extends from the side surface 1c in the y1 direction to the side surface 1c in the y2 direction. Each of the insulating portions 2A and 2B includes a plurality of through portions 21 connected to each other in plan view. The plurality of through portions 21 of each of the insulating portions 2A and 2B are aligned in a straight line.

The base member 1 is divided into three portions, namely a first portion 11, a second portion 12, and a third portion 13. The first portion 11 and the second portion 12 are separated from each other by the insulating portion 2A, and the first portion 11 and the third portion 13 are separated from each other by the insulating portion 2B. In the example shown in FIGS. 45 and 46, the first portion 11, the second portion 12, and the third portion 13 are aligned in the x direction, with the first portion 11 positioned between the second portion 12 and the third portion 13 in the x direction. The arrangement of the first portion 11, the second portion 12, and the third portion 13 is not limited to the illustrated example.

The third portion 13 has a third obverse surface 13a and a third reverse surface 13b. The third obverse surface 13a and the third reverse surface 13b are spaced apart from each other in the z direction. The third obverse surface 13a faces in the z2 direction, and the third reverse surface 13b faces in the z1 direction. The third obverse surface 13a is substantially flush with the first obverse surface 11a, the second obverse surface 12a, and the obverse surface 211 of each of the through portions 21 of the insulating portions 2A and 2B. The third reverse surface 13b is substantially flush with the first reverse surface 11b, the second reverse surface 12b, and the reverse surface 212 of each of the through portions 21 of the insulating portions 2A and 2B. In the present embodiment, the first obverse surface 11a, the second obverse surface 12a, and the third obverse surface 13a constitute the obverse surface 1a. The first reverse surface 11b, the second reverse surface 12b, and the third reverse surface 13b constitute the reverse surface 1b.

The obverse-surface electrode 31 of the wiring board C2 includes a first obverse-surface covering portion 311, a second obverse-surface covering portion 312, and a third obverse-surface covering portion 313. The third obverse-surface covering portion 313 covers the third obverse surface 13a (third portion 3). In the wiring board C2, the reverse-surface electrode 32 includes a first reverse-surface covering portion 321, a second reverse-surface covering portion 322, and a third reverse-surface covering portion 323. The third reverse-surface covering portion 323 covers the third reverse surface 13b.

As shown by imaginary lines (two-dot chain lines) in FIG. 45, the electronic component 5 and the bonding wires 6 can be arranged on the wiring board C2. In the example of FIG. 45, the electronic component 5 is mounted on the first portion 11, similarly to the case of the wiring board C1. The bonding wires 6 include those bonded to and electrically connecting the electrode on the obverse surface 51 of the electronic component 5 and the second obverse-surface covering portion 312, and those bonded to and electrically connecting the electrode on the obverse surface 51 of the electronic component 5 and the third obverse-surface covering portion 313.

As with the wiring board C1, the wiring board C2 includes a base member 1 made of a semiconductor material. Accordingly, the wiring board C2 can reduce the number of manufacturing man-hours as compared to the conventional wiring board (described in Patent Document 2), and thus can reduce the manufacturing cost.

In the wiring board C2, the main constituent material of the base member 1 is also Si, which is a semiconductor material. Accordingly, as with the wiring board C1, the wiring board C2 can electrically connect the obverse surface 1a of the base member 1 and the reverse surface 1b thereof, and has approximately the same heat dissipation property as the ALN substrate.

In addition, the wiring board C2 has the same advantages as the wiring board C1, owing to the elements configured in the same manner as those of the wiring board C1. Furthermore, the manufacturing method of the wiring board C2 has the same advantages as the manufacturing method of the wiring board C1, owing to the same steps as those in the manufacturing method of the wiring board C1.

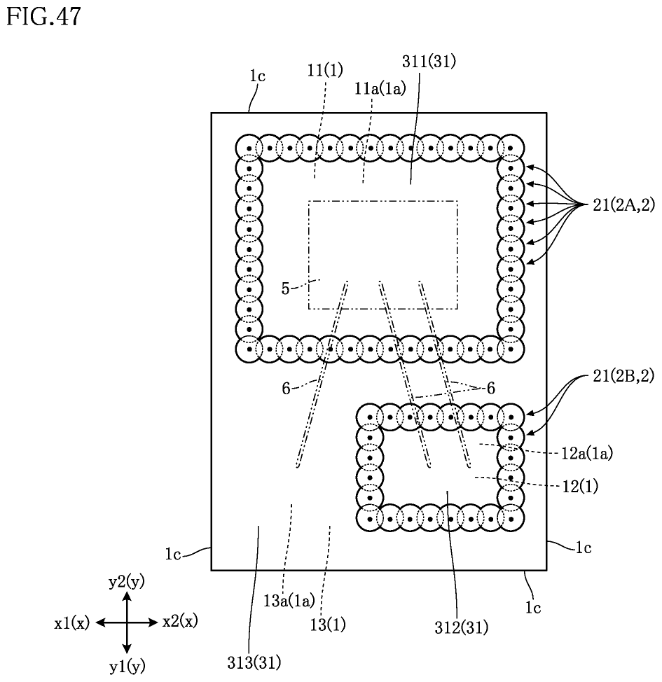

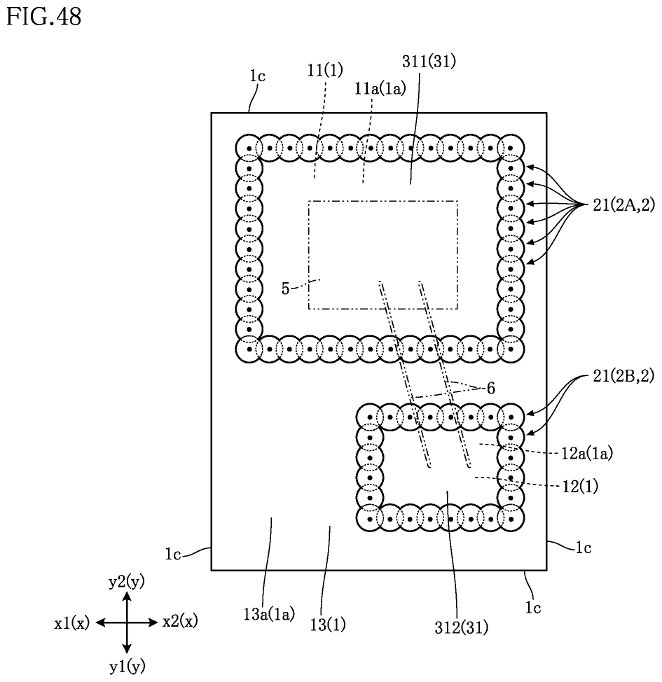

Each of the insulating portions 2A and 2B of the wiring board C2 is formed in a straight line in plan view, similarly to the case of the wiring board C1. However, the present disclosure is not limited to this example. For example, the shape of each of the insulating portions 2A and 2B in plan view may be an “L” shape, a “U” shape, or a square shape, as shown in FIGS. 40 to 42. For example, FIG. 47 shows a wiring board according to such a variation, where each of the insulating portions 2A and 2B is configured to have a square shape in plan view. In the variation shown in FIG. 47, the electronic component 5 and the bonding wires 6 can be arranged as shown by imaginary lines (two-dot chain lines), for example. For a wiring board having the same configuration as that shown in FIG. 47, the electronic component 5 and the bonding wires 6 may be arranged as shown by imaginary lines (two-dot chain lines) in FIG. 48. In the example shown in FIG. 48, none of the bonding wires 6 are bonded to the third portion 13 (third obverse-surface covering portion 313). Accordingly, it is not absolutely necessary to provide the third obverse-surface covering portion 313 that covers the third obverse surface 13a, and the third reverse-surface covering portion 323 covering the third reverse surface 13b. In this case, it is possible to provide an insulating film that covers the third obverse surface 13a, and an insulating film that covers the third reverse surface 13b.

Although the base member 1 of the wiring board C2 is divided into three portions (i.e., the first portion 11, the second portion 12, and the third portion 13), the present disclosure is not limited to this. For example, the base member 1 may be divided into four or more portions by increasing the number of insulating portions 2.

### Third Embodiment

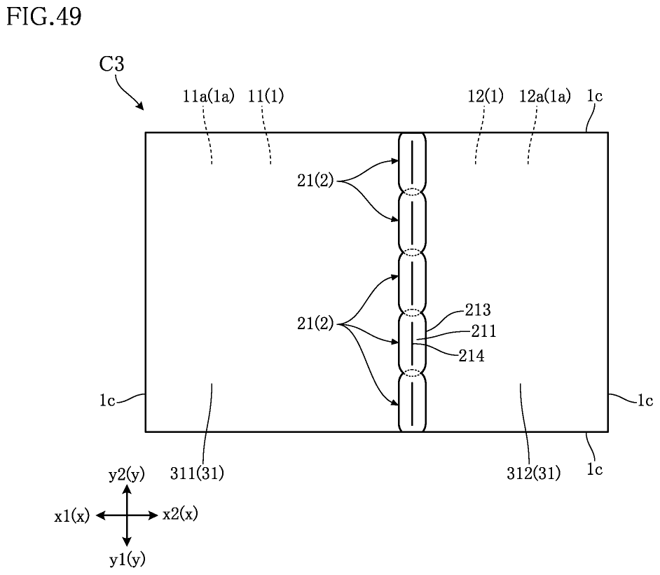

FIG. 49 shows a wiring board C3 according to a third embodiment of the second group of the present disclosure. FIG. 49 is a plan view showing the wiring board C3.

As shown in FIG. 49, the wiring board C3 is different from the wiring board C1 in that each of the through portions 21 is formed linearly in plan view. In an example in which the through portions 21 are aligned in the y direction, each of the through portions 21 has a linear shape elongated in the y direction. When each of the through portions 21 is formed to extend linearly, the boundary portions 214 are also formed to extend linearly in plan view. The direction in which the through portions 21 extend substantially coincides with the direction in which the boundary portions 214 extend.

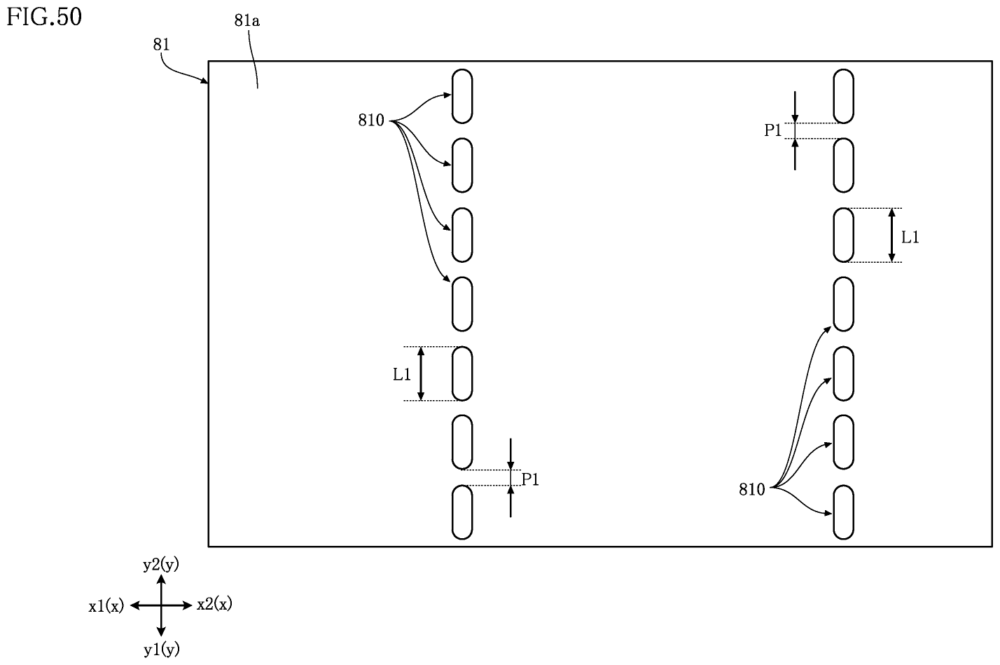

For example, the through portions 21 shown in FIG. 49 are formed by changing the shape of each of the through-holes 810 in plan view during the through-hole formation step of the manufacturing method of the wiring board C1. FIG. 50 is a plan view showing the through-hole formation step in the manufacturing method of the wiring board C3.

As shown in FIG. 50, in the through-hole formation step of the manufacturing method of the wiring board C3, each of the through-holes 810 is formed in an oval shape (elliptical shape) in plan view, instead of a circular shape in plan view. Note that a wafer preparation step before the through-hole formation step is the same as that for the wiring board C1. The through-holes 810 are aligned in the y direction with the long sides thereof extending along the y direction. The length L1 (see FIG. 50) of each of the through-holes 810 in a lengthwise direction is about 10 μm, for example. The interval P1 (see FIG. 50) between two adjacent through-holes 810 is the same as in the first embodiment.

Next, a thermal oxidation step is performed in the same manner as that of the manufacturing method in the first embodiment. As a result, the oxidation film 820 is formed inward in plan view from the peripheral walls 810c of the through-holes 810. In other words, the through portions 821 are formed to fill the through-holes 810. Furthermore, the oxidation film 820 is formed outward in plan view from the peripheral walls 810c of the through-holes 810. As such, adjacent through portions 821 are connected to each other.

After that, a grinding step and the subsequent steps are performed in the same manner as those in the manufacturing method of the first embodiment, so that the wiring board C3 shown in FIG. 50 is manufactured.

As with the wiring board C1, the wiring board C3 includes a base member 1 made of a semiconductor material. Accordingly, the wiring board C3 can reduce the number of manufacturing man-hours as compared to the conventional wiring board (described in Patent Document 2), and thus can reduce the manufacturing cost.

In the wiring board C3, the main constituent material of the base member 1 is also Si, which is a semiconductor material. Accordingly, as with the wiring boards C1 and A2, the wiring board C3 can electrically connect the obverse surface 1a of the base member 1 and the reverse surface 1b thereof, and has approximately the same heat dissipation property as the ALN substrate.

In addition, the wiring board C3 has the same advantages as the wiring boards C1 and A2, owing to the elements configured in the same manner as those of the wiring boards C1 and A2. Furthermore, the manufacturing method of the wiring board C3 has the same advantages as the manufacturing methods of the wiring boards C1 and A2, owing to the same steps as those in the manufacturing methods of the wiring boards C1 and A2.

### Fourth Embodiment

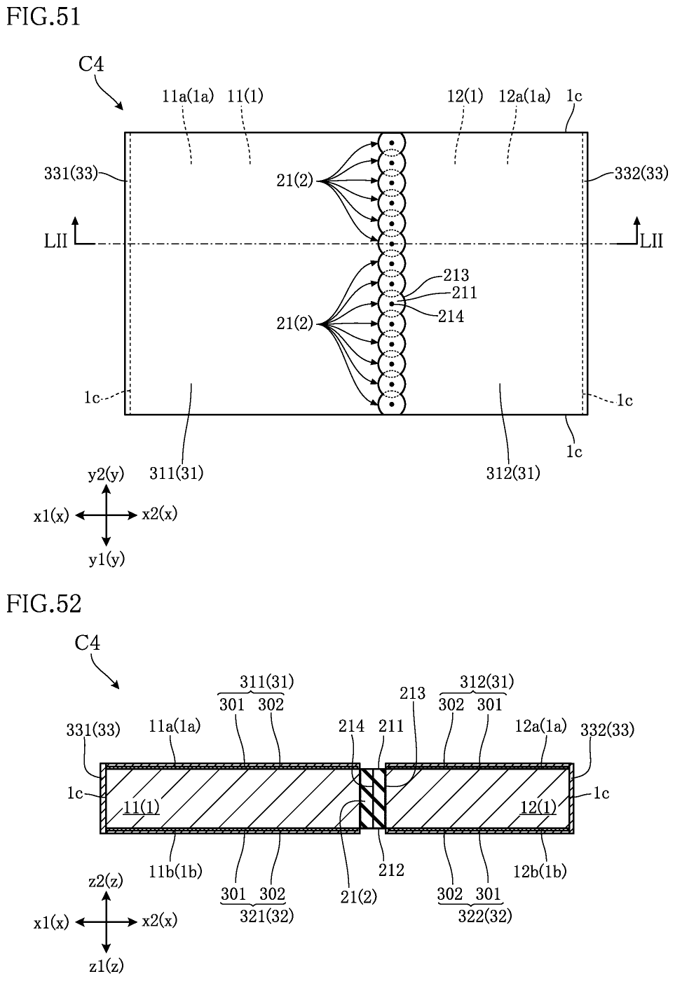

FIGS. 51 and 52 show a wiring board C4 according to a fourth embodiment of the second group of the present disclosure. FIG. 51 is a plan view showing the wiring board C4. FIG. 52 is a cross-sectional view taken along line LII-LII in FIG. 51.

As shown in FIGS. 51 and 52, the wiring board C4 is different from the wiring board C1 in further including a side electrode 33.

The side electrode 33 is formed on any of the side surfaces 1c of the base member 1. In the example shown in FIGS. 51 and 52, a side electrode 33 is formed on each of the pair of side surfaces 1c spaced apart from each other in the x direction. The side electrode 33 is made of a conductive material. For example, the side electrode 33 is made of Au, Ag, Cu (copper), or Al. As with the obverse-surface electrode 31 and the reverse-surface electrode 32, the side electrode 33 may include a plurality of metal layers stacked on each other or may include a single metal layer. The side electrode 33 is formed by sputtering or vapor deposition.

The side electrode 33 includes a first connecting portion 331 and a second connecting portion 332. The first connecting portion 331 is connected to the first obverse-surface covering portion 311 and the first reverse-surface covering portion 321 and electrically connects them. The first connecting portion 331 covers the side surface 1c that faces in the x1 direction. The second connecting portion 332 is connected to the second obverse-surface covering portion 312 and the second reverse-surface covering portion 322 and electrically connects them. The second connecting portion 332 covers the side surface 1c that faces in the x2 direction.

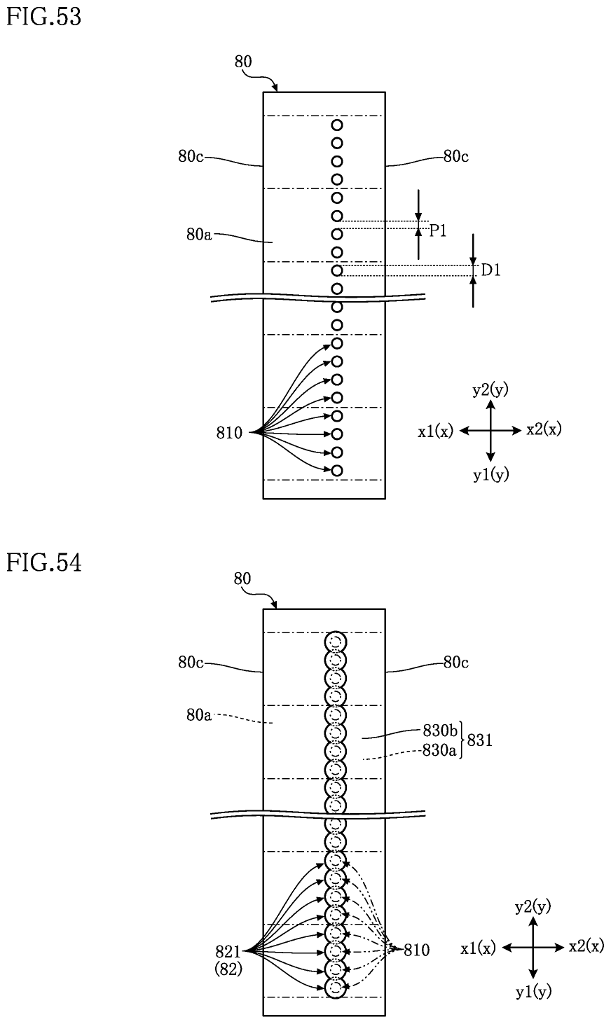

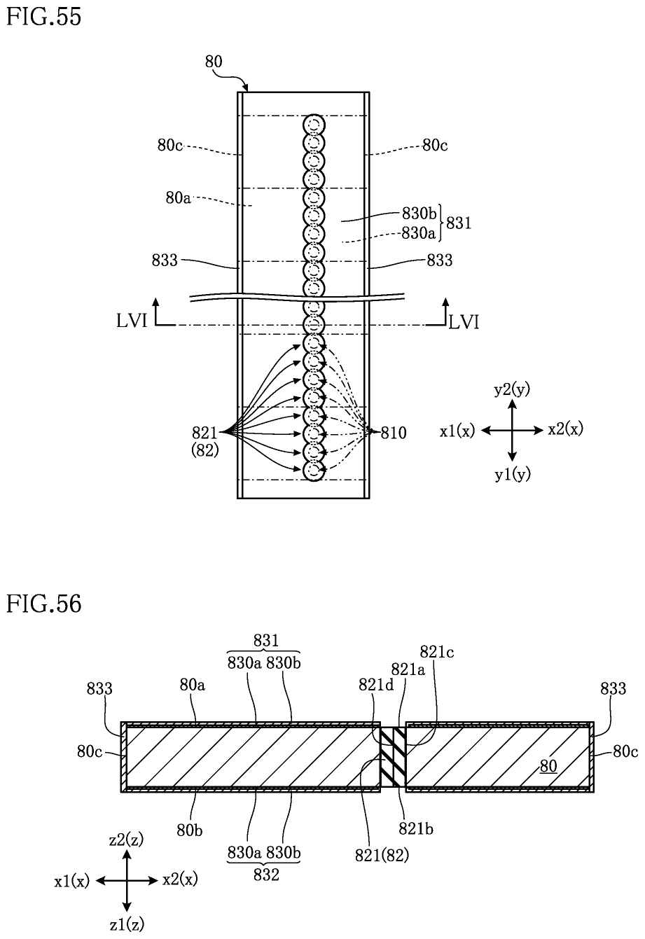

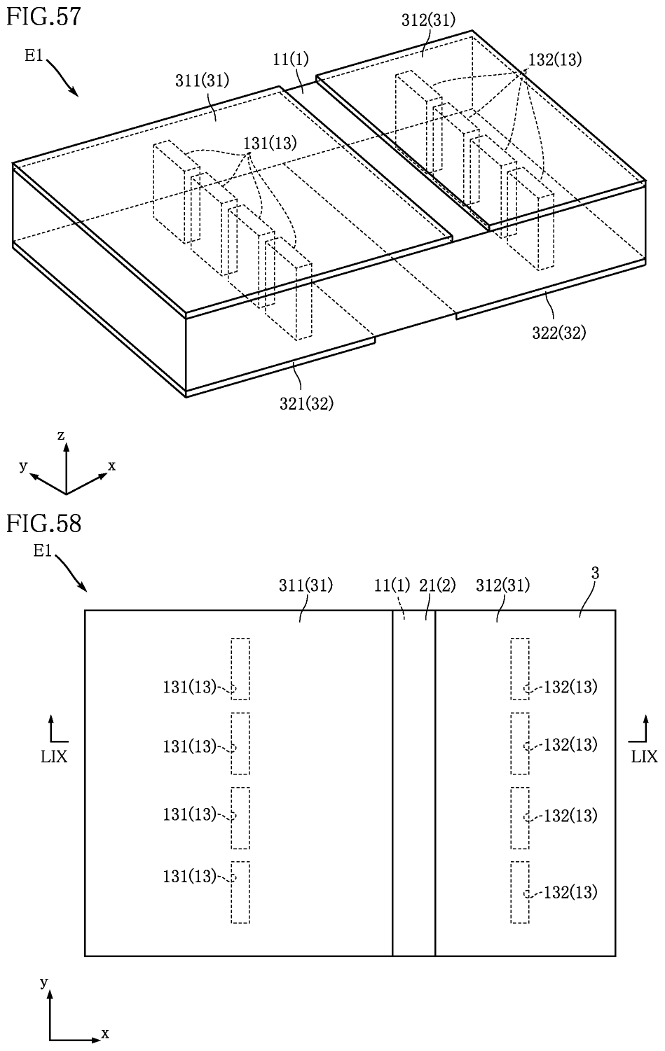

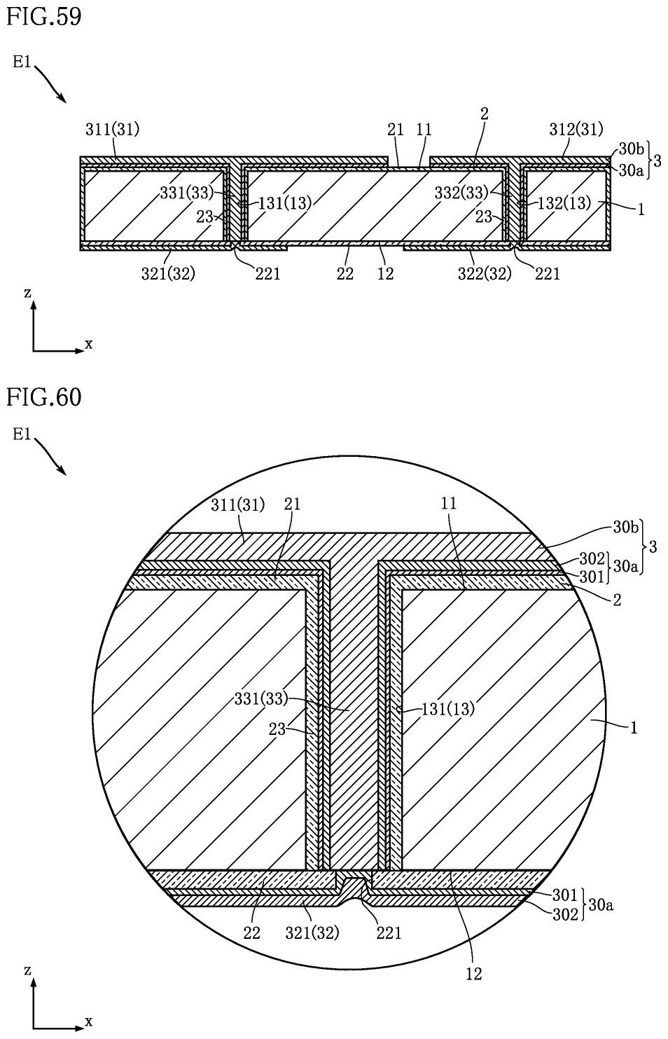

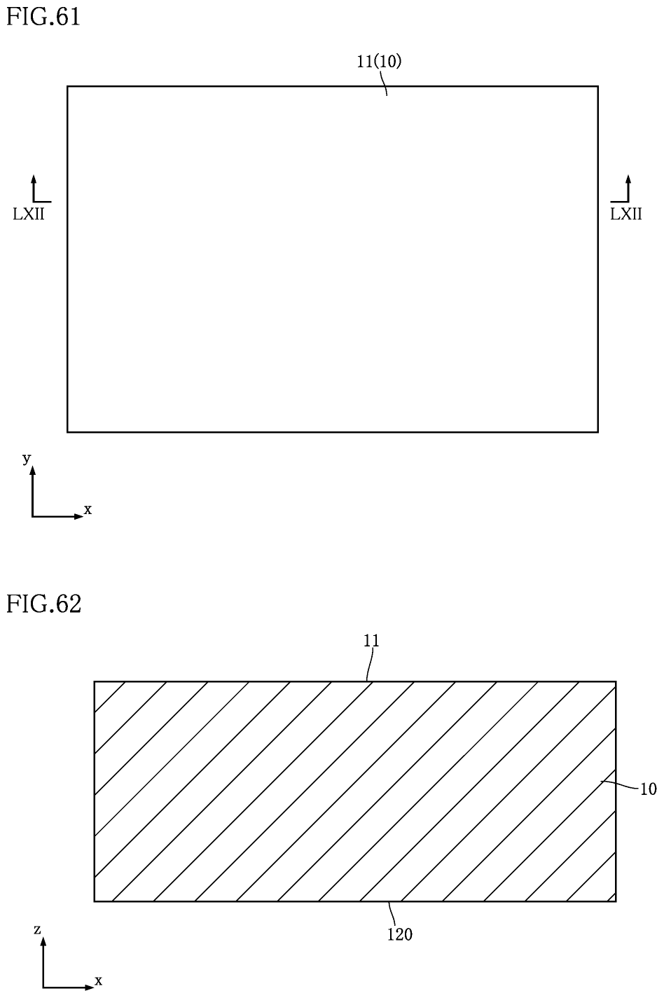

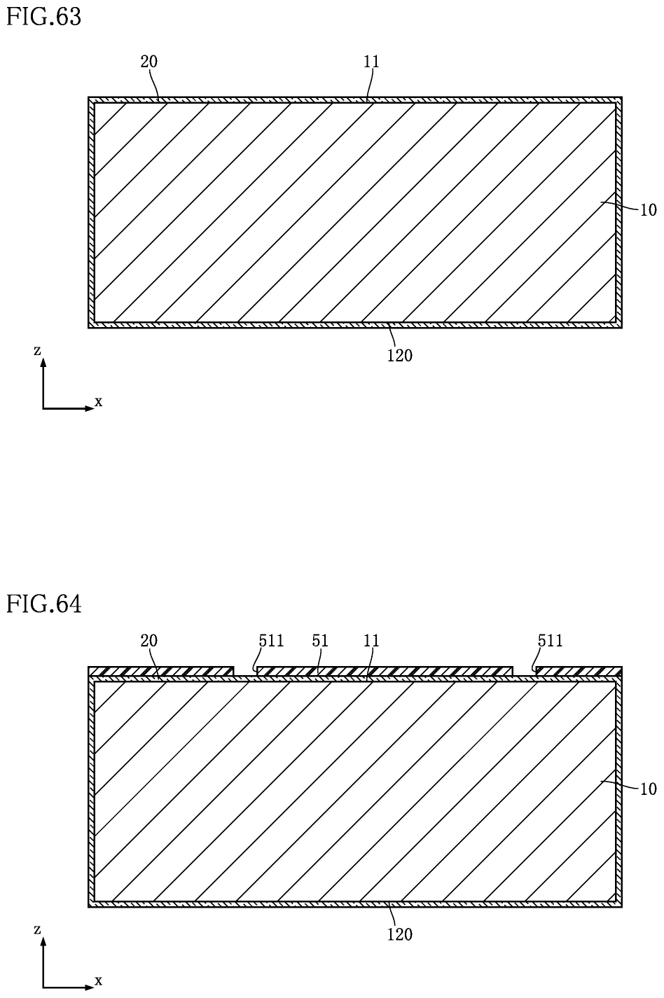

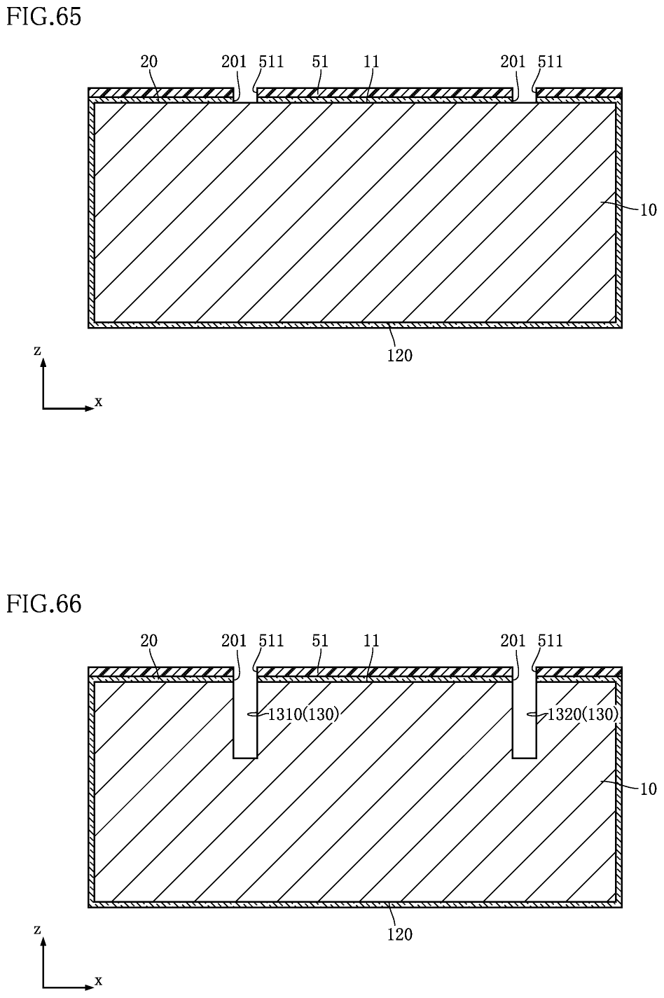

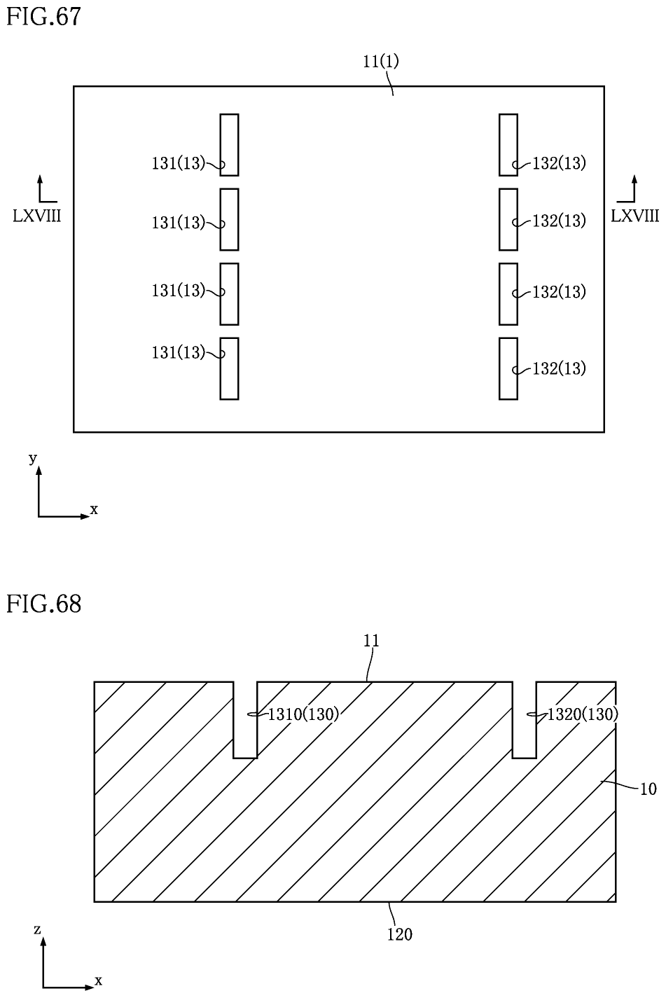

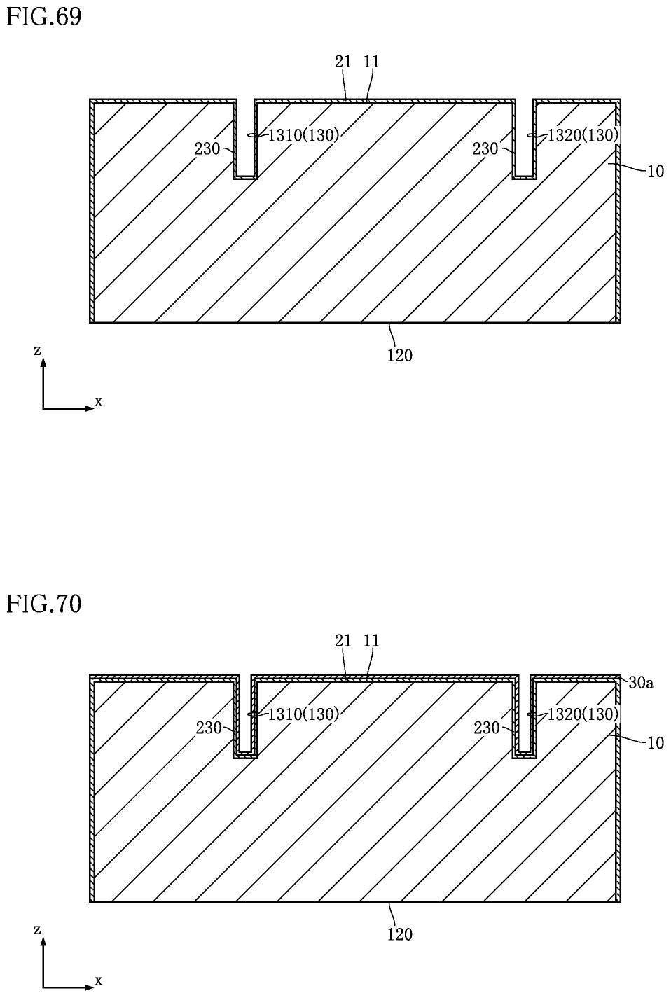

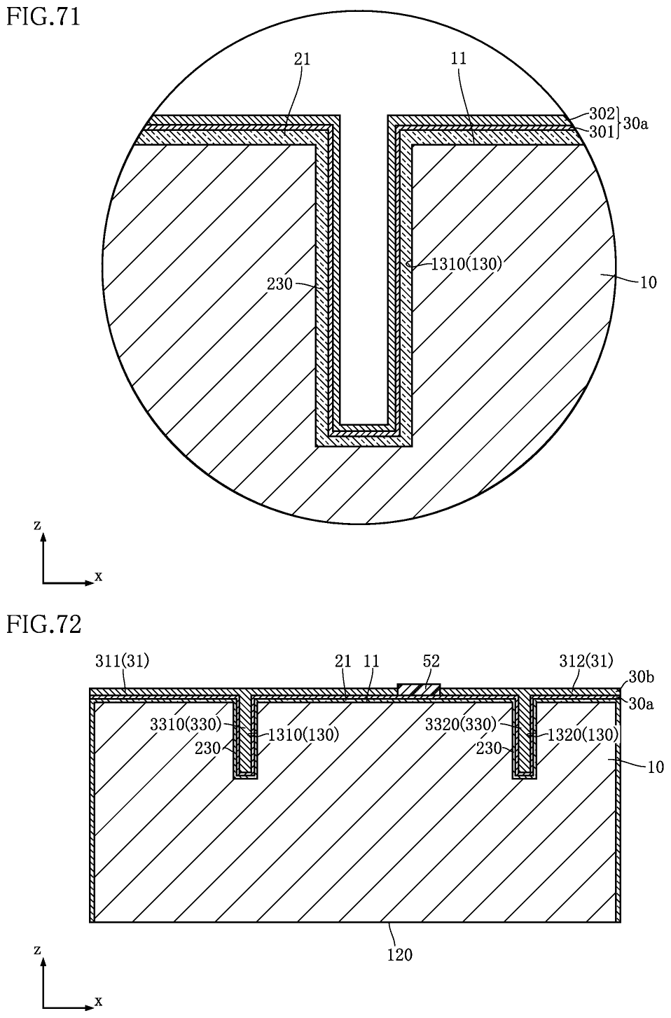

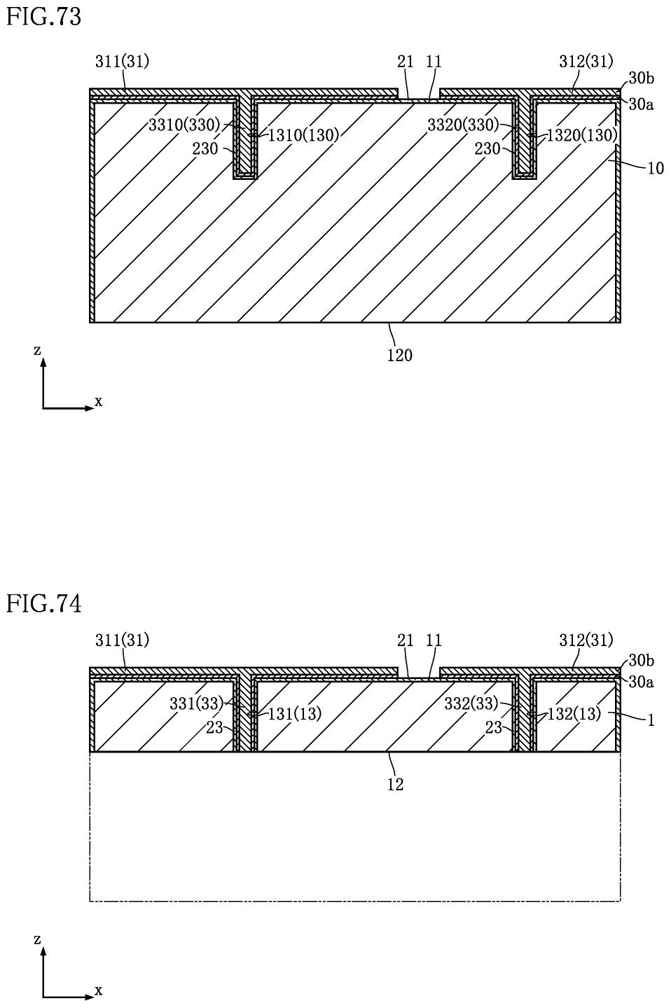

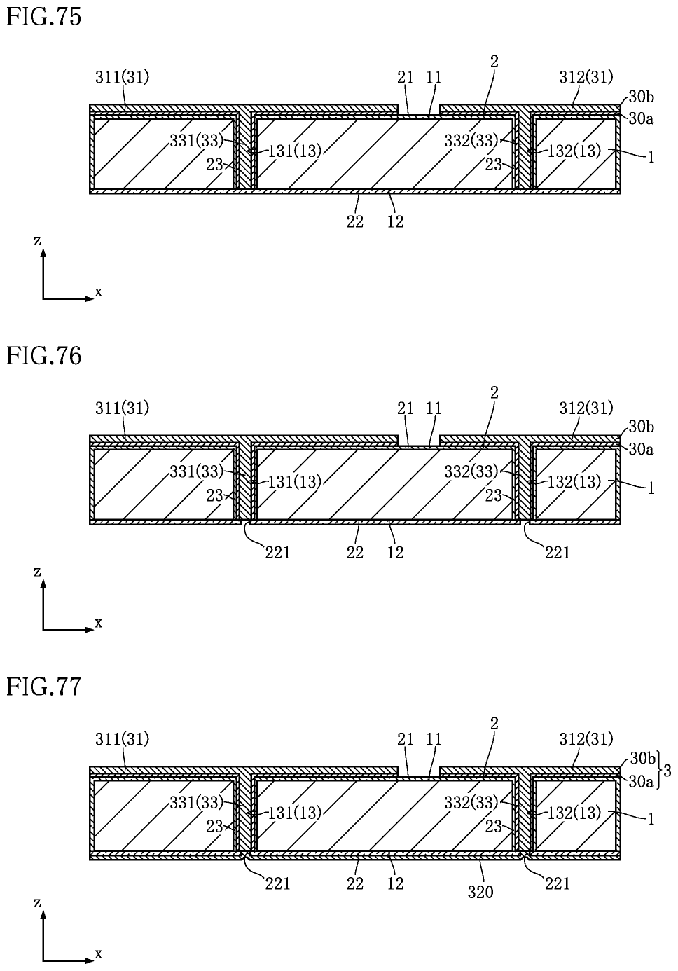

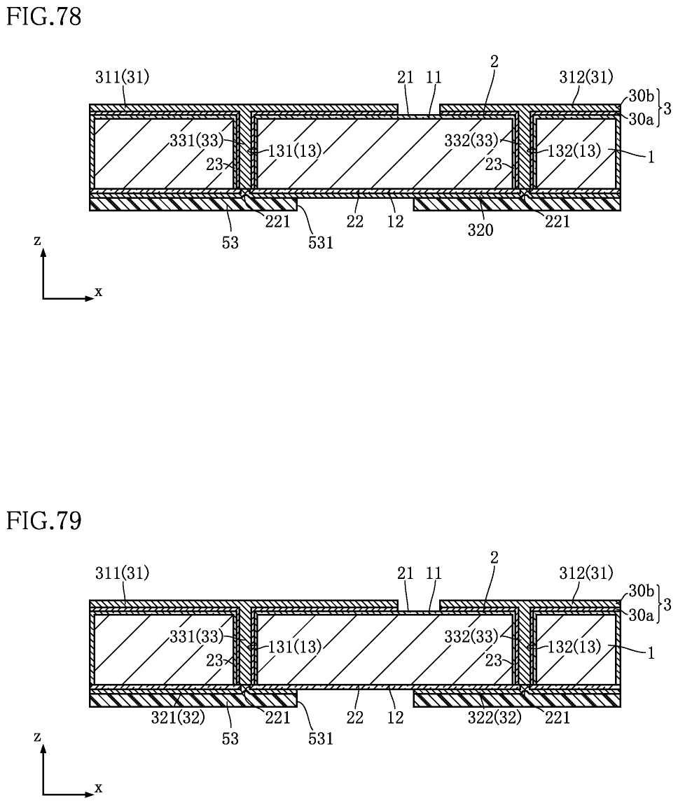

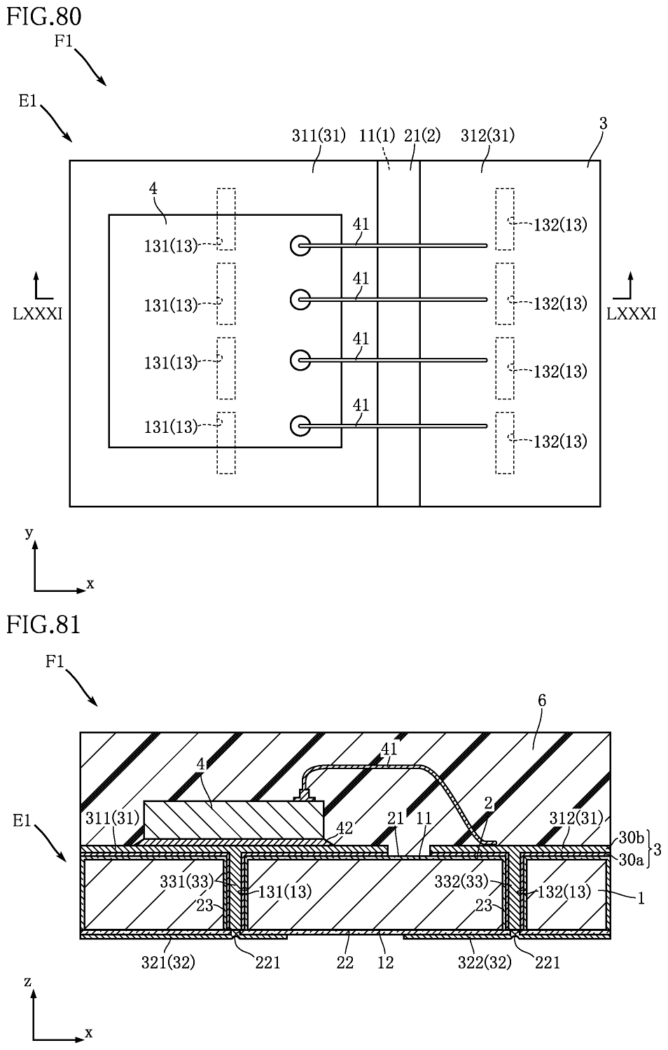

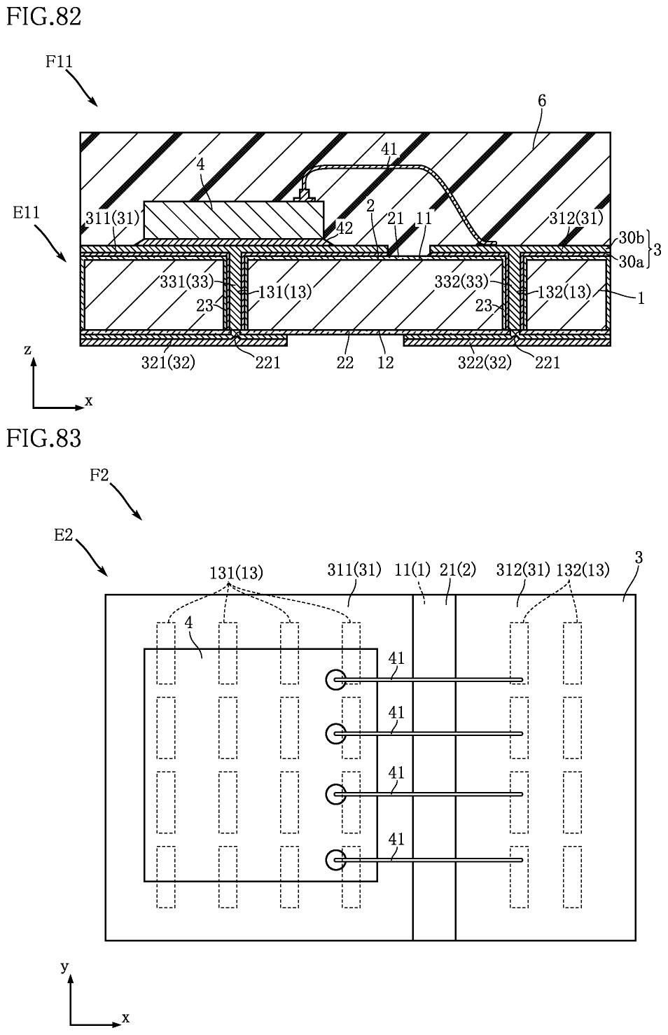

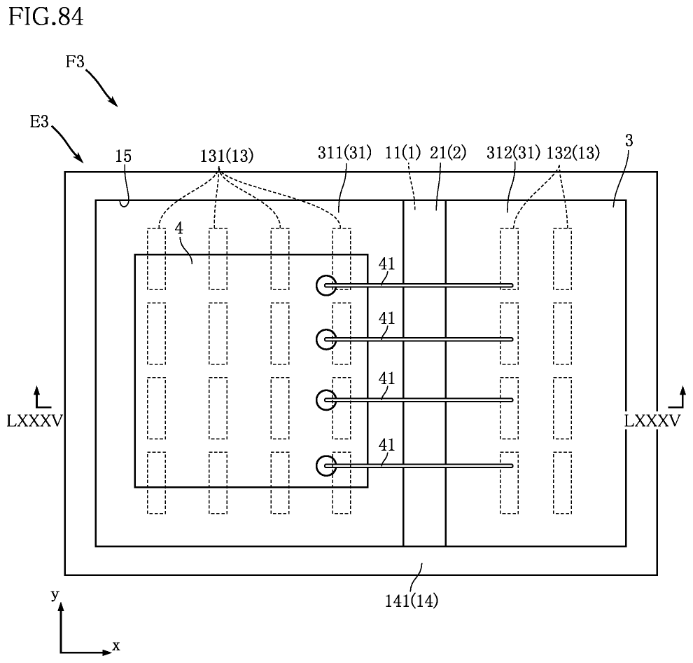

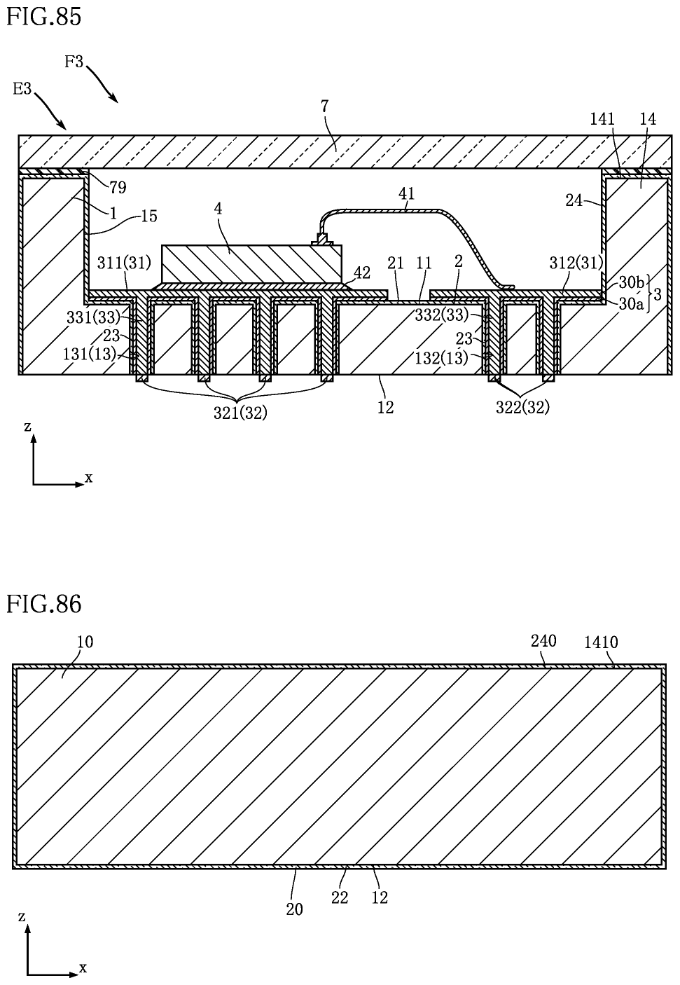

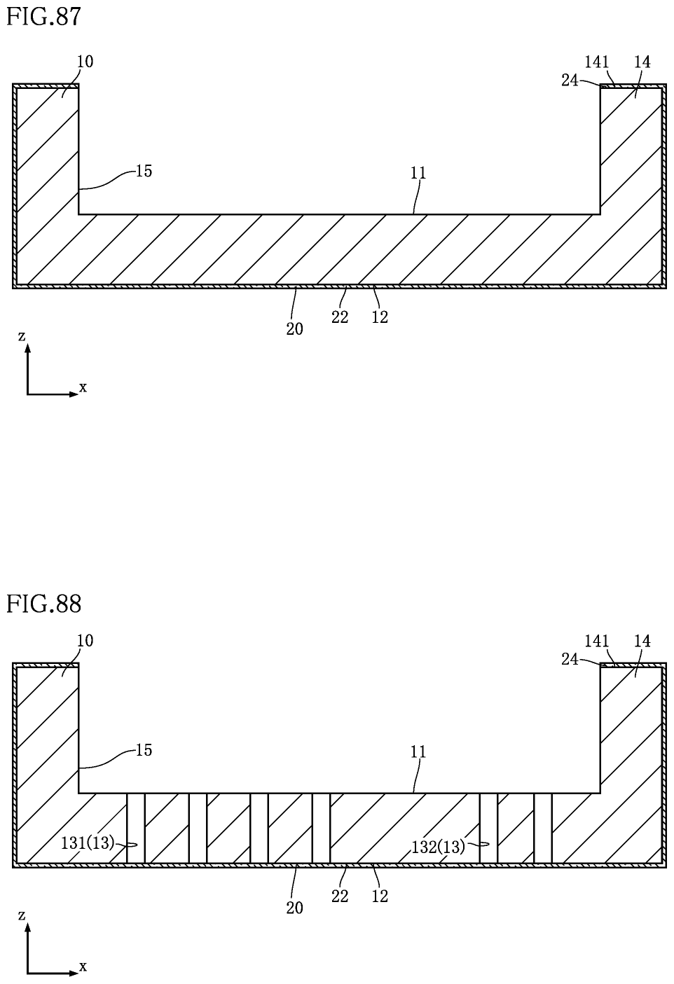

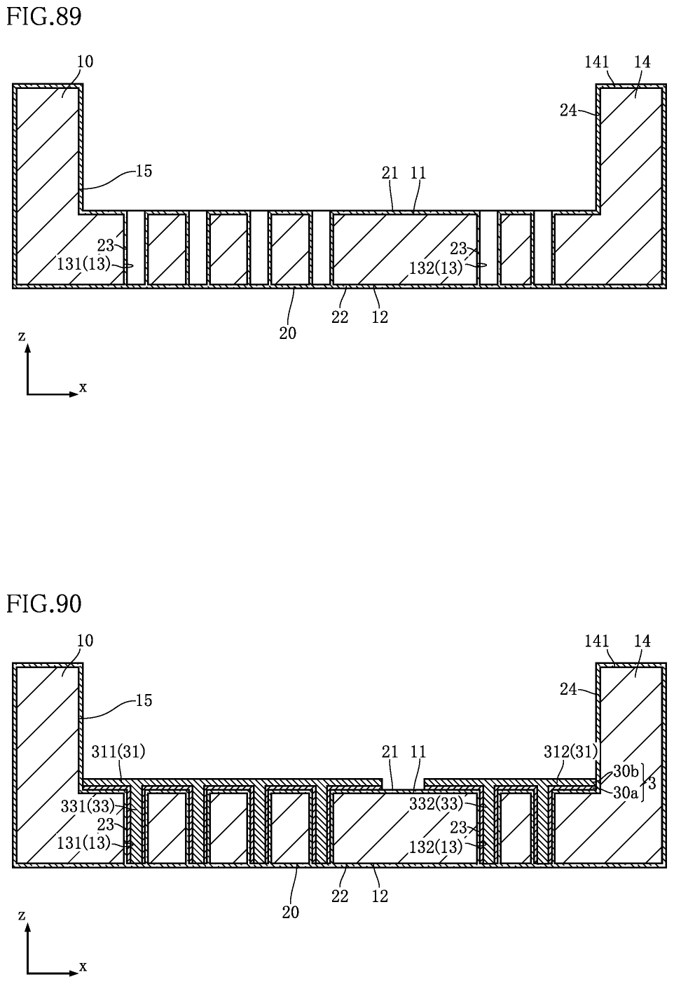

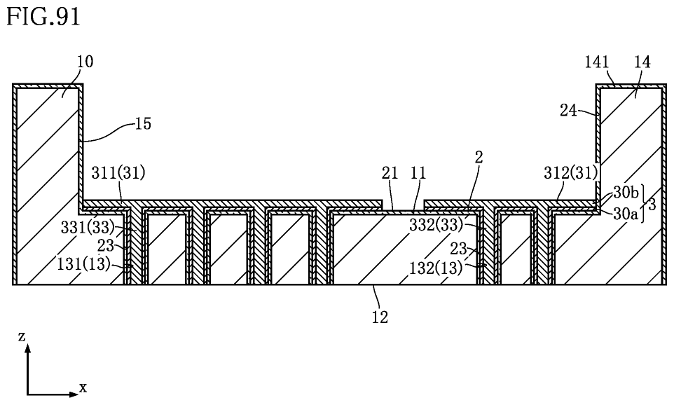

Next, a manufacturing method of the wiring board C4 is described with reference to FIGS. 53 to 56. Descriptions are omitted as to the same steps as those in the manufacturing method of the wiring board C1. Each of FIGS. 53, 54, and 55 is a plan view showing a step of the manufacturing method of the wiring board C4. FIG. 56 is a cross-sectional view taken along line LVI-LVI in FIG. 55 and showing a step of the manufacturing method of the wiring board C4.

In the manufacturing method of the wiring board C4, a band-shaped semiconductor wafer 80 is prepared, and a plurality of through-holes 810 are formed in the semiconductor wafer 80, as shown in FIG. 53. For example, the semiconductor wafer 80 is formed by cutting, in the y direction, the semiconductor wafer 81 having a circular shape in plan view as shown in FIG. 26. The semiconductor wafer 80 has a wafer obverse surface 80a, a wafer reverse surface 80b, and a pair of wafer side surfaces 80c. The wafer obverse surface 80a and the wafer reverse surface 80b are spaced apart from each other in the z direction. The wafer obverse surface 80a faces in the z2 direction, and the wafer reverse surface 80b faces in the z1 direction. The pair of wafer side surfaces 80c are connected to the wafer obverse surface 80a and the wafer reverse surface 80b, and are sandwiched between the wafer obverse surface 80a and the wafer reverse surface 80b in the z direction. The pair of wafer side surfaces 80c are spaced apart from each other in the x direction. One of the pair of wafer side surfaces 80c faces in the x1 direction, and the other in the x2 direction. The pair of wafer side surfaces 80c are cut surfaces resulting from the semiconductor wafer 81 having a circular shape in plan view being cut in the y direction, as described above. The dimension of the semiconductor wafer 80 in the x direction is substantially the same as the dimension of the base member 1 of the wiring board C4 in the x direction.

Next, a plurality of through-holes 810 are formed in the semiconductor wafer 80 in the same manner as in the through-hole formation step described above. The through-holes 810 in the present embodiment are arranged in a line in the y direction. The interval P1 between adjacent two of the through-holes 810 and the diameter D1 of each of the through-holes 810 are the same as those of the through-holes 810 in the first embodiment.

Next, similarly to the manufacturing method of the wiring board C1, the thermal oxidation step, the grinding step, the obverse-surface electrode forming step and the reverse-surface electrode forming step (the first metal layer formation step and the second metal layer formation step) are performed in sequence. As a result, an insulating portion 82, an obverse-surface electrode 831, and a reverse-surface electrode 832 are formed on the semiconductor wafer 80 as shown in FIG. 54.

Next, side electrodes 833 are formed as shown in FIGS. 55 and 56. In the step of forming the side electrodes 833 (side electrode formation step), the side electrodes 833 are formed on the pair of wafer side surfaces 80c along the long sides of the semiconductor wafer 80 by sputtering or vapor deposition, for example.

Then, the semiconductor wafer 80 is cut into pieces that each have a final product shape. The wiring board C4 as shown in FIGS. 51 and 52 is formed through the steps described above.

As with the wiring board C1, the wiring board C4 includes a base member 1 made of a semiconductor material. Accordingly, the wiring board C4 can reduce the number of manufacturing man-hours as compared to the conventional wiring board (described in Patent Document 2), and thus can reduce the manufacturing cost.

In the wiring board C4, the main constituent material of the base member 1 is also Si, which is a semiconductor material. Accordingly, as with the wiring boards C1 to A3, the wiring board C4 can electrically connect the obverse surface 1a of the base member 1 and the reverse surface 1b thereof, and has approximately the same heat dissipation property as the ALN substrate.

In addition, the wiring board C4 has the same advantages as the wiring boards C1 to A3, owing to the elements configured in the same manner as those of the wiring boards C1 to A3. Furthermore, the manufacturing method of the wiring board C4 has the same advantages as the manufacturing methods of the wiring boards C1 to A3, owing to the same steps as those in the manufacturing methods of the wiring boards C1 to A3.

The wiring board C4 includes the side electrode 33 having a first connecting portion 331 and a second connecting portion 332. The first connecting portion 331 electrically connects the first obverse-surface covering portion 311 and the first reverse-surface covering portion 321, and the second connecting portion 332 electrically connects the second obverse-surface covering portion 312 and the second reverse-surface covering portion 322. As a result, the first obverse-surface covering portion 311 and the first reverse-surface covering portion 321 are electrically connected to each other not only via the first portion 11, but also via the first connecting portion 331. This further improves the conductivity between the first obverse-surface covering portion 311 and the first reverse-surface covering portion 321. The second obverse-surface covering portion 312 and the second reverse-surface covering portion 322 are electrically connected to each other not only via the second portion 12, but also via the second connecting portion 332. This further improves the conductivity between the second obverse-surface covering portion 312 and the second reverse-surface covering portion 322. The configuration as described above is effective when the conductivity between the obverse-surface electrode 31 and the reverse-surface electrode 32 via the base member 1 is insufficient. For example, this configuration is effective when the base member 1 is made of a semiconductor material having insufficient conductivity.

Although the fourth embodiment has given an example where the side electrode 33 is formed on each of the pair of side surfaces 1c that are spaced apart from each other in the x direction, the side electrode 33 may be formed on each of the pair of side surfaces 1c that are spaced apart from each other in the y direction. In this case, the first connecting portion 331 covers the side surfaces 1c of the first portion 11 facing in the y direction, and the second connecting portion 332 covers the side surfaces 1c of the second portion 12 facing in the y direction.

The wiring board, the electronic device, and the method for manufacturing the wiring board according to the second group of the present disclosure are not limited to those in the above embodiments. Various design changes can be made to the specific configurations of the elements of the wiring board and the electronic device according to the second group of the present disclosure, and to the specific processing steps in the manufacturing method of the wiring board according to the second group of the present disclosure.

The second group of the present disclosure includes the configurations relating to the following clauses B1 to B19.

Clause B1.

A wiring board comprising:

a base member having an obverse surface and a reverse surface that are spaced apart from each other in a thickness direction, the base member being made of a semiconductor material; and

an insulating portion that penetrates through the base member from the obverse surface to the reverse surface in the thickness direction,

wherein the base member includes a first portion and a second portion that are separated from each other by the insulating portion.

Clause B2.

The wiring board according to clause B1, wherein the insulating portion is made of an oxide of the semiconductor material.

Clause B3.

The wiring board according to clause B1 or B2,

wherein the insulating portion includes a plurality of through portions penetrating through from the obverse surface to the reverse surface in the thickness direction, and

adjacent two of the through portions are connected to each other as viewed in the thickness direction.

Clause B4.

The wiring board according to clause B3, wherein each of the through portions has a circular cross section perpendicular to the thickness direction.

Clause B5.

The wiring board according to any of clauses B1 to B4, wherein the insulating portion is formed in an annular shape as viewed in the thickness direction.

Clause B6.

The wiring board according to any of clauses B1 to B5, further comprising:

an obverse-surface electrode covering the obverse surface; and

a reverse-surface electrode covering the reverse surface,

wherein the obverse-surface electrode and the reverse-surface electrode are electrically connected to each other via the base member.

Clause B7.

The wiring board according to any of clauses B1 to B6, wherein the semiconductor material contains Si as a main component.

Clause B8.

The wiring board according to clause B7, wherein the semiconductor material is doped with an impurity to increase conductivity.

Clause B9.

The wiring board according to clause B7 or B8, wherein the obverse surface is a (100) surface.

Clause B10.

An electronic device comprising:

the wiring board according to any of clauses B1 to B9; and

an electronic component electrically connected to the first portion and the second portion.

Clause B11.

A method for manufacturing a wiring board, comprising:

a wafer preparation step of preparing a semiconductor wafer having an obverse surface and a reverse surface spaced apart from each other in a thickness direction, the semiconductor wafer being made of a semiconductor material; and

an insulating portion formation step of forming an insulating portion in the semiconductor wafer, the insulating portion penetrating through from the obverse surface to the reverse surface in the thickness direction,

wherein the insulating portion formation step forms a first portion and a second portion in the semiconductor wafer, the first portion and the second portion being separated from each other by the insulating portion.

Clause B12.

The method according to clause B11,

wherein the insulating portion formation step includes:

a through-hole formation step of forming a plurality of through-holes in the semiconductor wafer, the plurality of through-holes penetrating through from the obverse surface to the reverse surface in the thickness direction; and

a thermal oxidation step of thermally oxidizing the semiconductor wafer so that a plurality of oxidation films serving as the insulating portion are formed in the plurality of through-holes,

wherein each of the plurality of oxidation films is an oxide of the semiconductor material.

Clause B13.

The method according to clause B12, wherein the plurality of through-holes are provided such that adjacent two of the through-holes are arranged at a first interval.

Clause B14.

The method according to clause B13, wherein the plurality of oxidation films formed in the thermal oxidation step are larger than the plurality of through-holes as viewed in the thickness direction, so that the plurality of oxidation films are connected to each other as viewed in the thickness direction to form the insulating portion.

Clause B15.

The method according to any of clauses B12 to B14, wherein the plurality of through-holes are arranged in an annular shape as viewed in the thickness direction.

Clause B16.

The method according to any of clauses B12 to B15, wherein the semiconductor material contains Si as a main component.

Clause B17.

The method according to clause B16, wherein the semiconductor material is doped with an impurity to increase conductivity.

Clause B18.

The method according to clause B17,

wherein the obverse surface is a (100) surface, and

in the through-hole formation step, the plurality of through-holes are formed by reactive etching.

Clause B19.

The method according to any of B11 to B18, further comprising:

an obverse-surface electrode forming step of forming an obverse-surface electrode covering the obverse surface; and

a reverse-surface electrode forming step of forming a reverse-surface electrode covering the reverse surface.

[Third Group]

The following describes a third group of the present disclosure. The terms and reference signs in the third group of the present disclosure are defined independently from the terms and reference signs in the other groups.

The terms such as “first”, “second” and “third” in the present disclosure are used merely as labels and not intended to impose orders on the elements accompanied with these terms.

### First Embodiment

FIGS. 1 to 4 show a substrate according to a first embodiment of the third group of the present disclosure. A substrate E1 according to the present embodiment includes a base member 1, an insulating portion 2, and a conductive portion 3.

FIG. 1 is a perspective view showing the substrate E1. FIG. 2 is a plan view showing the substrate E1. FIG. 3 is a cross-sectional view taken along line III-III of FIG. 2. FIG. 4 is a partially enlarged cross-sectional view showing the substrate E1. FIG. 1 omits the insulating portion 2 to facilitate understanding. In these figures, the x direction corresponds to a second direction in the third group of the present disclosure, the y direction corresponds to a first direction in the third group of the present disclosure, and the z direction corresponds to a thickness direction in the third group of the present disclosure.

The base member 1 of the substrate E1 is made of a semiconductor material. The semiconductor material is Si, for example. In the present embodiment, descriptions are provided with an example where the base member 1 is made of a single-crystal Si material. The size of the base member 1 is not particularly limited, and the thickness in the z direction may be 150 μm to 300 μm.

The base member 1 is in the form of a plate. In the present embodiment, the base member 1 has a rectangular shape having four sides along the x direction and the y direction as viewed along the z direction. The base member 1 has an obverse surface 11, a reverse surface 12, and a plurality of through-holes 13. The obverse surface 11 is a flat surface facing one side in the z direction (upper side in FIG. 3). The reverse surface 12 is a flat surface facing the other side in the z direction (lower side in FIG. 3).

The through-holes 13 penetrate through the base member 1 in the z direction, and reach the obverse surface 11 and the reverse surface 12. In the present embodiment, the through-holes 13 include first through-holes 131 and second through-holes 132. The first through-holes 131 and the second through-holes 132 are spaced apart from each other in the x direction. In the present embodiment, the first through-holes 131 are arranged in a line along the y direction. The second through-holes 132 are also arranged in a line along the y direction. The arrangement of the first through-holes 131 and the second through-holes 132 is not particularly limited.

Each of the first through-holes 131 and the second through-holes 132 may have any shape as long as they penetrate through the base member 1. In the present embodiment, each of the first through-holes 131 and the second through-holes 132 has a shape with an inner wall surface substantially parallel along the z direction. The shape of each of the first through-holes 131 and the second through-holes 132 as viewed along the z direction is not particularly limited, and may be selected from various shapes including a circular shape, an elliptical shape, a rectangular shape, and a polygonal shape. In the present embodiment, each of the first through-holes 131 and the second through-holes 132 has a narrow shape with a length in the y direction and a width in the x direction. The ratio of the dimension of each of the first through-holes 131 and the second through-holes 132 in the x direction to the dimension thereof in the y direction may be 1:5 to 20, such as about 1:10. For example, each of the first through-holes 131 and the second through-holes 132 has a dimension of about 1 μm in the x direction, and a dimension of about 10 μm in the y direction.

The insulating portion 2 is in contact with the base member 1, and is made of an insulating material. For example, the insulating material of the insulating portion 2 may be SiO₂ or SiN. In the present embodiment, the insulating material of the insulating portion 2 is SiN, for it has excellent thermal conductivity. The insulating portion 2 made of SiN is formed by plasma CVD or reduced-pressure plasma CVD, for example. The thickness of the insulating portion 2 is not particularly limited, and may be 10 nm to 100 nm.

The insulating portion 2 has an obverse-surface insulating portion 21, a reverse-surface insulating portion 22, and a plurality of through insulating portions 23. The obverse-surface insulating portion 21 covers the obverse surface 11 of the base member 1, and in the illustrated example, covers the entirety of the obverse surface 11. The reverse-surface insulating portion 22 covers the reverse surface 12 of the base member 1, and in the illustrated example, covers the entirety of the reverse surface 12. The through insulating portions 23 cover the inner wall surfaces of the through-holes 13, and in the illustrated example, cover the entirety of the inner wall surfaces of the through-holes 13. The reverse-surface insulating portion 22 has a plurality of openings 221. The openings 221 penetrate through the reverse-surface insulating portion 22 in the z direction. The openings 221 overlap with the respective through-holes 13 as viewed along the z direction. The size of each of the openings 221 as viewed along the z direction is smaller than the size of each of the through-holes 13 as viewed along the z direction.

The conductive portion 3 is in contact with the insulating portion 2, and in the present embodiment, is not in contact with the base member 1. The conductive portion 3 forms a conductive path of a semiconductor element or the like mounted on the substrate E1. The conductive portion 3 of the present embodiment includes an obverse surface portion 31, a reverse surface portion 32, and a plurality of through portions 33. The conductive portion 3 of the present embodiment has a first layer 30a and a second layer 30b.

As shown in FIGS. 3 and 4, the first layer 30a is supported via the insulating portion 2 by the obverse surface 11 and the reverse surface 12 of the base member 1, as well as by the inner wall surfaces of the through-holes 13 of the base member 1. The first layer 30a is in contact with the insulating portion 2. The configuration of the first layer 30a is not particularly limited. In the present embodiment, the first layer 30a includes a Ti layer 301 and a Cu layer 302. The Ti layer 301 is in contact with the insulating portion 2 and is made of Ti. The Cu layer 302 is formed on the Ti layer 301 and is made of Cu. The Ti layer 301 and the Cu layer 302 are formed by sputtering, for example. The Ti layer 301 may have a thickness of about 40 nm, and the Cu layer 302 may have a thickness of about 200 nm.

The second layer 30b is formed on the first layer 30a. The configuration of the second layer 30b is not particularly limited. In the present embodiment, the second layer 30b is made of Cu, and is formed by plating, for example. The second layer 30b may have a thickness of about 5 μm to 30 μm. In the present embodiment, the second layer 30b is thicker than the first layer 30a.

The obverse surface portion 31 is supported by the obverse surface 11 of the base member 1 via the obverse-surface insulating portion 21 of the insulating portion 2, and is in contact with the obverse-surface insulating portion 21. In the present embodiment, the obverse surface portion 31 includes a first obverse surface portion 311 and a second obverse surface portion 312. The first obverse surface portion 311 and the second obverse surface portion 312 are spaced apart from each other in the x direction. Each of the first obverse surface portion 311 and the second obverse surface portion 312 is not limited to having a particular shape, and has a rectangular shape in the illustrated example. The first obverse surface portion 311 reaches one end of the obverse surface 11 in the x direction, and both ends of the obverse surface 11 in the y direction. The second obverse surface portion 312 reaches the other end of the obverse surface 11 in the x direction, and both ends of the obverse surface 11 in the y direction. The first obverse surface portion 311 overlaps with the first through-holes 131 as viewed along the z direction. The second obverse surface portion 312 overlaps with the second through-holes 132 as viewed along the z direction. Each of the first obverse surface portion 311 and second obverse surface portion 312 of the obverse surface portion 31 is made of the first layer 30a and the second layer 30b.

The reverse surface portion 32 is supported by the reverse surface 12 of the base member 1 via the reverse-surface insulating portion 22 of the insulating portion 2, and is in contact with the reverse-surface insulating portion 22. In the present embodiment, the reverse surface portion 32 includes a first reverse surface portion 321 and a second reverse surface portion 322. The first reverse surface portion 321 and the second reverse surface portion 322 are spaced apart from each other in the x direction. Each of the first reverse surface portion 321 and the second reverse surface portion 322 is not limited to having a particular shape, and has a rectangular shape in the illustrated example. The first reverse surface portion 321 reaches one end of the reverse surface 12 in the x direction, and both ends of the reverse surface 12 in the y direction. The first reverse surface portion 321 overlaps with the first through-holes 131 and the first obverse surface portion 311 as viewed along the z direction. The second reverse surface portion 322 overlaps with the second through-holes 132 and the second obverse surface portion 312 as viewed along the z direction. The second reverse surface portion 322 reaches the other end of the reverse surface 12 in the x direction, and both ends of the reverse surface 12 in the y direction. In the illustrated example, each of the first reverse surface portion 321 and the second reverse surface portion 322 of the reverse surface portion 32 is made of the first layer 30a.

The through portions 33 are housed in the respective through-holes 13, and are connected to the obverse surface portion 31 and the reverse surface portion 32. In the present embodiment, the through portions 33 include a plurality of first through portions 331 and a plurality of second through portions 332. The first through portions 331 are housed in the respective first through-holes 131, and are connected to the first obverse surface portion 311 and the first reverse surface portion 321. The second through portions 332 are housed in the respective second through-holes 132, and are connected to the second obverse surface portion 312 and the second reverse surface portion 322. Each of the first through portions 331 and second through portions 332 of the through portions 33 in the present embodiment is made of the first layer 30a and the second layer 30b. The second layer 30b has a solid shape that fills the first through-holes 131 and the second through-holes 132.

Next, an example of a method for manufacturing the substrate E1 is described below with reference to FIGS. 5 to 23. Although these figures show a method for forming a single substrate E1 to facilitate understanding, the present disclosure is not limited to this. A plurality of substrates E1 may be manufactured by using a material with which the substrates E1 can be manufactured collectively and performing a suitable process such as a dividing process.

First, a base member material 10 is prepared as shown in FIGS. 5 and 6. The base member material 10 is the material of the base member 1, and in the present embodiment, is a Si wafer made of single crystal Si. The base member material 10 has an obverse surface 11 and a reverse surface 120. The obverse surface 11 and the reverse surface 120 are flat surfaces that face away from each other in the z direction. The thickness of the base member material 10 in the z direction is larger than that of the base member 1, and is 200 μm to 725 μm, for example. As viewed along the z direction, areas corresponding to a plurality of substrates E1 are formed in a matrix in the base member material 10 made of a Si wafer. Accordingly, a plurality of substrates E1 are manufactured from the single base member material 10.

Next, as shown in FIG. 7, an insulating layer 20 is formed. The insulating layer 20 is formed by thermally oxidizing the base member material 10, for example. As a result, the insulating layer 20 is formed to cover the entirety of the base member material 10.

Next, a resist layer 51 is formed as shown in FIG. 8. The resist layer 51 is formed on the portion of the insulating layer 20 supported by the obverse surface 11. A plurality of openings 511 are formed in the resist layer 51. The openings 511 penetrate through the resist layer 51 in the z direction, and substantially coincide with the through-holes 13 described above in shape, size, and arrangement as viewed along the z direction.

Next, as shown in FIG. 9, the portions of the insulating layer 20 exposed from the openings 511 are removed. The selective removal of the insulating layer 20 is performed by wet etching or dry etching, for example. As a result, a plurality of openings 201 coinciding with the openings 511 are formed in the insulating layer 20.

Next, as shown in FIG. 10, the base member material 10 is etched with the insulating layer 20 having the openings 201 serving as a mask, so that a plurality of recesses 130 are formed. The recesses 130 are formed by deep RIE (reactive ion etching), for example. As a result, the inner wall surfaces of the recesses 130 are shaped along the z direction. The depth of the recesses 130 in the z direction is smaller than the thickness of the base member 1. The recesses 130 include a plurality of first recesses 1310 and a plurality of second recesses 1320. The first recesses 1310 are portions to become the first through-holes 131 in the substrate E1, and the second recesses 1320 are portions to become the second through-holes 132.

Next, as shown in FIGS. 11 and 12, the resist layer 51 and the insulating layer 20 are removed. The resist layer 51 is removed by oxygen plasma, for example. The insulating layer 20 is removed by etching with hydrofluoric acid, for example. As a result, the base member material 10 having the recesses 130 (the first recesses 1310 and the second recesses 1320) recessed from the obverse surface 11 is obtained.

Next, an obverse-surface insulating portion 21 and recess insulating portions 230 are formed as shown in FIG. 13. The obverse-surface insulating portion 21 and the recess insulating portions 230 are made of an insulating material, such as SiO₂ or SiN. In the present embodiment, the obverse-surface insulating portion 21 and the recess insulating portions 230 are made of SiN by plasma CVD or reduced-pressure plasma CVD. The thickness of each of the obverse-surface insulating portion 21 and the recess insulating portions 230 is 10 nm to 100 nm, for example. The obverse-surface insulating portion 21 covers the obverse surface 11. The recess insulating portions 230 cover the recesses 130.

Next, a first layer 30a is formed as shown in FIGS. 14 and 15. The first layer 30a is formed by forming a Ti layer 301 by sputtering or the like, and then forming a Cu layer 302 on the Ti layer 301 by sputtering or the like. The Ti layer 301 may have a thickness of about 40 nm, and the Cu layer 302 may have a thickness of about 200 nm.

Next, a resist layer 52 is formed as shown in FIG. 16. The resist layer 52 is formed on a portion of the first layer 30a supported by the obverse surface 11. The shape, size, and position of the resist layer 52 are substantially the same as those of the gap between the first obverse surface portion 311 and the second obverse surface portion 312 of the substrate E1 described above. Next, a second layer 30b is formed. The second layer 30b is formed by plating or the like on the portion of the first layer 30a exposed from the resist layer 52. The second layer 30b is made of Cu, for example. The obverse surface portion 31 having the first obverse surface portion 311 and the second obverse surface portion 312, which is described above, is obtained by forming the second layer 30b. In addition, a plurality of recess filling portions 330 housed in the recesses 130 are obtained. The recess filling portions 330 include a plurality of first recess filling portions 3310 housed in the first recesses 1310, and a plurality of second recess filling portions 3320 housed in the second recesses 1320. The second layer 30b of each of the recess filling portions 330 has a solid shape.

Next, the resist layer 52 is removed as shown in FIG. 17. Then, the portion of the first layer 30a exposed from the second layer 30b is removed by etching or the like. Next, the base member material 10 is ground and thinned from the lower side in the z direction (the reverse surface 120 side). The grinding is performed such that the ground surface reaches the recess filling portions 330 (the first recess filling portions 3310 and the second recess filling portions 3320). In this way, the base member 1 having the obverse surface 11, and the reverse surface 12, which is a ground surface, is obtained as shown in FIG. 18. The recesses 130 of the base member material 10 become the through-holes 13 of the base member 1. The through-holes 13 include the first through-holes 131 and the second through-holes 132. The recess insulating portions 230 become the through insulating portions 23. The recess filling portions 330 (the first recess filling portions 3310 and the second recess filling portions 3320) become the through portions 33 (the first through portions 331 and the second through portions 332).

Next, as shown in FIG. 19, a reverse-surface insulating portion 22 is formed. The reverse-surface insulating portion 22 is formed by forming a SiN film by means of plasma CVD or reduced-pressure plasma CVD, for example. As a result, the insulating portion 2 having the obverse-surface insulating portion 21, the reverse-surface insulating portion 22, and the through insulating portions 23 can be obtained.

Next, as shown in FIG. 20, a plurality of openings 221 are formed in the reverse-surface insulating portion 22. The openings 221 overlap with the through-holes 13 and the through portions 33 as viewed along the z direction. More specifically, the openings 221 are smaller than the through portions 33 and individually encompassed by the through portions 33 as viewed along the z direction. The openings 221 are formed by reactive ion etching with a mask formed by lithography patterning, for example. As a result, the lower ends of the through portions 33 in the z direction are exposed from the respective openings 221.

Next, a conductive layer 320 is formed as shown in FIG. 21. The conductive layer 320 is formed by stacking a Ti layer and a Cu layer on the reverse-surface insulating portion 22 by sputtering so as to cover the reverse-surface insulating portion 22, for example. Next, a resist layer 53 is formed as shown in FIG. 22. The resist layer 53 has an opening 531. The opening 531 substantially coincides with the gap between the first reverse surface portion 321 and the second reverse surface portion 322 of the substrate E1. Next, as shown in FIG. 23, the portion of the conductive layer 320 exposed from the resist layer 52 is removed by etching or the like. As a result, the reverse surface portion 32 having the first reverse surface portion 321 and the second reverse surface portion 322 is obtained, and the conductive portion 3 having the obverse surface portion 31, the reverse surface portion 32, and the through portions 33 is obtained. After that, the resist layer 53 is removed to obtain the substrate E1 shown in FIGS. 1 to 4.

FIGS. 24 and 25 show a semiconductor device according to the first embodiment of the third group of the present disclosure. A semiconductor device F1 according to the present embodiment includes the substrate E1, a semiconductor element 4, and a sealing resin 6.

The semiconductor element 4 is mounted on the substrate E1, and performs main functions for the semiconductor device F1. The semiconductor element 4 is a vertical cavity surface emitting laser (VCSEL) element, for example. The VCSEL element is a light source for the semiconductor device F1, and emits light in a predetermined wavelength band. The semiconductor element 4 is not limited to a VCSEL element, and may be another light-emitting element such as an LED element, or an optical semiconductor element such as a photodiode, phototransistor, or a photo IC. The optical semiconductor element has a photoelectric conversion function of converting one of light energy and electric energy to the other. Furthermore, the semiconductor element 4 may be a semiconductor element (active element) such as a transistor, a diode, or an IC, or a passive element such as a resistor, a capacitor, or an inductor. It is preferable that the semiconductor element 4 be one having a large heat generation property among light-emitting elements and power active elements.

The semiconductor element 4 is bonded to the obverse surface portion 31 of the substrate E1 by a conductive bonding layer 42, for example. The conductive bonding layer 42 is solder or Ag paste, for example. As viewed along the z direction, the semiconductor element 4 overlaps with at least one of the first through-holes 131, and in the illustrated example, overlaps with all of the first through-holes 131.

First ends of a plurality of wires 41 are connected to the semiconductor element 4. The wires 41 are linear conductive members made of Au, Al, or Cu, for example. Second ends of the wires 41 are connected to the second obverse surface portion 312 of the obverse surface portion 31, and are electrically connected to the second reverse surface portion 322 of the reverse surface portion 32 via the second through portions 332.

The sealing resin 6 is arranged on the obverse surface 11 side of the base member 1, and covers the obverse surface portion 31, the semiconductor element 4, and the wires 41. The sealing resin 6 is made of black epoxy resin, for example.

Next, advantages of the substrate E1 and the semiconductor device F1 are described.

According to the present embodiment, the base member 1 is made of a semiconductor material, and the obverse surface portion 31 and the reverse surface portion 32 are connected via the through portions 33. As a result, the heat generated by the semiconductor element 4 mounted on the obverse surface portion 31 can be transferred more efficiently from the obverse surface portion 31 to the reverse surface portion 32 via the through portions 33. Furthermore, heat transfer of the base member 1 per se can also be expected. Since the through-holes 13 have the inner wall surfaces along the x direction, the through-holes 13 can be prevented from occupying undesirably large spaces when viewed along the z direction. This makes it possible to downsize the substrate E1 and the semiconductor device F1 while promoting heat dissipation from the semiconductor element 4.

Each of the through portions 33 has a solid shape. This makes it possible to increase the cross-sectional area of the heat transfer path connecting the obverse surface portion 31 to the reverse surface portion 32 and favorably promote heat dissipation.

Each of the through-holes 13 has a narrow shape with a length in the y direction and a width in the x direction. In this way, when the recesses 130 are formed by deep RIE as shown in FIG. 10, for example, the efficiency of etching can be increased.

The first through-holes 131 and the second through-holes 132 are aligned in the y direction. This makes it possible to further promote heat dissipation in the area where the first through-holes 131 and the second through-holes 132 are arranged.

The insulating portion 2 of the present embodiment is made of SiN. SiN has a higher thermal conductivity than SiO₂, for example. Accordingly, when heat from the obverse surface portion 31 is transferred to the reverse surface portion 32 via the obverse-surface insulating portion 21, the base member 1, and the reverse-surface insulating portion 22, the heat transfer efficiency in the obverse-surface insulating portion 21 and the reverse-surface insulating portion 22 can be improved.

The semiconductor element 4 overlaps with the first through-holes 131 as viewed along the z direction. As such, heat from the semiconductor element 4 is more efficiently transferred to the through portions 33 via the obverse surface portion 31. This is preferable for promoting the dissipation of heat from the substrate E1 and the semiconductor device F1. Furthermore, the configuration in which the semiconductor element 4 overlaps with all of the first through-holes 131 as viewed along the z direction is preferable for promoting heat dissipation.

In the manufacturing process of the substrate E1, the base member material 10 is ground and thinned from the other side in the z direction (reverse surface 120 side). This makes it possible to reduce the thickness of the semiconductor device F1.

FIGS. 26 to 35 show another embodiment of the third group of the present disclosure. In these figures, elements that are identical or similar to those in the above embodiment are designated by the same reference signs as in the above embodiment.

### First Variation of First Embodiment

FIG. 26 shows a first variation of the substrate E1 and the semiconductor device F1. A substrate Ell and a semiconductor device F11 according to the present variation are different from the substrate E1 and the semiconductor device F1 described above with respect to the configuration of the reverse surface portion 32.

In the present variation, the reverse surface portion 32 is made of the first layer 30a and the second layer 30b. As described above, the first layer 30a is a Cu layer formed by plating, for example. Such a configuration is obtained by forming the conductive layer 320 shown in FIG. 21, and then forming the first layer 30a on the conductive layer 320 by plating.

The present variation can also realize downsizing while promoting heat dissipation. Furthermore, when the semiconductor device F11 is mounted on a circuit board or the like using the reverse surface portion 32, advantages such as improvement of the strength of conduction bonding are expected. As can be understood from the present variation, specific configurations of elements such as the reverse surface portion 32 are not particularly limited.

### Second Embodiment

FIG. 27 shows a substrate according to a second embodiment of the third group of the present disclosure. A substrate E2 and a semiconductor device F2 according to the present embodiment are different from those in the above embodiment in the configurations of the through-holes 13, the through insulating portions 23, and the through portions 33.

In the present embodiment, the first through-holes 131 form multiple lines that are each arranged along the y direction and that are spaced apart from each other in the x direction, as viewed along the z direction. In other words, the first through-holes 131 are arranged in a matrix along the x direction and the y direction. The illustrated example shows 4-line arrangement where each line includes four first through-holes 131. The semiconductor element 4 overlaps with the at least one of the first through-holes 131 as viewed along the z direction, and in the illustrated example, overlaps with all of the first through holes 131.

The second through-holes 132 form multiple lines that are each arranged along the y direction and that are spaced apart from each other in the x direction, as viewed along the z direction. In other words, the second through-holes 132 are arranged in a matrix along the x direction and the y direction. The illustrated example shows 2-line arrangement where each line includes four first through-holes 131.

The present embodiment can also realize downsizing while promoting heat dissipation. Since the first through-holes 131 are arranged in a matrix, the efficiency of heat dissipation from the obverse surface portion 31 to the reverse surface portion 32 via the through portions 33 can be further improved.

### Third Embodiment

FIGS. 28 and 29 show a substrate and a semiconductor device according to a third embodiment of the third group of the present disclosure. A semiconductor device F3 according to the present embodiment includes a substrate E3, the semiconductor element 4, and a cover 7. FIG. 28 omits the cover 7 to facilitate understanding.

In the substrate E3 of the present embodiment, the base member 1 has a peripheral wall portion 14 and a recess 15. The peripheral wall portion 14 protrudes from the obverse surface 11 to the one side in the z direction (upper side in FIG. 29). The peripheral wall portion 14 has a rectangular ring shape surrounding the obverse surface 11, as viewed along the z direction. The peripheral wall portion 14 has a top surface 141. The top surface 141 of the peripheral wall portion 14 is a flat surface positioned on the one side in the z direction and perpendicular to the z direction. The recess 15 is a portion recessed from the top surface 141 to the other side in the z direction, and is surrounded by the peripheral wall portion 14 as viewed along the z direction. In the present embodiment, the obverse surface 11 serves as the bottom surface of the recess 15. The insulating portion 2 has a peripheral-wall insulating portion 24. The peripheral-wall insulating portion 24 covers the peripheral wall portion 14.

As is the case with the substrate E2 described above, the base member 1 has the first through-holes 131 and the second through-holes 132. In the illustrated example, the insulating portion 2 does not have the reverse-surface insulating portion 22 described above, and the reverse surface 12 of the base member 1 is exposed from the insulating portion 2. Note that the insulating portion 2 may have the reverse-surface insulating portion 22 that covers the reverse surface 12.

In the present embodiment, the reverse surface portion 32 has first reverse surface portions 321 and second reverse surface portions 322. The first reverse surface portions 321 connect to the respective first through portions 331, and are spaced apart from each other. The first reverse surface portions 321 protrude from the obverse-surface insulating portion 21. The second reverse surface portions 322 are spaced apart from each other, and are connected to the respective second through portions 332. The second reverse surface portions 322 protrude from the obverse-surface insulating portion 21.

The semiconductor element 4 is supported by the obverse surface 11, and is housed in the recess 15. The semiconductor element 4 is offset to the other side in the z direction relative to the top surface 141.

The cover 7 is a member that covers the recess 15. In the present embodiment, the cover 7 is made of a material that transmits light from the semiconductor element 4. For example, the cover 7 is a plate-like member made of glass. The cover 7 is bonded to the top surface 141 via a bonding layer 79, which is made of an adhesive, for example.

Next, an example of a method for manufacturing the substrate E3 is described with reference to FIGS. 30 to 35.

First, a base member material 10 is prepared as shown in FIG. 30. The base member material 10 of the present embodiment is a Si wafer made of single crystal Si, and has an obverse surface 1410 and a reverse surface 12. The obverse surface 1410 and the reverse surface 12 are flat surfaces that face away from each other in the z direction. Then, an insulating layer 20 is formed on the base member material 10. The insulating layer 20 has an obverse-surface insulating portion 240 covering the obverse surface 1410 and a reverse-surface insulating portion 22 covering the reverse surface 12. The insulating layer 20 is formed by thermal oxidation process, for example.

Next, as shown in FIG. 31, a recess 15 is formed in a base member 1. The recess 15 is formed by removing a portion of the obverse-surface insulating portion 240 of the insulating layer 20, and performing deep RIE (reactive ion etching) on the obverse surface 1410 exposed from the portion. As a result, the base member material 10 has a peripheral wall portion 14 and the recess 15. The bottom surface of the recess 15 become the obverse surface 11.

Next, a plurality of through-holes 13 are formed as shown in FIG. 32 by, for example, the same method as that described with reference to FIGS. 7 to 10. The through-holes 13 include a plurality of first through-holes 131 and a plurality of second through-holes 132. At this point, the deep RIE (reactive ion etching) reaches the reverse-surface insulating portion 22 of the insulating layer 20, and the reverse-surface insulating portion 22 functions as a so-called stopper.

Next, a plurality of through insulating portions 23 are formed as shown in FIG. 33 by performing a thermal oxidation process, for example. Next, a conductive portion 3 is formed as shown in FIG. 34 by, for example, the same method as that described with reference to FIGS. 14 to 17. Due to the conductive portion 3 thus formed, a plurality of first through portions 331 are housed in the respective first through-holes 131, and a plurality of second reverse surface portions 322 are housed in the respective second through-holes 132.

Next, as shown in FIG. 35, the reverse-surface insulating portion 22 is removed by wet etching, for example. Unlike the illustrated example, it is possible to remove a peripheral-wall insulating portion 24 as well as the reverse-surface insulating portion 22 by wet etching.

After that, a plurality of first reverse surface portions 321 in contact with the first through-holes 131 and a plurality of second reverse surface portions 322 in contact with the second through-holes 132 are formed by electroless plating, for example. As a result, the substrate E3 shown in FIGS. 28 and 29 is obtained. Note that the reverse surface portion 32 of the conductive portion 3 is not limited to having the configuration shown in the illustrated example, and may have any suitable configuration selected from the configurations shown in FIG. 3 and FIG. 26.

The present embodiment can also realize downsizing while promoting heat dissipation. It is also possible to protect the semiconductor element 4 by housing the semiconductor element 4 in the recess 15 of the base member 1. In addition, the base member 1 having the peripheral wall portion 14 is advantageous in that the cover 7 for protecting the semiconductor element 4 can be easily arranged.

The substrate and the semiconductor device according to the third group of the present disclosure are not limited to the above embodiments. Various design changes can be made to the specific configurations of the substrate and the elements of the semiconductor device according to the third group of the present disclosure.

The third group of the present disclosure includes the configurations relating to the following clauses C1 to C17.

Clause C1.

A substrate comprising:

a base member made of a semiconductor material and having an obverse surface and a reverse surface that face away from each other in a thickness direction; and

a conductive portion formed on the base member,

wherein the base member has a through-hole penetrating through in the thickness direction to reach the obverse surface and the reverse surface, the through-hole having an inner wall surface along the thickness direction, and

the conductive portion has an obverse surface portion supported by the obverse surface, a reverse surface portion supported by the reverse surface, and a through portion housed in the through-hole and connected to the obverse surface portion and the reverse surface portion.

Clause C2.

The substrate according to clause C1, wherein the through portion has a solid shape.

Clause C3.

The substrate according to clause C1 or C2, wherein the through portion has a narrow shape with a length in a first direction and a width in a second direction as viewed along the thickness direction, the first direction being perpendicular to the thickness direction, the second direction being perpendicular to the thickness direction and the first direction.

Clause C4.

The substrate according to clause C3, wherein a plurality of the through portions are aligned in the first direction.

Clause C5.

The substrate according to clause C3 or C4,

wherein the obverse surface portion includes a first obverse surface portion and a second obverse surface portion spaced apart from each other in the second direction,

the reverse surface portion includes a first reverse surface portion and a second reverse surface portion that are spaced apart from each other in the second direction,

the base member has a plurality of the through-holes including a first through-hole overlapping with the first obverse surface portion and the first reverse surface portion as viewed along the thickness direction, and a second through-hole overlapping with the second obverse surface portion and the second reverse surface portion as viewed along the thickness direction, and

the through portion includes a first through portion housed in the first through-hole and a second through portion housed in the second through-hole.

Clause C6.

The substrate according to clause C5, further comprising an insulating portion having an obverse-surface insulating portion interposed between the obverse surface and the obverse surface portion, a reverse-surface insulating portion interposed between the reverse surface and the reverse surface portion, and a through insulating portion interposed between the through-hole and the through portion.

Clause C7.

The substrate according to clause C6, wherein the insulating portion is made of a nitride.

Clause C8.

The substrate according to clause C6 or C7, wherein the conductive portion includes a first layer and a second layer, the first layer being supported by the obverse surface, the reverse surface, and the inner wall surface of the through-hole, the second layer being formed on portions of the first layer that are supported by the obverse surface and the inner wall surface.

Clause C9.

The substrate according to clause C8, wherein the second layer is thicker than the first layer.

Clause C10.

The substrate according to clause C9, wherein the second layer has a solid shape at the through portion.

Clause C11.

The substrate according to any of clauses C8 to C10, wherein the second layer does not include any portion supported by the reverse surface.

Clause C12.

The substrate according to any of clauses C8 to C11, wherein the first layer includes a Ti layer made of Ti, and a Cu layer formed on the Ti layer.

Clause C13.

The substrate according to any of clauses C8 to C12, wherein the second layer contains Cu.

Clause C14.

The substrate according to any of clauses C5 to C13, wherein as viewed along the thickness direction, a plurality of the first through-holes form multiple lines that are each arranged along the first direction and that are spaced apart from each other in the second direction.

Clause C15.

A semiconductor device comprising:

the substrate according to any of clauses C1 to C14; and

a semiconductor element mounted on the obverse surface portion of the conductive portion.

Clause C16.

The semiconductor device according to clause C15 that depends on clause C14, wherein the semiconductor element overlaps with the plurality of first through-holes as viewed along the thickness direction.

Clause C17.

The semiconductor device according to clause C16, wherein the semiconductor element is an optical semiconductor element that has a photoelectric conversion function of converting one of light energy and electric energy to the other.

1. A method for manufacturing a diffusion cover that diffuses and transmits light from a semiconductor light-emitting element, the method comprising the steps of:
preparing a base member having an obverse surface and a reverse surface that face away from each other in a thickness direction;
forming a lens material on the obverse surface, the lens material containing a photosensitive transparent resin; and
removing a portion of the lens material by performing grayscale exposure and development, and forming a lens having a plurality of lens members.

2. The method according to claim 1,
wherein the photosensitive transparent resin has positive photosensitivity, and
the grayscale exposure is performed by irradiation with light from a side of the lens material.

3. The method according to claim 2, wherein the step of forming the lens includes forming a base layer covering the obverse surface, and forming the plurality of lens members such that each of the lens members connects to the base layer.

4. The method according to claim 2 or 3, wherein the base member includes a glass substrate.

5. The method according to claim 4, wherein the diffusion cover includes the base member and the lens.

6. The method according to claim 3,
wherein the base member includes a silicon substrate,
the method further comprises the step of peeling off the lens from the base member after the step of forming the lens, and
the diffusion cover includes the lens peeled off from the base member.

7. A diffusion cover that diffuses and transmits light from a semiconductor light-emitting element, comprising:
a base member having an obverse surface and a reverse surface that face away from each other in a thickness direction; and
a lens arranged on the obverse surface, having a plurality of lens members protruding to the same side as a side that the obverse surface faces in the thickness direction, and containing a transparent resin.

8. The diffusion cover according to claim 7,
wherein the lens has a base layer that is in close contact with the obverse surface, and
the plurality of lens members are integrally connected to each other on the base layer.

9. The diffusion cover according to claim 8, wherein a first dimension, which is a length of the lens in the thickness direction, is 1 μm to 10 μm.

10. The diffusion cover according to claim 9, wherein a second dimension, which is a length of each of the lens members in the thickness direction, is 1 μm to 10 μm.

11. The diffusion cover according to claim 10, wherein the first dimension is one to three times larger than the second dimension.

12. The diffusion cover according to claim 7, wherein the base member includes a glass substrate.

13. A semiconductor light-emitting device comprising:
a semiconductor light-emitting element;
a support that supports the semiconductor light-emitting element; and
the diffusion cover according to claim 7, the diffusion cover overlapping with the semiconductor light-emitting element as viewed in the thickness direction.

14. The semiconductor light-emitting device according to claim 13,
wherein the support has a first surface, a second surface, a third surface, and a fourth surface, the semiconductor light-emitting element being arranged on the first surface, the first surface facing in the thickness direction, the second surface facing in a direction opposite from the direction in which the first surface faces, the third surface facing in the same direction as the first surface, being spaced farther apart from the second surface than the first surface is from the second surface, and surrounding the first surface as viewed in the thickness direction, the fourth surface being provided between the first surface and the third surface, and
the diffusion cover is supported by the third surface.

15. The semiconductor light-emitting device according to claim 14,
wherein the lens has a lens region in which the plurality of lens members are formed, and a non-lens region that surrounds the lens region as viewed in the thickness direction and in which the plurality of lens members are not formed, and
the diffusion cover is arranged such that the non-lens region faces the third surface.

16. The semiconductor light-emitting device according to claim 13, wherein the semiconductor light-emitting element is a VCSEL element.
